(19) United States
(12) Patent Application Publication
(10) Pub. No.: US 2026/0130242 A1
(43) Pub. Date: May 7, 2026

(54) SEMICONDUCTOR PACKAGING WITH EMBEDDED DEVICE AND REDISTRIBUTION LAYER

(71) Applicant: SEMICONDUCTOR COMPONENTS INDUSTRIES, LLC, Scottsdale, AZ (US)

(72) Inventors: Dinesh RAMANATHAN, Los Altos Hills, CA (US); Anders Soren LIND, San Juan Capistrano, CA (US); Vijay B. RENTALA, Plano, TX (US); Christopher Lee TESSLER, Poughquag, NY (US); Michael J. SEDDON, Gilbert, AZ (US); Gabrielle ROBERT, Fishkill, NY (US); Jorge LUBGUBAN, Danbury, CT (US)

(73) Assignee: SEMICONDUCTOR COMPONENTS INDUSTRIES, LLC, Scottsdale, AZ (US)

(21) Appl. No.: 19/376,690

(22) Filed: Oct. 31, 2025

Related U.S. Application Data
(60) Provisional application No. 63/715,912, filed on Nov. 4, 2024.
(60) Provisional application No. 63/736,415, filed on Dec. 19, 2024.

(51) Int. Cl. H01L 23/00; H01L 23/31; H01L 23/538; H01L 25/10

(52) U.S. Cl. CPC H10W 70/611; H10W 70/635; H10W 70/65; H10W 74/114; H10W 90/00; H10W 70/60

(57) ABSTRACT

A semiconductor package may include a semiconductor die disposed on a first substrate and having at least a first contact on a first side and at least a second contact on a second side that is opposed to the first side. An insulator, such as a dielectric, may encapsulate the semiconductor die. A second substrate may be disposed on the first substrate with the semiconductor die therebetween. Either of the first or second substrate may have a cavity formed therein, and the semiconductor die may be disposed in one or both of the cavities. Vias through the first substrate, the dielectric, and/or the second substrate may be used to connect to the semiconductor die, enabling formation of a redistribution layer. Magnetic elements and associated windings may also be used in place of the semiconductor die and associated contacts.

### CROSS-REFERENCE TO RELATED APPLICATION

This application claims the benefit of and priority to U.S. Provisional Application No. 63/715,912, filed Nov. 4, 2024, and U.S. Provisional Application No. 63/736,415, filed Dec. 19, 2024, and to U.S. Non-provisional Application xx/xxx, xxx, filed concurrently herewith and titled SEMICONDUCTOR MODULE WITH POWER BRIDGE FOR INTEGRATED DIE INTERCONNECTION, which are incorporated by reference herein in their entireties.

### TECHNICAL FIELD

This description relates to semiconductor device packaging.

### BACKGROUND

Conventional packaging techniques for semiconductor devices have a number of shortcomings. Such shortcomings are particularly problematic in the context of packaging semiconductor power devices, because such devices typically have multiple requirements that must be met concurrently by a selected packaging technique.

For example, semiconductor power devices often require high-voltage and high temperature operation, thereby requiring high-voltage isolation for safety reasons and high thermal conductivity for heat transfer to a heatsink(s) of some type. Power device packaging is also often desired to be low cost and small size, further exacerbating difficulties in meeting voltage/thermal requirements.

In a specific example, it is desirable to provide semiconductor modules for traction inverters for electric vehicles with a low on-resistance across many parallel devices, along with low circuit parasitics, while maintaining the above-referenced requirements for low cost, small size, and voltage/thermal management. In another specific example, artificial intelligence (AI) datacenters have large-scale power requirements, but current packaging techniques suffer from, e.g., complexity associated with multi-chip packaging within a small footprint (exacerbated by the use of flip-chip technology), poor thermal conductivity of mold compounds used for encapsulation, and undesirably large package volume caused by the inclusion of bond wires.

More recent approaches attempt to address the above and related challenges, such as approaches using printed circuit board (PCB) embedding. However, these approaches can be expensive and complex, while still failing to satisfactorily address existing challenges. For example, PCB embedding typically requires expensive laser drilling for vias, while providing insufficient cooling.

### SUMMARY

According to one general aspect, a semiconductor package includes a substrate, a semiconductor die disposed on the substrate and having at least a first contact on a first side and at least a second contact on a second side that is opposed to the first side, a dielectric encapsulant encapsulating the semiconductor die and having vias formed therein, and a redistribution layer formed on the dielectric encapsulant and connected to the first contact and the second contact through the vias.

According to another general aspect, a method of making a semiconductor package includes providing a semiconductor die on a substrate, the semiconductor die having at least a first contact on a first side and at least a second contact on a second side that is opposed to the first side, encapsulating the semiconductor die with a dielectric encapsulant, forming vias in the dielectric encapsulant, and forming a redistribution layer on the dielectric encapsulant that is connected to the first contact and the second contact through the vias.

According to another general aspect, a semiconductor package includes a first substrate, a semiconductor die disposed on the first substrate, a second substrate having a cavity formed therein, the cavity defining a first portion of the second substrate having a first depth and a second portion of the second substrate having a second depth that is greater than the first depth, and the second substrate being attached to the first substrate by the second portion of the second substrate and with the semiconductor die disposed within the cavity, a via formed through the first portion of the second substrate, and a contact disposed on the second substrate and electrically connected to the semiconductor die through the via.

According to another general aspect, a method of making a semiconductor package includes disposing a semiconductor die on a first substrate, forming a cavity in a second substrate, the cavity defining a first portion of the second substrate having a first depth and a second portion of the second substrate having a second depth that is greater than the first depth, attaching the second substrate to the first substrate by the second portion of the second substrate and with the semiconductor die disposed within the cavity, forming a via through the first portion of the second substrate, and disposing a contact on the second substrate and electrically connected to the semiconductor die through the via.

According to another general aspect, a semiconductor package includes a substrate having a cavity formed therein, a magnetic element disposed in the cavity, a metallic winding disposed on the substrate and surrounding the magnetic element, a dielectric encapsulant encapsulating the magnetic element and the metallic winding, and a contact electrically connected to the metallic winding through a via formed in the dielectric encapsulant.

According to another general aspect, a method of making a semiconductor package includes forming a cavity in a substrate, disposing a magnetic element in the cavity, providing a metallic winding on the substrate and surrounding the magnetic element, encapsulating the magnetic element and the metallic winding with a dielectric encapsulant, forming a via formed in the dielectric encapsulant, and electrically connecting a contact to the metallic winding through the via.

According to another general aspect, a semiconductor package includes a first substrate, a metal layer disposed on the first substrate, metal pillars disposed on the metal layer and defining a cavity, a semiconductor die disposed in the cavity with a first surface disposed on the metal layer, an encapsulant encapsulating the semiconductor die, including a second surface thereof opposed to the first surface, and at least a portion of the metallic pillars, a second substrate formed on the encapsulant and the metal pillars, and a redistribution layer formed on the second substrate and connected to the first surface of the semiconductor die, the second surface of the semiconductor die, and at least one of the metal pillars, through vias formed through the second substrate.

According to another general aspect, a method of making a semiconductor package includes forming a metal layer on a first substrate, disposing metal pillars on the metal layer to define a cavity, disposing a semiconductor die in the cavity with a first surface disposed on the metal layer, encapsulating, with an encapsulant, the semiconductor die, including a second surface thereof opposed to the first surface, and at least a portion of the metal pillars, forming a second substrate on the encapsulant and the metal pillars, forming vias through the second substrate, and forming a redistribution layer on the second substrate and connected to the first surface of the semiconductor die, the second surface of the semiconductor die, and at least one of the metal pillars, through the vias.

The details of one or more implementations are set forth in the accompanying drawings and the description below. Other features will be apparent from the description and drawings, and from the claims.

### BRIEF DESCRIPTION OF THE DRAWINGS

FIG. 1 is a cross-sectional view of a semiconductor module according to example embodiments.

FIG. 2A is a cross-sectional view of an example processing stage for forming the semiconductor module of FIG. 1.

FIG. 2B is a cross-sectional view of an example processing stage for forming a semiconductor module that is similar to the semiconductor module of FIG. 1.

FIG. 2C is a cross-sectional view of an example processing stage for forming the semiconductor module of FIG. 2B.

FIG. 2D is a cross-sectional view of a further example processing stage for forming the semiconductor module of FIG. 2B.

FIG. 2E is a cross-sectional view of an example processing stage for forming the semiconductor module of FIG. 2D that illustrates additional example optional contacts.

FIG. 2F is a cross-sectional view of a final processing stage for the semiconductor module of FIG. 2B.

FIG. 3 is a cross-sectional view of a semiconductor module with a cavity according to example embodiments.

FIG. 4 is a cross-sectional view of an example embodiment with a second substrate.

FIG. 5A is a cross-sectional view of a first processing stage for forming the example embodiment of FIG. 4.

FIG. 5B is a cross-sectional view of a second processing stage for forming the example embodiment of FIG. 4.

FIG. 6 is a cross-sectional view of an example embodiment with stacked devices.

FIG. 7 is a cross-sectional view of an example embodiment with stacked modules.

FIG. 8 is a cross-sectional view of an example embodiment of a semiconductor module with backside contacting.

FIG. 9 is an example embodiment illustrating ease of connection of a semiconductor module constructed using described techniques to provide footprint matching with existing packages.

FIG. 10 is a cross-sectional view of an example embodiment with nested modules.

FIG. 11 illustrates a first example use case for the example embodiment of FIG. 10.

FIG. 12 illustrates a first example use case for the example embodiment of FIG. 9.

FIG. 13 is a circuit diagram illustrating operation of a module according to example embodiments that operates as a solid-state relay.

FIG. 14 is a top view of a portion of a wafer used to produce modules with four semiconductor dies each.

FIG. 15 is a top view of an entirety of the wafer of FIG. 14.

FIG. 16 is an example implementation demonstrating dual thermal and electrical connectivity.

FIG. 17 is an alternate example implementation demonstrating dual thermal and electrical connectivity.

FIG. 18 illustrates an example embodiment with multiple cavities.

FIG. 19 illustrates an example embodiment with an array of multiple modules of FIG. 18 deployed together.

FIG. 20A is an isometric view of an example embodiment with a cooling block.

FIG. 20B is a cross-sectional view of the example embodiment of FIG. 20A

FIG. 21 is a 3D exploded view of an example assembled package for the embodiments of FIGS. 18-20B.

FIG. 22 illustrates an example of single-metal layer routing for multiple dies.

FIG. 23 is a cross-sectional view of an example dual-cavity embodiment.

FIG. 24 is a cross-sectional view of an alternate example dual-cavity embodiment.

FIG. 25 is a cross-sectional view of an example single-cavity embodiment on metal.

FIG. 26 is a cross-sectional view of an example dual-cavity embodiment with silicon bonded to diamond.

FIG. 27 is a cross-sectional view of an example dual-cavity embodiment with a drain-side redistribution layer.

FIG. 28 is a cross-sectional view of an alternate example dual-cavity embodiment with a drain-side redistribution layer.

FIG. 29 is a cross-sectional view of an example dual-cavity embodiment with one cavity formed using a metal substrate and a substrate frame.

FIG. 30 is a cross-sectional view of an example dual-substrate, single-cavity embodiment.

FIG. 31 is a cross-sectional view of an example dual-cavity embodiment with a redistribution layer formed between substrates.

FIG. 32 is a cross-sectional view of an example dual-cavity embodiment with integrated passive devices.

FIG. 33 is a cross-sectional view of an example dual-cavity embodiment with integrated active circuitry.

FIG. 34 is a cross-sectional view of an example dual-cavity embodiment with integrated MEMs technology.

FIG. 35 is a cross-sectional view of an example dual-cavity embodiment with integrated MEMs pipes for liquid cooling.

FIG. 36 is a cross-sectional view of an alternate example dual-cavity embodiment with integrated MEMs technology and/or active circuitry.

FIG. 37 is a cross-sectional view of an example dual-cavity, dual-die embodiment.

FIG. 38 is a top view of an example embodiment that may be constructed using various ones of the example embodiments of FIG. 37 and/or FIGS. 39-50.

FIG. 39 is a cross-sectional view of an example dual-die embodiment having a substrate with a cavity on metal to provide a common drain connection.

FIG. 40 illustrates example gate/source routing.

FIG. 41 illustrates example gate/source/drain routing for the example of FIG. 40

FIG. 42 is a cross-sectional view of an example dual-cavity, dual-die embodiment with a single redistribution layer.

FIG. 43 is a cross-sectional view of an example stacked module with multiple dual-cavity, dual-die modules.

FIG. 44 is a cross-sectional view of an example stacked module in a half-bridge configuration.

FIG. 45 is a cross-sectional view of an alternate example stacked module in a half-bridge configuration.

FIG. 46 is a cross-sectional view of a second alternate example stacked module in a half-bridge configuration.

FIG. 47 is a cross-sectional view of an implementation of the example of FIG. 46 with busbars.

FIG. 48 is a top view of the example embodiment of FIG. 47.

FIG. 49 is a cross-sectional view of an additional example stacked module in a half-bridge configuration.

FIG. 50 is a circuit diagram for a stacked module in a half-bridge configuration.

FIG. 51 is a cross-sectional view of a dual-cavity embodiment packaged with a printed circuit board and a heatsink.

FIG. 52 is a cross-sectional view of a single-cavity embodiment with alternate gate routing and a bonded interface.

FIG. 53 is a cross-sectional view of a single-cavity embodiment with alternate gate and source routing to accommodate a heatsink.

FIG. 54 is a cross-sectional view of a single-cavity embodiment with alternate gate routing.

FIG. 55 is a cross-sectional view of a single-cavity embodiment with an embedded magnetic element.

FIG. 56 is a top view of the example of FIG. 55.

FIG. 57A illustrates a first example embodiment of the examples of FIG. 55 and FIG. 56.

FIG. 57B illustrates a second example embodiment of the examples of FIG. 55 and FIG. 56.

FIG. 58 illustrates a third example embodiment of the examples of FIG. 55 and FIG. 56.

FIG. 59 is a cross-sectional view of an alternate single-cavity embodiment.

FIG. 60 is an example top view of the embodiment of FIG. 59.

FIG. 61A illustrates first example processes for forming a lower assembly of FIG. 59.

FIG. 61B illustrates second example processes for forming a lower assembly of FIG. 59.

FIG. 61C illustrates third example processes for forming a lower assembly of FIG. 59.

FIG. 61D illustrates fourth example processes for forming a lower assembly of FIG. 59.

FIG. 61E illustrates fifth example processes for forming a lower assembly of FIG. 59.

FIG. 61F illustrates sixth example processes for forming a lower assembly of FIG. 59.

FIG. 61G illustrates seventh example processes for forming a lower assembly of FIG. 59.

FIG. 62A illustrates first example processes for forming an upper assembly of FIG. 59.

FIG. 62B illustrates second example processes for forming an upper assembly of FIG. 59.

FIG. 62C illustrates third example processes for forming an upper assembly of FIG. 59.

FIG. 62D illustrates fourth example processes for forming an upper assembly of FIG. 59.

FIG. 63A illustrates first example processes for forming an alternate embodiment with metal pillars.

FIG. 63B illustrates second example processes for forming an alternate embodiment with metal pillars.

FIG. 63C illustrates third example processes for forming an alternate embodiment with metal pillars.

FIG. 63D illustrates fourth example processes for forming an alternate embodiment with metal pillars.

FIG. 63E illustrates fifth example processes for forming an alternate embodiment with metal pillars.

FIG. 63F illustrates sixth example processes for forming an alternate embodiment with metal pillars.

FIG. 63G illustrates seventh example processes for forming an alternate embodiment with metal pillars.

FIG. 63H illustrates eighth example processes for forming an alternate embodiment with metal pillars.

FIG. 63I illustrates ninth example processes for forming an alternate embodiment with metal pillars.

FIG. 63J illustrates tenth example processes for forming an alternate embodiment with metal pillars.

FIG. 64 is a cross-sectional view of an example embodiment with heat sinks formed in vias.

FIG. 65 illustrates an example process flow for forming cavities that may be used with various embodiments.

FIG. 66 is a first flowchart illustrating example embodiments.

FIG. 67 is a second flowchart illustrating example embodiments.

FIG. 68 is a third flowchart illustrating example embodiments.

FIG. 69 is a fourth flowchart illustrating example embodiments.

### DETAILED DESCRIPTION

Described power semiconductor packaging techniques enable improvements to the above and other shortcomings of conventional techniques. For example, described techniques provide improved thermal properties (including dual side cooling), improved package parasitics, and simplified two-sided electrical/thermal access. Described techniques provide more compact and more reliable packages, while enabling use of simplified manufacturing techniques that nonetheless enable a high degree of flexibility in constructing a wide range of semiconductor modules, among other advantages.

In described example techniques, at least one semiconductor die is provided on a substrate and encapsulated or embedded within an insulator, such as a dielectric layer or an air cavity. A second substrate may be positioned on the first substrate with the semiconductor die and the insulator positioned between the first substrate and the second substrate. Vias through the second substrate, and/or through the dielectric layer may be used to provide a redistribution layer (RDL) that provides electrical access to, and control of, the semiconductor die.

Using these and similar structures, many different embodiments may be constructed, using many different fabrication methods. For example, the one or more semiconductor dies may be disposed within one or more cavities. For example, when a second substrate is used to enclose or encapsulate a semiconductor die positioned on or in a first substrate, one or more cavities may be formed in either or both of the first substrate and the second substrate.

A RDL may be provided for the semiconductor die(s) at a single plane or layer within the resulting module. For example, when the semiconductor die includes a transistor, source, gate, and drain contacts of the transistor may be redistributed to a single metallization layer. For example, when a second substrate is included, the RDL may be provided at a layer of the module that is on a surface of the second substrate that is opposed from the first substrate. In other examples, the RDL may be provided at a layer of the module that is between the first substrate and the second substrate. In still other examples, contacts for the semiconductor die may be distributed to opposed sides of the module.

Example embodiments may have electrical connectivity on a top and/or bottom surface, and may have thermal conductivity on a top and/or bottom surface of the semiconductor module. For example, the semiconductor module may have electrical connectivity on a top surface, and thermal conductivity at a bottom surface.

Mechanical devices may be fabricated and integrated with the semiconductor die within the semiconductor module. For example, a micro-electronic mechanical systems (MEMS) device may be incorporated. For example, MEMS devices may be incorporated to provide a fast, galvanically isolated electromechanical solid state relay, which may be used, e.g., as a circuit breaker that provides advantages of both electromechanical and solid state circuit breakers.

In other examples, magnetic elements may be included instead of, or in addition to, semiconductor devices. Metal layers or traces may be used to provide windings around the magnetic element(s) that enable construction of transformers and other inductive devices.

Many different fabrication techniques may be used. For example, when standard dielectric and/or semiconductor materials are used, standard fabrication techniques may be incorporated to enable construction of described devices in a fast, inexpensive, and reliable manner. For example, when a second substrate includes Silicon, then common etching techniques may be used to provide through-Silicon-vias (TSVs) for use in constructing a RDL. In contrast, as referenced above, conventional embedded packaging techniques using organic materials or other encapsulants may require more expensive drilling techniques, such as laser drilling, to provide for electrical connections.

In some embodiments, when Silicon is used for a first and second substrate, wafer-to-wafer bonding may be used, followed by singulation of individual semiconductor modules. In other embodiments, semiconductor devices may be disposed on wafer panels followed by singulation/dicing, and then an addition of a second substrate may be provided.

In this way, the second substrate and/or dielectric layer, and included vias used to form a RDL, may partially or completely replace wirebonds or other conventional interconnect techniques. Further, as the second substrate may be provided using Silicon, or variations thereof (e.g., Silicon Carbide (SiC)), active or passive devices may be included in the second substrate, thereby adding flexibility to available design choices for a module, while further decreasing the module size. Thus, described techniques may be used to augment or replace conventional semiconductor packages, including for high-power semiconductor devices and modules.

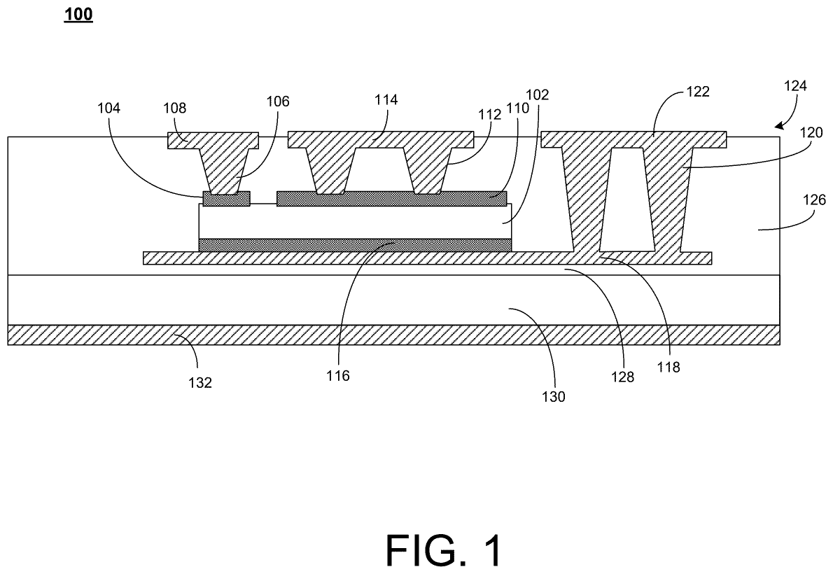

FIG. 1 is a cross-sectional view of a semiconductor module 100 according to example embodiments. In the example of FIG. 1, a semiconductor die 102 is illustrated as a transistor having a gate pad 104, source pad 110, and drain pad 116. For example, the semiconductor die 102 may represent a Silicon or Gallium Nitride based transistor, which may be provided with low on-resistance, reduced parasitics, fast and efficient switching, and other benefits described herein, including improved capability for operating in high current, high power, and high temperature environments. In other embodiments, the semiconductor die 102 may include an Insulated Gate Bipolar Transistor (IGBT), Silicon Carbide (SiC) diodes, or thyristors. Further, these and other devices, and various combinations thereof, may benefit from the reliability and flexibility provided by described encapsulation and electrical routing techniques, described in more detail, below.

For example, the gate pad 104 is illustrated as having a gate connection or gate contact 108 that is formed using a gate via 106. Similarly, the source pad 110 is illustrated as having a source connection or source contact 114 that is formed using source vias 112. The drain pad 116 is disposed on a metal layer 118 that extends beyond the semiconductor die 102 and beyond vias 120 to enable electrical contact with a drain connection or drain contact 122. In FIG. 1, any suitable metal, e.g., copper, may be used to form the various electrical contacts and/or layers.

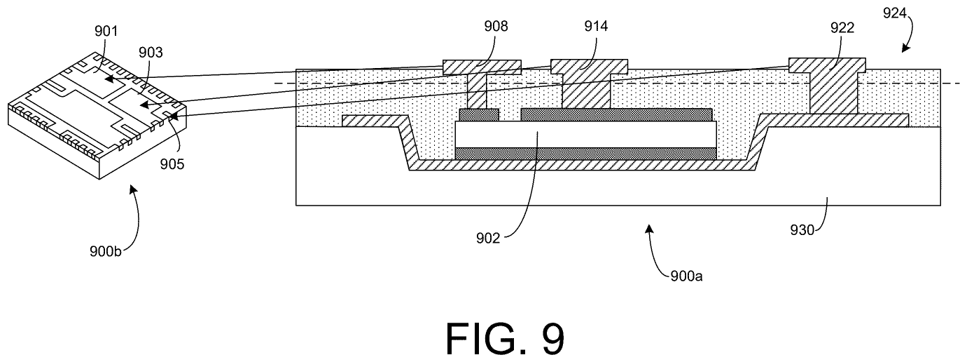

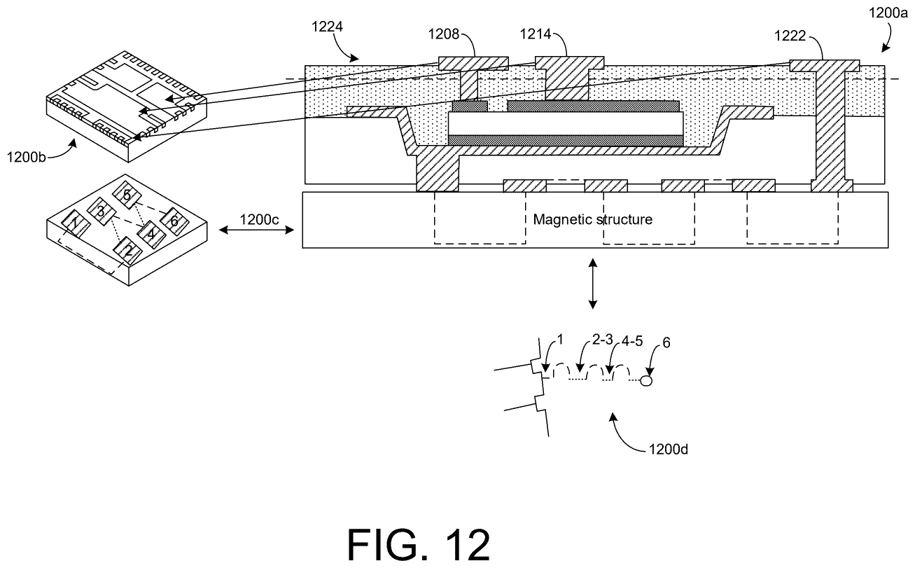

Accordingly, the gate contact 108, the source contact 114, and the drain contact 122 may be included in a metallization layer that provides a RDL 124 that enables the type of flexible, reliable connections of the semiconductor die 102 to other components within a larger semiconductor module referenced above, and illustrated and described in more detail in various example embodiments provided below. Put another way, the RDL 124 provides easy and reliable contact to the semiconductor die 102, as shown, for example, in FIGS. 9 and 12.

Further in FIG. 1, a dielectric 126 provides encapsulation of the semiconductor die 102. The encapsulating dielectric 126 may be provided using any suitable nonconductive dielectric material, including, e.g., silicon oxide, silicon nitride, silicon oxynitride, or polyimide (PSP), to name a few. Such materials are widely used in semiconductor processing for their ability to provide insulation, e.g., when providing separation between metallization layers. In FIG. 1, however, the dielectric 126 provides full encapsulation of the semiconductor die 102, extending around the semiconductor die 102, and the vias 106, 112, 120, as well as around the metal layer 118. In particular, a dielectric layer 128 provides separation between the encapsulated semiconductor die 102 and a substrate 130.

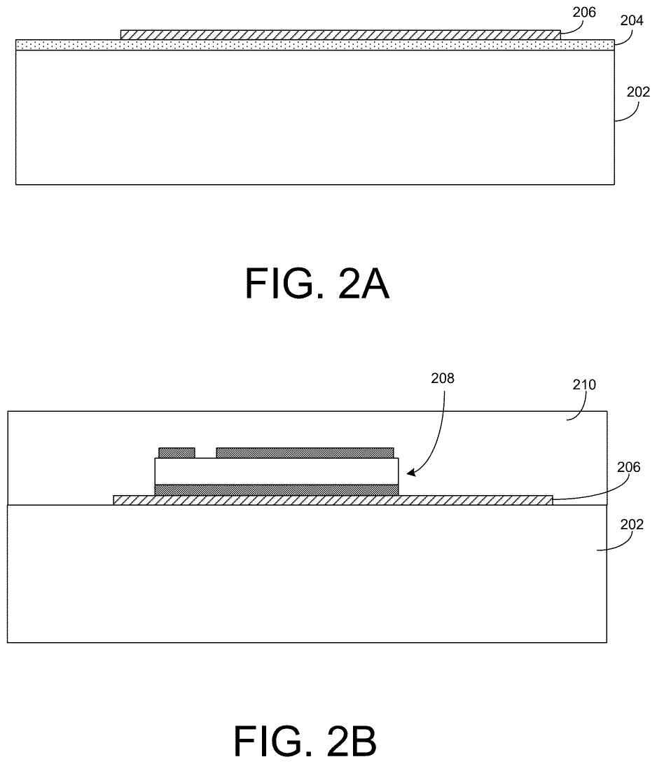

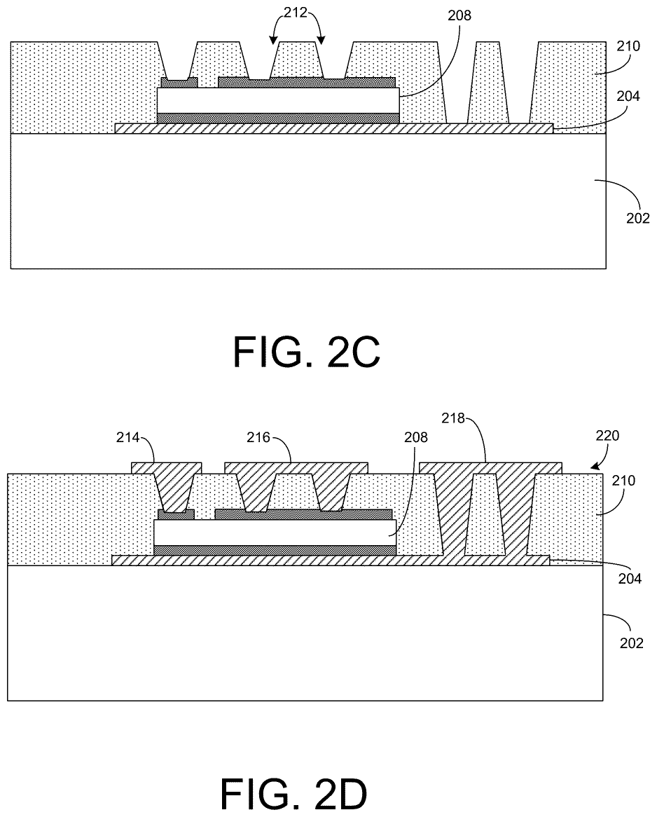

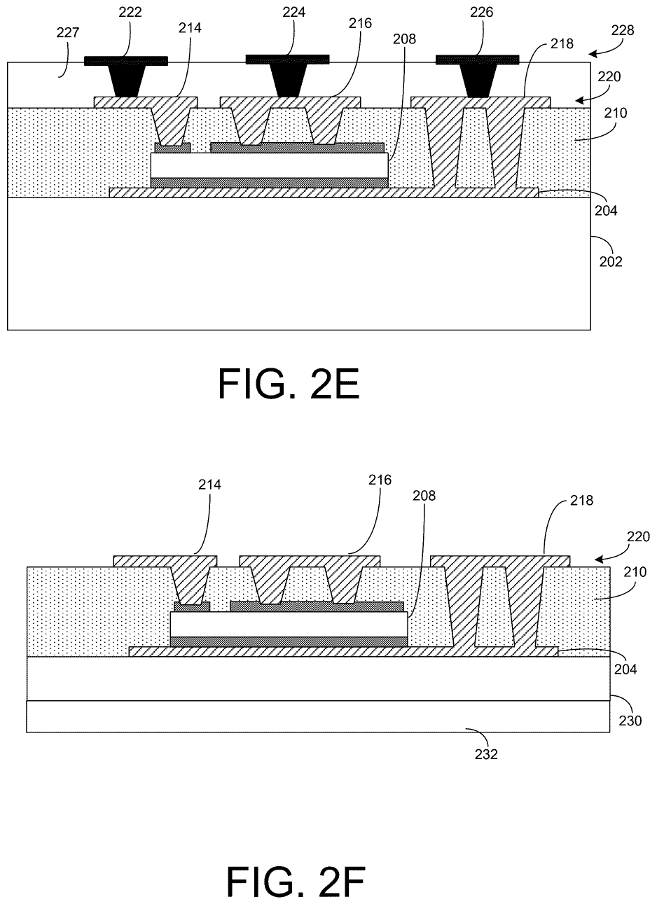

The substrate 130 may be provided using any suitable material, including a semiconductor material such as Silicon, or other suitable materials, including, e.g., metal, ceramic, or glass. A heatsink 132 may be attached to the substrate 130. As just referenced, in FIG. 1, the dielectric layer 128 provides electrical isolation between the semiconductor die 102 and the substrate 130, enabling use of the heatsink 132. In other implementations, e.g., as shown in the examples of FIGS. 2B-2F, the metal layer 118 may be formed directly on the substrate 130, e.g., may not be electrically isolated from the substrate 130.

Use of the substrate 130 and the encapsulating dielectric 126 enable use of otherwise standard techniques for fabricating or processing the semiconductor module 100, as illustrated and described in more detail, below, with respect to FIGS. 2A-2F. The dielectric 126 is capable of being used as an encapsulant in part because of the superior thermal management techniques described herein, including the potential for topside and/or bottom side cooling, where bottom side cooling is illustrated in FIG. 1 through the use of the dielectric layer 128 and the heatsink 132.

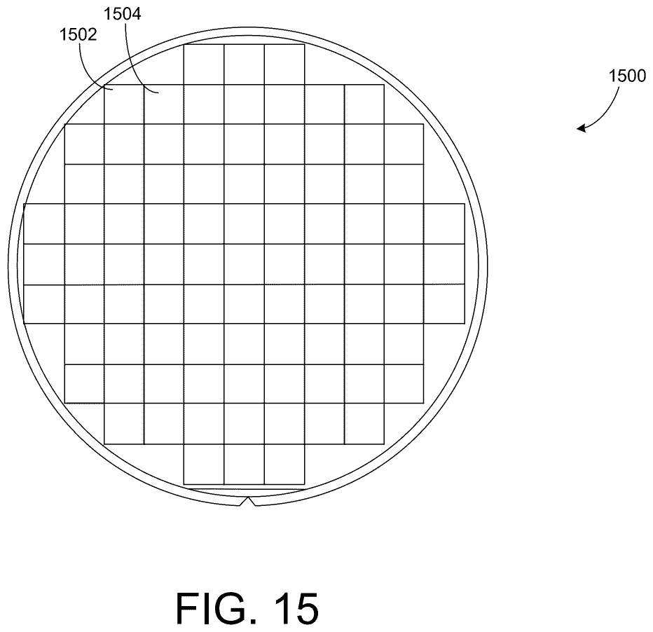

FIG. 2A is a cross-sectional view of an example processing stage for forming the semiconductor module of FIG. 1. In FIG. 2A, a substrate 202 may represent any suitable substrate, such as a silicon substrate. For example, a 300 mm silicon wafer may be used, as described in more detail with respect to FIGS. 14 and 15.

Then, a dielectric layer 204 may be deposited across the silicon wafer, using any suitable deposition technique. The dielectric layer 204 corresponds to the dielectric layer 128 of FIG. 1, and provides electrical isolation between the substrate 202 and a metal layer 206, where the metal layer 206 corresponds to the metal layer 118 of FIG. 1.

The metal layer 206 of desired thickness and patterning may be deposited across the Silicon wafer. That is, FIG. 2A illustrates the metal layer 204 on one reticle of a wafer, where the metal layer 204 may be copied a desired number of times across the wafer to achieve multiple instances of the semiconductor module 100 of FIG. 1 for one wafer.

In FIGS. 2B-2F, the dielectric layer 204 is omitted, thereby enabling electrical connectivity to the substrate 202. That is, as shown in FIG. 2B, the metal layer 206 is formed directly on the substrate 202. Then, a semiconductor die 208 is attached (e.g., soldered or sintered) to the metal layer 206. That is, multiple instances of the semiconductor die 208 may be attached across the wafer for each semiconductor module to be formed.

Then, a dielectric layer 210, corresponding to the dielectric layer 126 of FIG. 1, may be deposited across the wafer, including the substrate 202 and the metal layer 206 of FIG. 2B. Standard processing techniques may be used to achieve any desired patterning of the dielectric layer 210 across the wafer and to achieve a substantially flat surface of the dielectric layer 210. Accordingly, as described and illustrated with respect to FIG. 1, and as shown in FIG. 2B, the semiconductor die 208 is entirely encapsulated or embedded by the dielectric layer 210.

In FIG. 2C, vias 212 are formed, e.g., etched, to establish contact with the semiconductor die 208. Then, in FIG. 2D, and consistent with the example of FIG. 1, metal may be deposited or otherwise provided within the vias 212 to provide a gate contact 214, a source contact 216, and a drain contact 218. As also described with respect to FIG. 1, the contacts 214, 216, 218 provide a RDL 220 that enables flexible, reliable, and straightforward connection to the semiconductor die 208.

FIG. 2E is a cross-sectional view of an example processing stage for forming the semiconductor module of FIG. 2D that illustrates additional example optional contacts 222, 224, 226 formed in vias in, and providing electrical connection through, a dielectric layer 227. That is, the contacts 222, 224, 226 represent metal contacts that provide a gate contact 222, a source contact 224, and a drain contact 226 that collectively provide a second RDL 228. The second RDL 228 thus enables additional connectivity options for the semiconductor die 208. More generally, any arbitrary number or layers of such RDLs may be provided, as needed to enable desired connections to the semiconductor die 208.

FIG. 2F is a cross-sectional view of a final processing stage for the semiconductor module of FIG. 2B. In FIG. 2F, the substrate 202 of FIG. 2E undergoes grinding or other type of thinning to provide thinned substrate 230. A backside metal 232 may then be added, e.g., to enable further connection for the semiconductor die 208 (e.g., to a drain connection thereof). Singulation or other dicing may then proceed to obtain individual or groups of semiconductor modules. The resulting example embodiment of FIG. 2F may thus be observed to be similar to that of FIG. 1 and FIG. 2A, but without the electrical isolation provided by the dielectric layer 128 of FIG. 1 or the dielectric layer 204 of FIG. 2A.

The example embodiments of FIGS. 1 and 2A-2F, along with various other example embodiments described below, provide multiple benefits. For example, use of a sufficiently high-quality dielectric as an encapsulant ensures high-voltage isolation concurrently with good thermal conduction, and, in particular, provide superior thermal performance to conventional substrates, such as Active Metal Brazing (AMB) or Direct-Bond Copper (DBC) substrates.

Described techniques enable via formation using etching techniques (rather than drilling, e.g., laser drilling), so that via formation is inexpensive with very good depth control. Further, described techniques accelerate time from request to delivery of modules. For example, construction may be performed using standard semiconductor fabrication and test techniques (and automation), without requiring a distinct packaging process or toolset. Similarly, semiconductor design tools may be used for automation and for extraction of electrical and mechanical properties such as device parasitics.

In addition to improved device parasitics, package parasitics are improved via controlled and optimized impedances in a redistribution layout. Further, example embodiments provide excellent thermal properties, including the potential for dual-side cooling with an optimized thermal path. Described modules may be easily expanded to include multiple (same or different) base devices, as well as embedded passive devices and active circuitry, including MEMS.

Various components and elements are described above with respect to FIG. 1 and FIGS. 2A-2F, and below, but should be understood to be by way of non-limiting example. For example, a substrate used may include Si, SiC, GaN, Sapphire, Diamond, or similar semiconducting material or isolating material. Accordingly, any specific nature or property of such a substrate (e.g., electrical, thermal, mechanical, chemical, or physical property) may be engineered/selected. Substrates may be processed at wafer level at standard wafer diameters (e.g. 2″, 4″, 6″, 8″, 12″) and/or may originate from sliced ingots. Substrates may have an initial targeted thickness and may be thinned at a further processing step (e.g., after die attach and interlayer dielectric (ILD)/RDL) to achieve overall total thickness target of end product. Substrates may be pre-processed to include semiconductor features (e.g., transistors made by standard semiconductor wafer fabrication techniques such as doping or photo development), and/or may be pre-processed to include other features such as MEMS or metal-insulator-metal (MIM) structures such as MIM capacitors.

One or more of many types of backside surface treatments may be applied. For example, backside treatments (e.g. after wafer thinning) may be providing using known/standard processing techniques. For example, copper or diamond may be used for good thermal conductivity and/or heat spreading. Metallization with plating and/or an inert dielectric may be provided for passivation. Mechanical bonding (e.g., solder, sinter, etch) may be used.

Mechanical bonding to environment and/or electrical connection may be provided using, e.g., solder, sinter, and/or etch. Backside surface treatments also provide mechanical stress control, e.g., to avoid wafer bowing and matching of thermal coefficients of thermal expansion. For example, a back-side metal (e.g., copper or aluminum with a plating/surface treatment such as silver or a silver alloy for contact formation and/or with a non-conducting material (e.g., a dielectric) for passivation) may be deposited by sputtering or similar techniques. In addition to controlling wafer bow and other mechanical stresses, metal layer thickness may be determined or optimized for, e.g., targeting a minimum/maximum resistance value for a given layout (width, length), enabling target fusing current goals such as a minimum value, a targeted value or a maximum value, and/or achieving cost targets (e.g., using a thinner layer to lower cost).

As noted above, dielectric layers may be formed using any suitable dielectric material, which may be deposited using standard wafer processing techniques such as chemical vapor deposition (CVD), lamination, sputtering, or printing (e.g., screen-printing), and, as needed, associated processing such as photo-resist/development, etching, drilling, grinding, or polishing. A composition and thickness of each layer may correspond to, and be appropriate for, a target stand-off voltage, electrical potential desired to be blocked, and/or leakage current targets, e.g., such that the embedded semiconductor dies substantially determines the overall standoff voltage and/or leakage currents (e.g., using a thinner ILD for low-voltage applications and thicker ILD for high-voltage applications).

Embedded semiconductor dies that may be included in described embodiments may include, in addition to the examples referenced above, non-power semiconductor devices such as digital, analog, or mixed signal Integrated Circuit (IC) devices, e.g., a gate-driver IC. In addition to Si, SiC, or GaN, compound devices, such as silicon-on-insulator (SOI) or GaN on Si may be used. Embedded devices may also include non-semiconductor, passive or discrete electronic components, such as a resistor, capacitor, or inductor realized in any form (e.g., semiconductor, thin film, Multi-Layer Ceramic Chip (MLCC) or otherwise). More generally, virtually any device having a thickness compatible with described embedding techniques may be used, some of which are described and illustrated below, including, e.g., MEMS component(s) or a copper block.

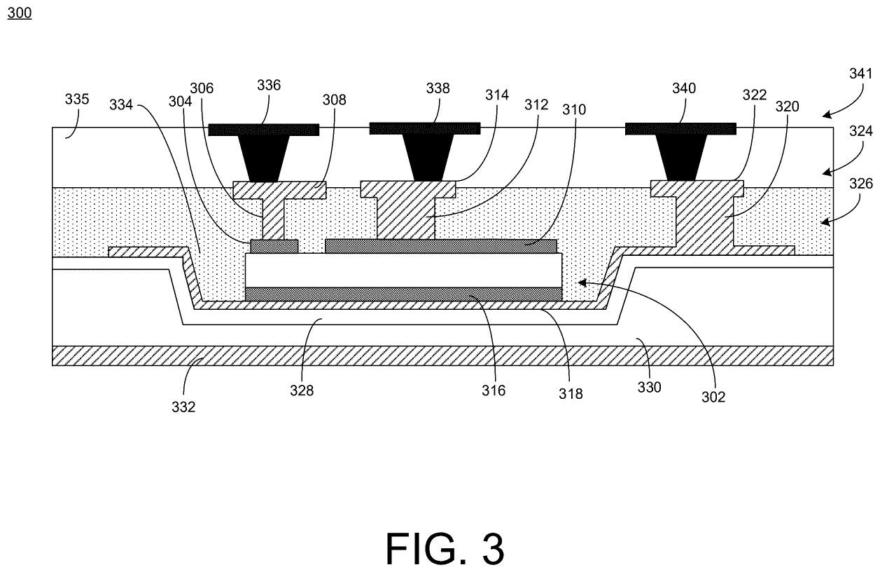

A single semiconductor die or multiple (perhaps different) dies may be included in a single module. For example, a SiC transistor may be embedded with a Si gate-drive IC and decoupling capacitors within a single embedded module. An entire sub-circuit, circuit or even a full system (e.g., power system) may be included. Different dies may have different thicknesses, and may be die-attached using any known/common technique(s). Such techniques may include, but are not limited to, solder, diffusion solder, sinter, epoxy/glue or other methods of achieving mechanical bonding and/or electrical conductivity. One or more dies may be included in a flip-chip orientation (e.g., inverted as compared to the examples of FIGS. 1 and 2A-2F), with included metals being patterned accordingly. For example, for embodiments with cavities such as in FIG. 3, below, vertical current flow MOSFETs may be positioned with gate and source terminals facing into the cavity with a drain facing up/out of the cavity.

Vias may be formed using standard semiconductor fabrication techniques at wafer level such as etching with resist (photo) or other known/standard techniques. Etching may be done using a selective chemical process that has a faster etch-rate in the dielectric compared to the metal for contacting, such that good depth-control can be achieved. Vias may have any shape and/or size that is found relevant and/or optimal for processing, cost and electrical properties. Multiple vias may be formed in parallel to provide an array.

Each RDL may be formed as a single layer (e.g., top metal) or may be an arbitrary count of layers (e.g., interleaving layers of ILD and RDL with vias connecting one metal layer to the next through the ILD)). Similar to other metal layers discussed above, each RDL may be formed using any metal (pure or alloy) that typically has high electrical conductivity, and may be plated or surface treated. Metal used may have a thickness relevant for achieving specific target resistance, target fusing current, or target electro-migration target, e.g., on the order of about 1 um to 50 um. Metal may be deposited by standard wafer processing techniques such as CVD, sputtering, or similar technique(s), or may be plated by electroless or electrolysis or other known techniques.

An RDL may be passivated by conducting or non-conducting passivation material/techniques. An RDL may be processed using known techniques for purposes including but not limited to implementation of MIM-capacitors, embedded inductors or resistors, or MEMS. With such integrations, many different use cases may be achieved, some of which are described and illustrated below in detail, such as integrated liquid cooling, sensors, or mechanical micro relays.

FIG. 3 is a cross-sectional view of a semiconductor module 300 with a cavity 334 according to example embodiments. Similar to FIG. 1, FIG. 3 includes a semiconductor die 302 with a gate pad 304 connected through a gate via 306 to a gate contact 308, a source pad 310 connected through a source via 312 to a source contact 314, and a drain pad 316 connected to a metal layer 318 and thereby to a drain contact 322 through a drain via 320. In this way, a RDL 324 is formed on a surface of a dielectric 326 that embeds and encapsulates the semiconductor die 302.

A dielectric layer 328 (similar to the dielectric layer 128 of FIG. 1 or the dielectric layer 204 of FIG. 2A) separates the metal layer 318 from a substrate 330. A metal layer 332 is disposed on a surface of the substrate 330 that is opposed from the semiconductor die 302. Similar to the example of FIG. 2E, additional example optional contacts 336, 338, 340 are encapsulated in a dielectric layer 335. That is, the contacts 336, 338, 340 represent metal contacts that provide a gate contact 336, a source contact 338, and a drain contact 340 that collectively provide a second RDL 341. The second RDL 341 thus enables additional connectivity options for the semiconductor die 302. More generally, as noted with respect to FIG. 2E, any arbitrary number of such RDLs may be provided, as needed to enable desired connections to the semiconductor die 302.

In addition to compatibility with all potential variations of the embodiments of FIGS. 1 and 2A-2F, the inclusion of the cavity 334 in the embodiment of FIG. 3 enables precise and secure placement and embedding of the semiconductor die 302. The example embodiment of FIG. 3 may be constructed very similarly to the example of FIGS. 2A-2F. For example, prior to the operations of FIGS. 2A-2F, the cavity 334 may be formed within the substrate 202 of FIG. 2A, after which remaining operations of FIGS. 2A-2F may proceed.

In FIG. 3, the cavity 334 may be formed using wafer processing techniques (or combinations thereof), including, but not limited to, the following techniques. For example, dry or wet etching techniques may be used, such as reactive ion etching (RIE) or Tetramethylammonium Hydroxide (TMAH) based etching, respectively. The cavity 334 may also be formed using mechanical grinding, drilling, or stamping. In other examples, rather than forming the cavity within an existing substrate, mesa creation on a surface of a substrate may be performed to define a cavity relative to mesas that are formed using deposition (e.g., through CVD, sputtering, or lamination).

Although FIG. 3 illustrates a single cavity with the single semiconductor die 302, other example semiconductor modules may have multiple cavities, each with one or more semiconductor dies, and/or may have a single cavity with two or more dies. Different cavities in a single module/wafer may have different depths.

In other implementations, a single cavity may have local areas of different depths. For example, half of a cavity may be of one depth to fit one embedded die, whereas the other half of cavity may be deeper to fit another embedded die having a different thickness. In FIG. 3, a depth of the cavity 334 is similar to a thickness of the semiconductor die 302. More generally, a depth of a cavity may substantially match the thickness of an embedded die or may be deeper or shallower in depth.

When one or more embedded dies are disposed within one or more cavities, a semiconductor die(s) may be embedded inside a cavity, on a mesa (outside of a cavity), and/or a combination thereof (if multiple dies are included). If multiple dies are included with multiple thicknesses, then, as just referenced, the dies may be assembled in cavities of different depths, where each cavity depth is in part determined by the corresponding embedded die thickness. In other implementations, die(s) may be provided in a single cavity of a uniform depth and/or in a single cavity of a varying depth.

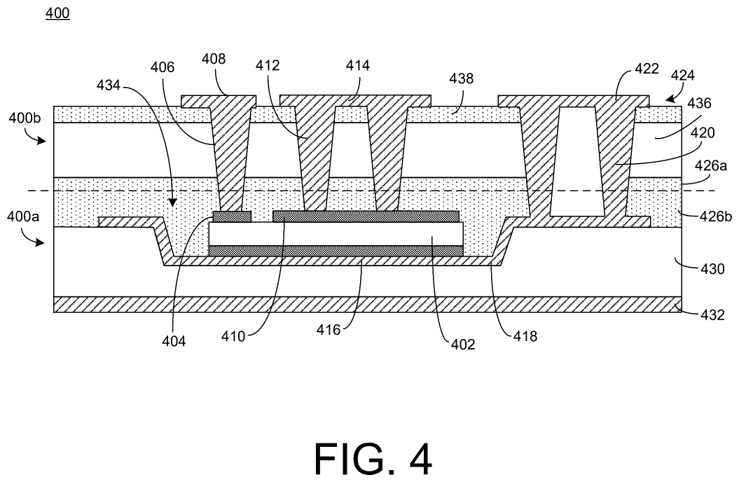

FIG. 4 is a cross-sectional view of an example embodiment of a semiconductor module 400 with a second substrate. Similar to FIGS. 1 and 3, FIG. 4 includes a semiconductor die 402 with a gate pad 404 connected through a gate via 406 to a gate contact 408, a source pad 410 connected through a source via 412 to a source contact 414, and a drain pad 416 connected to a metal layer 418 and thereby to a drain contact 422 through a drain via 420. In this way, a RDL 424 is formed on a surface of a dielectric 426b that embeds and encapsulates the semiconductor die 402.

In FIG. 4, similar to the examples of FIGS. 2B-2F, the metal layer 418 is disposed directly on a substrate 430. A metal layer 432 is disposed on a surface of the substrate 430 that is opposed from the semiconductor die 402. Similar to FIG. 3, the semiconductor die 402 is disposed within a cavity 434.

In FIG. 4, the semiconductor module 400 includes a first portion 400a having a second portion 400b disposed thereon. As referenced above and discussed in more detail, below, the semiconductor module 400 may be formed using wafer-to-wafer bonding, or at the panel/reticle level.

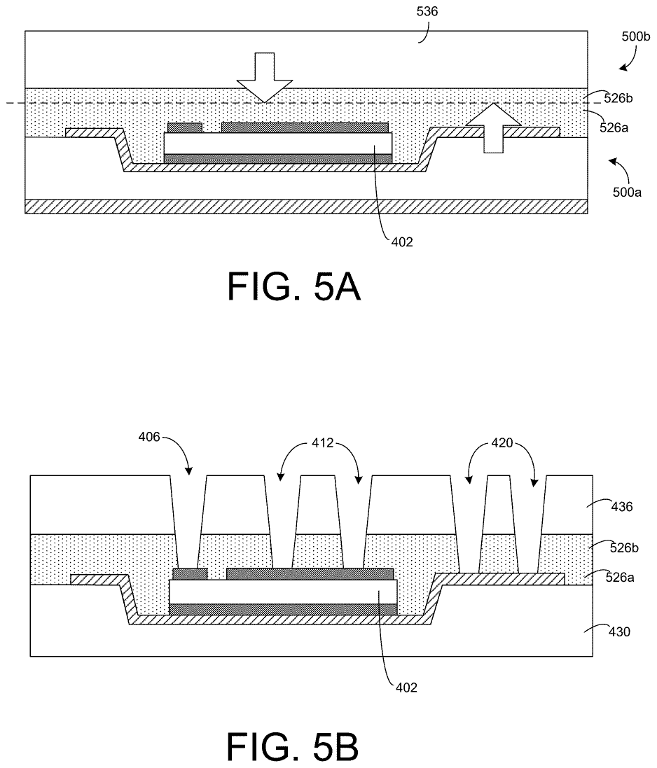

In either case, a dielectric layer 426a is joined with the dielectric layer 426b, as discussed in more detail, below, with respect to FIG. 5A. A second substrate 436 is adjacent to the dielectric layer 426a, with a dielectric layer 438 disposed on the second substrate 436. Accordingly, the vias 406, 412, 420 are formed through all of the dielectric layers 426a, 426b, the second substrate 436, and the dielectric layer 438, with the RDL 424 formed on the dielectric layer 438 in FIG. 4.

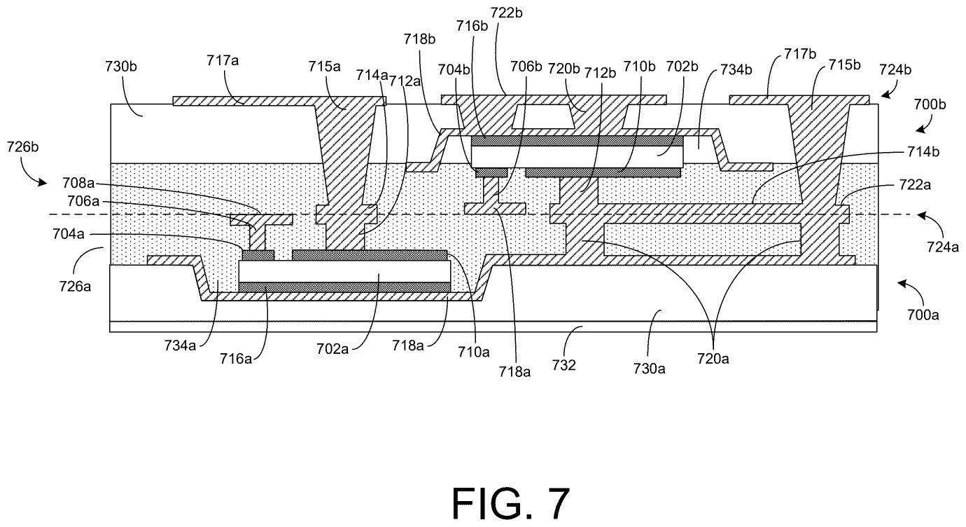

In addition to compatibility with all potential variations of the embodiments of FIGS. 1 and 2A-2F, the inclusion of the second portion 400b in the embodiment of FIG. 4 enables many different embodiments obtainable by substitution of different materials and/or thicknesses used for the second portion 400b, e.g., for the second substrate 436. For example, when the second substrate 436 includes silicon, one or more additional semiconductor dies may be included therein, as shown, for example, in the example embodiment of FIG. 7. Then, such dies may be connected with the semiconductor die 402 to achieve a design goal, e.g., using multiple interconnected devices to form a half-bridge.

FIGS. 5A and 5B are cross-sectional views of a first processing stage and a second processing stage for forming the example embodiment of FIG. 4. In FIG. 5A, a first portion 500a is constructed using the techniques of FIGS. 2A and 2B, with the cavity of FIG. 3. As shown by the dashed line and arrows in FIG. 5A, a second portion 500b, is joined to the first portion 500a. For example, the second portion 500b may be part of a lid wafer bonded to a wafer that includes the first portion 500a. For example, opposing planar dielectric surfaces 526a, 526b of the portions 500a, 500b may be bonded to one another to dispose a second substrate 536 over the semiconductor die 402.

In FIG. 5B, the gate via 406, source vias 412, and drain vias 420 are formed, e.g., by etching through the second substrate 536 of FIG. 5A to form the second substrate 436 of FIG. 4, and by etching through the bonded dielectric layers 526a, 526b to form the etched dielectric layers 426a, 426b of FIG. 4. Accordingly, the gate contact 408, the source contacts 414, and the drain contacts 422 of FIG. 4 may be provided, as shown in FIG. 4, to thereby provide redistribute all of the electrical signals of the semiconductor die 402 to a top surface of the module 400 as the RDL 424 of FIG. 4.

When wafer-to-wafer bonding is used, the second portion 500b may be understood to be part of a lid wafer bonded to a top surface of an underlying wafer of the first portion 500a. For example, such bonding may include any suitable bonding technique(s), including hybrid bonding (in which electrical contact points between the substrate surface of the first portion 500a and the lid surface of the second portion 500b), or wafer bonding (such as all-oxide bonding between flat surfaces of dielectric layers 526a, 526b, with electrical contacts made by vias after the bonding operation, as shown in FIG. 5B).

Once the structure of FIG. 4 is created, further processing may be performed. For example, the further processing of FIG. 2E, including addition of further RDLs, may be performed. More generally, all of the variations discussed above with respect to FIGS. 1-3 may be included, as well as many other variations, some of which are discussed below in the context of other example embodiments.

In the example embodiments of FIGS. 4, 5A, and 5B, an upper or lid wafer (e.g., of the second portion 500b of FIG. 5A) may include an unprocessed or processed version of the substrate 436/536. For example, included or processed features may include any semiconductor circuitry and/or associated wafer processing such as doping. Features may include passive elements, such as copper blocks, resistors, capacitors, or inductors. Features may include MEMs or any other device that may be fabricated on a wafer.

Either of the substrates 430 and/or 436/536 may be made, for example, from an isolating material (e.g., Sapphire), a semiconductor material (e.g., silicon or GaN) or a conducting material (e.g., a metal, such as copper). The substrates 430 and/or 436/536 may be the same or different ones of these or other materials. When the material(s) includes silicon, the various vias 406, 412, 420 may be formed as through-silicon vias (TSVs). Either or both wafers used may be any desired and available thickness.

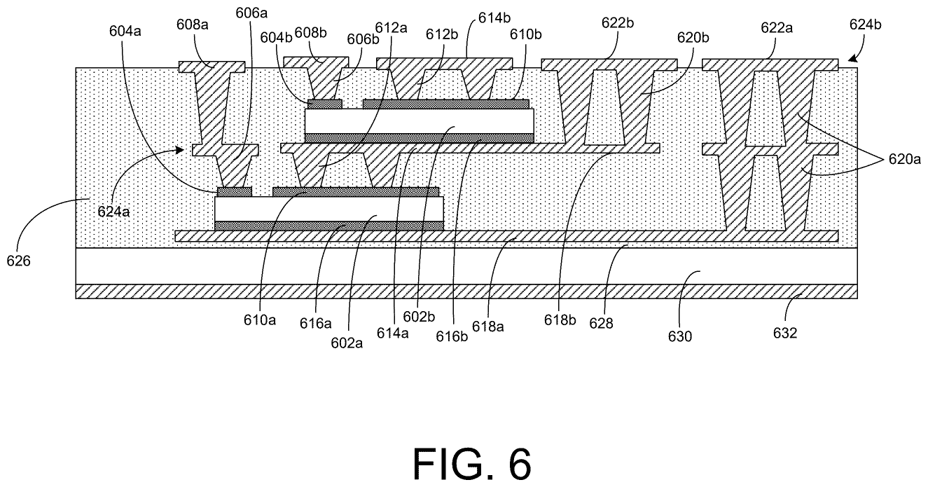

FIG. 6 is a cross-sectional view of an example embodiment with stacked devices. FIG. 6 includes a semiconductor die 602a with a gate pad 604a connected through a gate via 606a to a gate contact 608a, a source pad 610a connected through a source via 612a to a source contact 614a, and a drain pad 616a connected to a metal layer 618a and thereby to a drain contact 622a through a drain via 620a. In this way, a RDL 624a is formed in a dielectric 626 that embeds and encapsulates the semiconductor die 602a.

In FIG. 6, similar to the examples of FIGS. 1 and 2A, the metal layer 618a is disposed on a dielectric layer 628, which is itself disposed on a substrate 630. A metal layer 632 is disposed on a surface of the substrate 630 that is opposed from the semiconductor die 602a.

FIG. 6 further illustrates a semiconductor die 602b with a gate pad 604b connected through a gate via 606b to a gate contact 608b, a source pad 610b connected through a source via 612b to a source contact 614b, and a drain pad 616b connected to a metal layer 618b and thereby to a drain contact 622b through a drain via 620b. In this way, a RDL 624b is formed on a surface of the dielectric 626 that embeds and encapsulates the semiconductor die 602b.

The embodiment of FIG. 6, and variations thereof, may be formed by using (e.g., iterating) the techniques described above with respect to FIGS. 2A-2F. Other variations may be included, e.g., either or both of the semiconductor dies 602a, 602b may be disposed within a cavity. Moreover, although only the semiconductor dies 602a, 602b are illustrated in FIG. 6, virtually any desired number of semiconductor dies may be included. The various semiconductor dies and associated layers may be of any desired thickness(es), and may be the same or different thicknesses as one another. FIG. 6 may be used to implement a power half-bridge, but many other power-or non-power circuits may be constructed, e.g., full-bridge, T-type, parallel, anti-parallel, series, or anti-series.

FIG. 7 is a cross-sectional view of an example embodiment with stacked modules 700a, 700b. FIG. 7 includes the stacked module 700a with a semiconductor die 702a with a gate pad 704a connected through a gate via 706a to a gate contact 708a, a source pad 710a connected through a source via 712a to a source contact 714a, and a drain pad 716a connected to a metal layer 718a and thereby to a drain contact 722a through a drain via 720a. In this way, a RDL 724a is formed at a junction of a dielectric 726a and a dielectric 726b, similar to the embodiment of FIG. 4, where the dielectric 726a embeds and encapsulates the semiconductor die 702a. As further illustrated, the semiconductor die 702a is disposed within a cavity 734a, similar to the embodiment of FIG. 3.

In FIG. 7, the metal layer 718a is disposed on a substrate 730a. A metal layer 732 is disposed on a surface of the substrate 730a that is opposed from the semiconductor die 702a.

FIG. 7 further illustrates the stacked module 700b with a semiconductor die 702b within a cavity 734b having a gate pad 704b connected through a gate via 706b to a gate contact 708b, a source pad 710b connected through a source via 712b to a source contact 714b, and a drain pad 716b connected to a metal layer 718b and thereby to a drain contact 722b through a drain via 720b. In this way, a RDL 724b is formed on a surface of the dielectric 726b that embeds and encapsulates the semiconductor die 702b.

In FIG. 7, the metal layer 718b is disposed on a substrate 730b. A via 715a through the substrate 730b and the dielectric 726b is used to establish a source contact 717a for the semiconductor die 702a. A via 715b through the substrate 730b and the dielectric 726b is used to establish a contact 717b connected to the drain contact 722a of the semiconductor die 702a and to the source contact 714b of the semiconductor die 702b.

The embodiment of FIG. 7, and variations thereof, may be formed by using (e.g., iterating) the techniques described above with respect to FIGS. 2A-2F and FIGS. 5A, 5B.

Other variations may be included, e.g., FIG. 7 illustrates two stacked modules 700a, 700b, but an arbitrary number of modules may be stacked. In FIG. 7, the stacked modules 700a, 700b include the same types of semiconductor dies 702a, 702b, but different devices may be used, as well. Similarly, the substrates 730a, 730b may the same material, thickness, or may be different.

Bonding techniques for bonding the modules 700a, 700b may include wafer bonding (e.g., dielectric-to-dielectric), hybrid bonding (e.g., a mix of conductor and dielectric, as shown), or any other suitable bonding method. In some embodiments, one wafer may be flip-mounted (e.g., flip-chip mounted) relative to the other wafer, or the wafers may have the same orientation as one another. Similarly, wafers and included devices may have the same grid/rotation as one another, or may be rotated with respect to each other, with any arbitrary or desired target angle of the rotation.

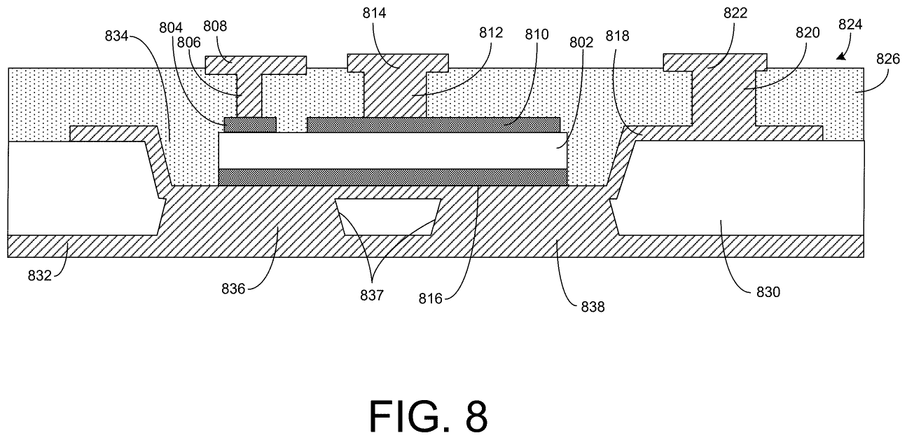

FIG. 8 is a cross-sectional view of an example embodiment of a semiconductor module with backside contacting. In FIG. 8 a semiconductor die 802 has a gate pad 804 connected through a gate via 806 to a gate contact 808, a source pad 810 connected through a source via 812 to a source contact 814, and a drain pad 816 connected to a metal layer 818 and thereby to a drain contact 822 through a drain via 820. In this way, a RDL 824 is formed on a surface of a dielectric 826 that embeds and encapsulates the semiconductor die 402 within a cavity 834.

In FIG. 8, the metal layer 816 is disposed directly on a substrate 830 and on backside contacts 836, 838 connected to a metal layer 832. As shown, the backside contacts are formed using vias 837. In this way, electrical connectivity to the drain pad 816 may be established at both surfaces of the module of FIG. 8.

In FIG. 8 and similar examples, a backside (drain) of the semiconductor die 802 may be reached by various techniques. For example, wet or dry etching, or other techniques used to etch silicon, may be used. Mechanical techniques, such as drilling, grinding, or milling/machining may be used. Other potential techniques include laser or plasma drilling.

FIG. 8 illustrates an example in which parallel TSVs or other vias 837 are used to provide a patterned metal contact. In other examples, the substrate 830 may be thinned to the point that the metal layer 818 directly contacts the metal layer 832.

In other aspects and examples, the semiconductor die 802 may be provided with a low-ohmic contact at the backside (e.g., drain) by any suitable method(s). For example, techniques of conductor deposition (e.g., patterned or unpatterned) may be used, such as CVD, sputter, or electro-plating. In other examples, die-attach of a conductor plug (e.g., a copper puck) may be performed, e.g., may be soldered, diffusion soldered, sintered, or Anisotropic Conductive Adhesive (ACA) bonded.

Varying levels of thickness may be chosen for one or more of the metal layer 818, the backside contacts 836, 838, and/or the metal layer 832. During etching, a stop material may be used at the bottom of the cavity 834 for backside operations, i.e., a backside etch-stop may be provided. In other examples, a shim may be installed between the semiconductor die and a bottom of the cavity 834 (e.g., a copper piece) to aid in stopping back-side grinding/etching/drilling. In this way, access to the drain contact 816 (or other conductive element of the semiconductor die 802) may be provided without burrowing completely through to the semiconductor die 802 itself.

FIG. 9 is an example embodiment illustrating ease of connection of a semiconductor module constructed using described techniques to provide footprint matching with existing packages (or other desired footprint(s)). In FIG. 9, a semiconductor module 900a is illustrated that is similar to the embodiment of FIG. 3, but without the insulating layer 328. Or, put another way, similar to the embodiment of FIG. 2F, but with the cavity 334 of FIG. 3. However, the example module 900a of FIG. 9 is not limiting, and any of the described embodiments, or variations thereof, may be substituted for the module 900a.

In FIG. 9, the module 900a includes a semiconductor die 902 and a RDL 924 that includes gate contact 908, source contact 914, and drain contact 922, which are constructed using the above-described techniques. Further elements of the module 900a correspond to earlier-described elements, and are not labeled or described here separately for the sake of brevity.

Further in FIG. 9, a package 900b constructed using the module 900a is illustrated as having a Quad Flat No-lead (QFN) footprint. FIG. 9 illustrates that the module 900a may be constructed with the contacts 908, 914, and 922 and/or the RDL 924 matching and thus providing the footprint of the package 900b, including contacts 901, 903, 905. In other words, the module 900a illustrates a design approach in which the module 900a provides an embedded device engineered to have the same physical and electrical layout as the QFN package 900b.

More specifically, the QFN package 900b refers to a type of surface-mount integrated circuit package with no protruding leads, and with the electrical contacts 901, 903, 905 being flat and located on a bottom surface, typically allowing direct soldering onto a printed circuit board (PCB) (not shown in FIG. 9). Thus, by matching the footprint of the QFN package 900b, the module 900a can be seamlessly integrated into existing circuit board designs without requiring modifications to board layouts. Such compatibility ensures that the module 900a can replace or function interchangeably with traditionally packaged devices, while maintaining the same or better electrical connections and performance characteristics. In FIG. 9, the specific QFN footprint shown in the module 900b corresponds to a module with multiple different dies forming 2 half-bridges with corresponding gate-drivers, whereas the example of embedded module 900a is simplified for the sake of brevity and example, and does not explicitly show the corresponding number of embedded dies and connectivity

In one specific example embodiment, the embedded module 900a may be designed to replicate the footprint of a powerstage, which is a component that includes gate-driver circuits, high-side (HS) switches, and low-side (LS) switches. Gate-drivers are circuits that control the switching of power transistors, while high-side and low-side switches are typically metal-oxide-semiconductor field-effect transistors (MOSFETs) used in power management applications, such as voltage regulation or motor control. By matching this powerstage footprint, the embedded module 900a can serve as a direct substitute, acting as a second source that is form-fit-function compatible with a QFN powerstage product. As a result, the embedded module 900a fits the same physical space and pin layout while also performing the same or better electrical functions, providing a reliable option that does not require redesigning existing circuit boards or other packaging elements.

Additionally, the embedded module 900a offers enhanced thermal performance compared to traditional QFN packages. For example, conventional packages may be overmolded with epoxy molding compound (EMC), a plastic material that encapsulates a chip but has relatively poor thermal conductivity. In contrast, in one embodiment and using disclosed techniques, the embedded module 900a may include a heatsink attached to a surface of the substrate 930 of the module 900a, allowing improved heat dissipation in a direction away from a PCB. The substrate 930, as described herein, may include silicon or another material(s) with high thermal conductivity, to thereby transfer heat more effectively than the EMC used in traditional packages. Thus, the embedding process described herein effectively provides a package that enables the embedded module 900a to function as a traditionally packaged die, chip, System-on-Chip (SoC), or System-in-Package (SiP), while offering improved cooling and compatibility with standard QFN footprints.

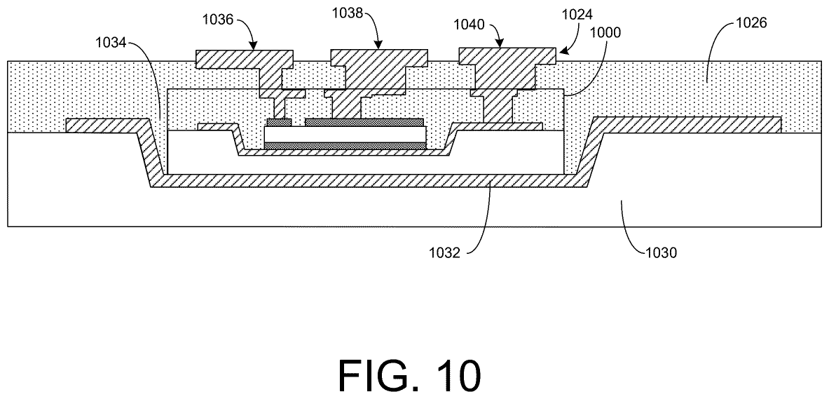

FIG. 10 is a cross-sectional view of an example embodiment with nested modules. In FIG. 10, a module 1000 is formed in accordance with above-described techniques. Specifically, the module 1000 is formed similarly to the module 900a of FIG. 9, but any of the modules described above, or variations thereof, may be used.

Further in FIG. 10, the module 1000 is disposed within a cavity 1034 formed in a substrate 1030, with an intervening metal layer 1032 disposed on the substrate 1030 and lining the walls and bottom surface of the cavity 1034. A dielectric 1026 embeds the module 1000. A gate contact 1036, source contact 1038, and drain contact 1040 provide a RDL 1024, and may be formed using above-described techniques.

Thus, FIG. 10 illustrates that one or more semiconductor dies may be embedded using described techniques, and with further packaging that includes further embedding in another embedded module. Such recursive embedding may be provided any desired number of times. Further packaging may be provided using traditional packaging technologies, such as leadframe, bond-wires, EMC, and/or Gel-filled module(s), to name a few.

Further packaging may be provided using wafer-scaled/wafer level packaging techniques and/or using panel-level packaging techniques. In further examples, PCB-embedding techniques or any other packaging techniques may also be used.

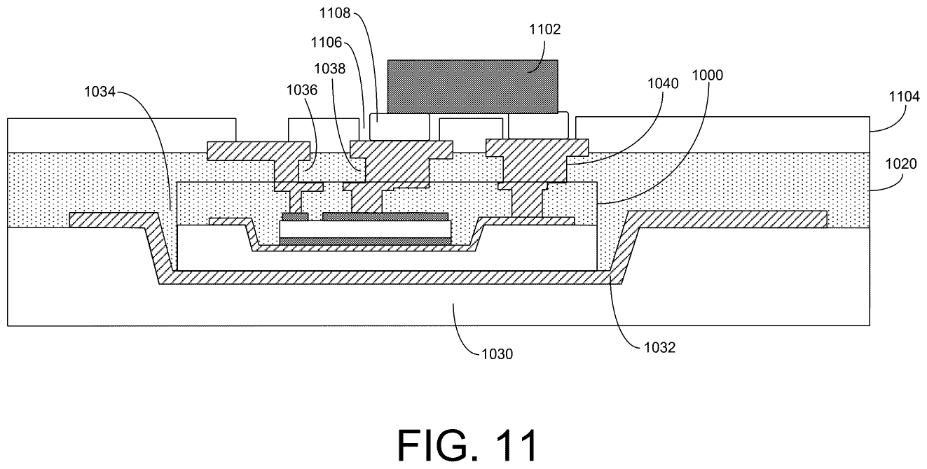

FIG. 11 illustrates a first example use case for the example embodiment of FIG. 10. Specifically, FIG. 11 illustrates inclusion of a component 1102 that may easily be added/connected to one or more of the contacts 1036, 1038, 1040 of the module of FIG. 10. For example, the component 1102 may represent a bus bar, or may represent various types of electrical components, as discussed in more detailed examples, below.

For example, as just referenced, the component 1102 may represent a bus bar. In the context of semiconductor packaging, a bus bar refers to a relatively thick conductive structure used to improve electrical performance. For example, a bus bar may include a metallic strip or bar (e.g., a highly conductive material such as copper or copper alloys), used to carry high electrical currents or distribute power efficiently.

As may be observed from FIGS. 10 and 11, the contacts 1036, 1038, 1040 may be formed with a larger thickness than corresponding contacts of the module 1000, where thicknesses of the latter contacts of the module 1000 may be limited due to size or fabrication constraints during the fabrication process(es). As a result, such relatively thin conductors created during wafer fabrication processes may have relatively higher electrical resistance and/or be prone to issues such as overheating or electro-migration. In contrast, bus bars, such as may be formed by the component 1102, are thicker and can handle higher currents with lower resistance. Consequently, by attaching bus bars as the component 1102 to the embedded module 1000, performance targets (e.g., reducing electrical resistance, increasing a fusing current, and mitigating electro-migration may be met, thereby enhancing reliability and efficiency in applications like power electronics or high-current systems.

In FIG. 11, the component 1102 representing a bus bar may be bonded to the contacts 1038, 1040 through openings 1108 in an insulating layer 1104, e.g., using solder contacts 1106. More generally, any of soldering, diffusion soldering, sintering, ACA bonding may be used.

Integration of bus bars may be implemented prior to packaging steps such as gel-filling, injection molding, or transfer molding. By attaching bus bars prior to these steps, the embedded module 1000 gains enhanced electrical performance while still being compatible with standard packaging processes. This approach allows the module 1000 to function in high-power applications, while offering superior current-handling capabilities compared to traditional thin conductors.

In other examples, as referenced above, the component 1102 may represent various other electrical components. For example, such components may include Negative Temperature Coefficient (NTC) thermistors, Multilayer Ceramic Capacitors (MLCCs), resistors, inductors, gate-driver Integrated Circuits (ICs), or any other active or passive circuit soldered or otherwise bonded to the contacts 1036, 1038, 1040, as described above. These and other components may be integrated to add specific corresponding functionalities, compatible with existing PCB assembly while integrating the various components directly onto the embedded module of FIG. 11, or any other example embodiments described herein, including the examples of FIG. 1-9.

Further non-limiting examples of components that may be embedded as the component 1102 include semiconductor components, passive electronic components, and sensors. For example, semiconductor components, such as transistors, diodes, microprocessors, or Application-Specific Integrated Circuits (ASICs), may be used to add processing or switching capabilities. Gate-driver ICs may be used to control power transistors in applications such as motor drives or inverters. Passive components, such as resistors, capacitors, inductors, or transformers, or copper blocks (e.g., as alternatives to bus bars for low-resistance conduction), may be used to facilitate or enhance electrical performance. Sensors, such as Microelectromechanical Systems (MEMS) or NTC thermistors, enable environmental monitoring, including current monitoring (to thereby provide a circuit breaker), as well as temperature sensing for thermal management in high-power systems. By bonding one or more such components before any final packaging steps (e.g., gel-filling or EMC encapsulation), it is possible to create compact, multifunctional modules that integrate easily into systems requiring high reliability and performance.

FIG. 12 illustrates an example use case for the example embodiment of FIG. 9. In FIG. 12, a module 1200a is constructed using described techniques to provide contacts 1208, 1214, 1222, and, similar to FIG. 9, may be included in a QFN package shown as module 1200b. A magnetic structure 1200c represents, e.g., an inductor(s). Operations of the illustrated module(s) 1200a, 1200b are illustrated by a circuit diagram 1200d.

In more detail, the magnetic structure 1200c, such as an inductor, is illustrated as being connected to a side of the module 1200a that is opposed to the side with the RDL 1224. This connection allows the module 1200c to interface with the inductor's windings, enabling compact integration of power management functions directly onto the module, thereby reducing the need for external components and minimizing the overall system size.

As shown in the circuit diagram 1200d, a backside connection to a switch-node labeled as “1” in FIG. 12, e.g., a midpoint of a half-bridge configuration, defines an electrical junction at which the inductor connects, e.g., to manage current or voltage fluctuations. Inductor windings are illustrated as dashed lines between nodes 1 and 2, nodes 3 and 4, and nodes 5 and 6. Conductive traces or thin metal paths, shown as dashed lines connecting nodes 2 and 3 and nodes 4 and 5, complete the windings of the magnetic structure 12000c (e.g., the referenced inductor windings). These conductive traces effectively act as wires that wrap around or connect to the inductor's core, enabling the module 1200a to contribute to a magnetic field generation. By integrating these windings directly onto the surface of the module 1200a, assembly is simplified, parasitic losses (e.g., resistance or inductance from external connections) are reduced, and performance in high-frequency or high-power applications is enhanced. In other examples, a stand-alone instance of such a magnetic element may be similarly integrated without the partial windings implemented in the module 1200a.

Further, a redistribution of the magnetic structure's output may be enabled, such that an electrical output from the inductor (e.g., filtered or regulated current) can be rerouted within the module 1200a/1200b to other components, such as a filter capacitor, or directed externally through alternative pathways outside the module 1200a/1200b. Such redistribution may involve, e.g., additional backside traces or internal routing to optimize signal integrity or power delivery. For example, the inductor's output might be connected to a filter capacitor within the module to stabilize the power supply for an embedded SoC or SiP, or it could be routed off-module to an external capacitor for flexibility in system design.

As noted above, many other components and associated functionalities may be included in semiconductor modules constructed using described techniques. For example, any substrate included in such a module may contain virtually any component/functionality available in the context of wafer-processing. For example, any active semiconductor element, passive element (e.g., resistors, inductors, or capacitors, including MIM capacitors), sensors, and MEMs elements, including cooling channels and electro-mechanical relays.

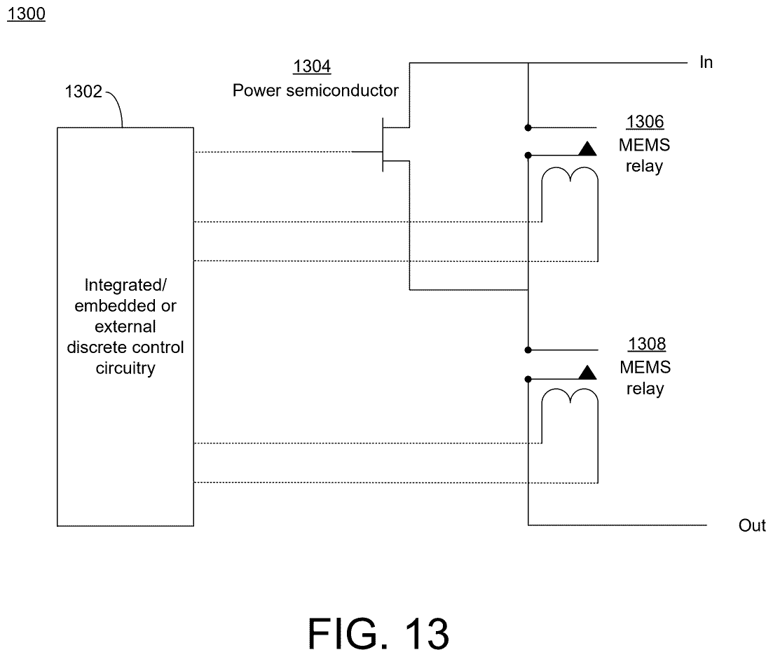

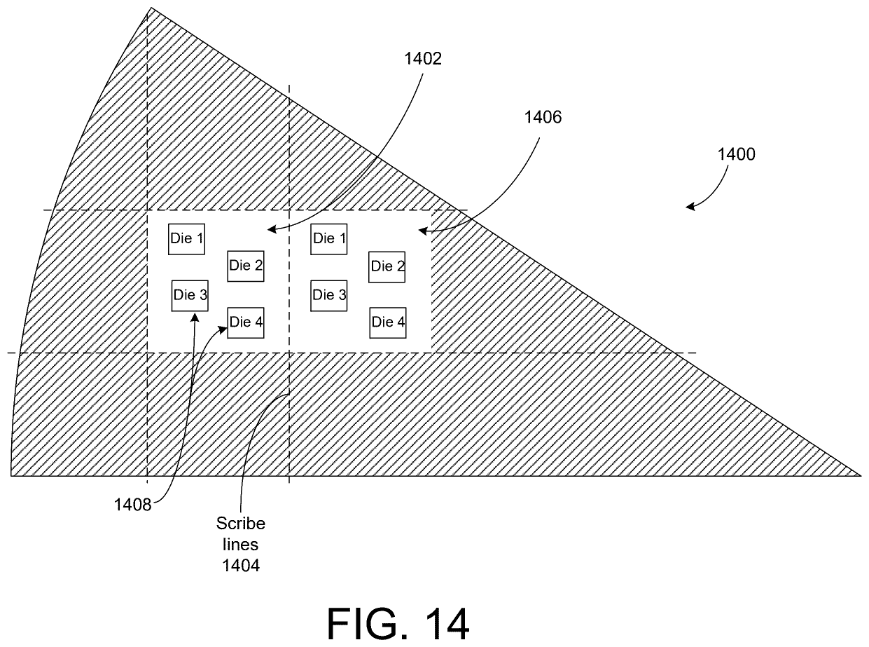

In a specific example, FIG. 13 is a circuit diagram illustrating operation of a module according to example embodiments that operates as a solid-state relay, e.g., for high-voltage direct current (DC) switching. In FIG. 13, control circuitry 1302 may represent integrated/embedded or external/discrete control circuitry, e.g., including gate driver circuit(s). The control circuitry 1302 interfaces with the gate of a power transistor 1304, which may represent any of the various semiconductor dies discussed above (e.g., the semiconductor die 102 of FIG. 1). The control circuitry 1302 further controls actuation inputs of two Micro-Electro-Mechanical Systems (MEMS) relays 1306, 1308, which are arranged along a current path from an input (In) node to an output (Out) node.

Further in FIG. 13, the transistor 1304 has its source connected to the In node, with the MEMS relay 1306 positioned between the source and drain to enable Galvanic isolation between the IN and OUT terminals, when the relay is in the OFF state. The MEMS relay 1308 is connected between the transistor's drain and the Out node, completing the path. When put into its OFF state(e.g., in response to an overcurrent condition), the control circuitry 1302 sends signals to open the transistor as well as both MEMS relays 1306, 1308, establishing a galvanic isolation between In to Out. When conduction between IN and OUT is desired (e.g. the relay is in the ON state), the MEMS relay 1308 ensures a very low-resistance conduction path regardless of the on-state resistance (or voltage drop) of the transistor. The transistor ensures an extremely fast reaction time, and the ability to interrupt high DC current, which would otherwise cause degradation (arc-formation) in a purely mechanical relay. The turn-on sequence is, e.g., to first close relay 1308 (no current flowing), then semiconductor 1304 (which establishes current-flow without any risk of arcing/welding, etc.), and then finally relay 1306, which enhances current flow (lowers conduction resistance), but without any risk of arcing/welding, since current flow is already established and voltage across relay 1306 is essentially 0V at the time of turn-on. The turn-on sequence can happen much faster than traditional mechanical contactor action. The turn-off sequence is the opposite: first relay 1306 is turned OFF, which commutates the current to semiconductor 1304 channel, such that no arcing occurs at the relay contacts. Then the semiconductor 1304 is turned off in order to arrest the current. Due to the semiconductor nature of described embodiments, there is no arcing or other issues with this turn-off. After current is fully interrupted, relay 1308 is turned off, ensuring a galvanic isolation between IN and OUT. This turn-off happens at 0 A of current, and therefore does not cause any arcing or other lifetime degradation issues for the relay. The turn-off sequence may happen much more rapidly than for tradition mechanical-only relay types, and the reliability/lifetime is dramatically extended compared to mechanical-only relays, especially in the number of times the turn-off/turn-on sequences can be achieved before performance is detrimentally degraded. The configuration of FIG. 13 ensures safe, isolated operation, as the MEMS relays 1306, 1308 act as mechanical switches that physically open or close contacts without electrical continuity between input and output sides. Moreover, since the components are integrated in an embedded module, the full system is extremely small in size and simple to deploy compared to, e.g., non-integrated and/or non-embedded embodiments.

Power semiconductors, such as the transistor 1304, may be, e.g., embedded elements, external elements, attached to the surface of the embedded module, or integrated as processed semiconductor elements in substrate wafer (e.g., via doping). Similarly, the control circuitry 1302 may be an embedded element(s), may be attached to an embedded module surface, or may be external (non-integrated). The MEMS relays 1306, 1308 may be realized by wafer processing of an embedded wafer, or may be embedded as dies, attached to the surface of embedded module, or external.

During operation, when a switching command is received, the control circuitry 1302 first asserts the gate voltage to prepare the transistor 1304 if needed, then actuates the MEMS relays 1306, 1308, closing their contacts in sequence. The MEMs relay 1306 may thus be configured to shunt current around the transistor 1304 for low-loss conduction, while the MEMs relay 1308 directs the flow to the Out node. Opening the MEMs relays 1306, 1308 reverses the process, instantly isolating the path with no residual voltage or current leakage due to the mechanical break.

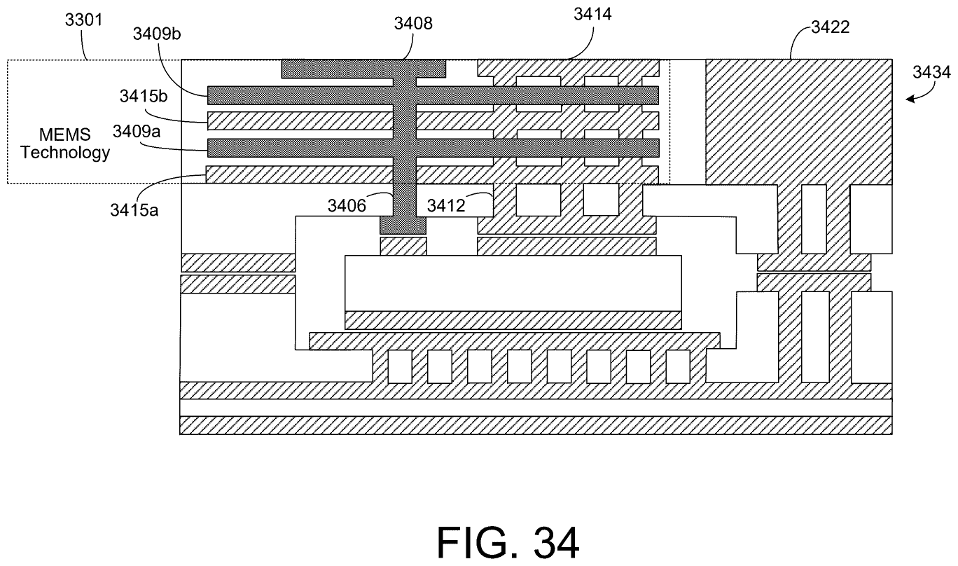

Thus, the embodiment of FIG. 13 provides a high speed, low conduction loss (high current), very long-life solid-state relay capable of handling high-voltage DC and providing galvanic isolation with minimal heat generation. The combination of the transistor's fast switching and the MEMS relays'mechanical durability enables rapid on/off times while handling large currents and high voltages, while surpassing traditional electromechanical relays in lifespan. Galvanic isolation from the MEMS relays prevents high-voltage faults from propagating to the low-voltage control side, enhancing safety in applications like electric vehicles or renewable energy inverters. Specific implementation examples of the circuit of FIG. 13, as well as other example modules that include MEMs devices, are provided below, e.g., with respect to FIGS. 34-36.

FIG. 14 is a top view of a portion 1400 of a wafer used to produce modules with four semiconductor dies each. Specifically, a module 1402 is illustrated as including four dies 1408, while a module 1406 is illustrated as including four dies 1410. Scribe lines 1404 define panels in which modules, such as the modules 1402, 1406, may be formed. By providing multiple modules laid out in an array on the wafer, parallel/concurrent processing of multiple modules is enabled.

FIG. 15 is a top view of an entirety of the wafer of FIG. 14. FIG. 15 illustrates an example wafer layout for a 300 mm wafer 1500. In the example of FIGS. 15, 89 modules or panels of 25 mm×25 mm size may be mapped to the wafer 1500. For example, panels 1502, 1504 may correspond to (i.e., provide for the construction of) the modules 1402, 1406 of FIG. 14. In the specific example of FIG. 15, for the layout of FIG. 14, each of the four dies 1408 or 1410 may be constructed as square elements that are, e.g., 5000 microns per side. Of course, many other sizes and dimensions may be used.

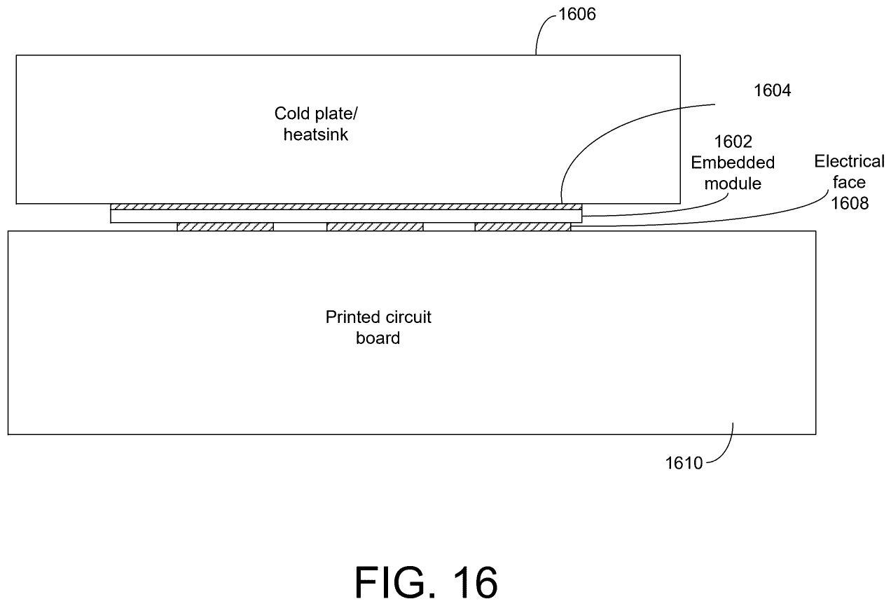

FIG. 16 is an example implementation demonstrating dual thermal and electrical connectivity. In FIG. 16, an embedded module 1602 represents any one of many of the module implementations described above, such as the QFN-compatible module 900b of FIG. 9. As discussed above, e.g., with respect to FIG. 9, the embedded module 1602 may easily be connected to a printed circuit board 1610 at its electrical face 1608, e.g., using conventional connection techniques. The embedded module 1602 may further be connected on an opposed thermal face 1604 to a heat sink 1606. Accordingly, electrical connectivity with improved thermal management is provided by the implementation of FIG. 16.

Thus, preceding example embodiments illustrate embedded modules with an electrical face that may be soldered to a PCB and/or to other component(s). Similarly, leadframes, busbars, copper blocks or similar elements soldered to such embedded modules, which themselves may be connected, e.g., to DC-link capacitors, electric machines, gate-driver ICs, or similar elements.

Embedded modules as described herein may be partially or fully covered by a dielectric material. Leadframes, busbars, copper blocks or similar elements soldered to the electric face of such an embedded module may protrude from the dielectric material thereby facilitating electrical connection to the embedded module.

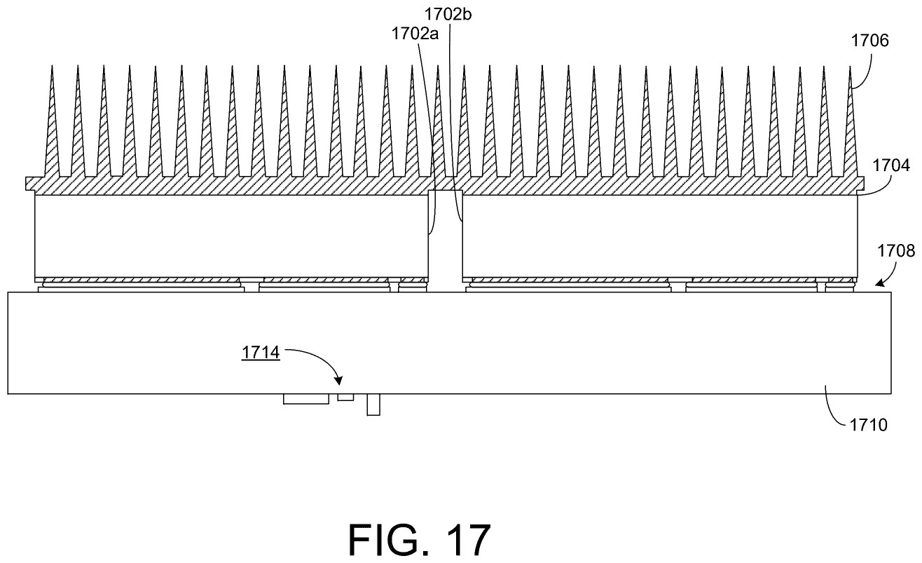

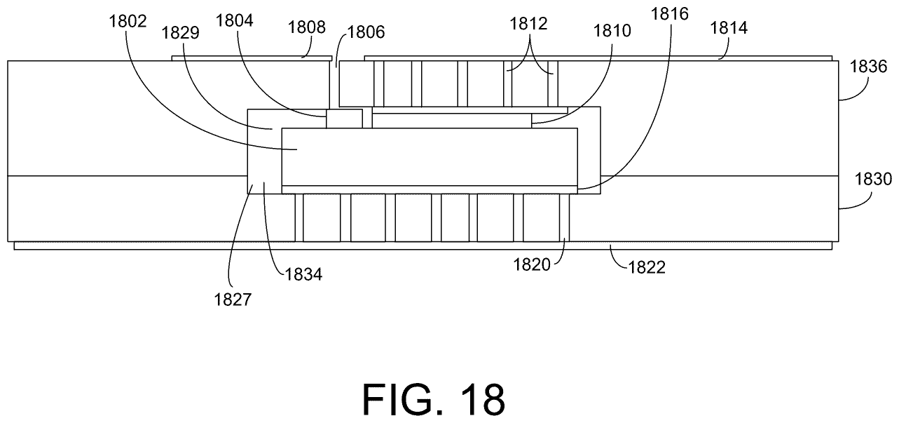

FIG. 17 is an alternate example implementation demonstrating dual thermal and electrical connectivity. In FIG. 17, an embedded module 1702a and an embedded module 1702b both have solder connections 1704 to a heatsink 1706. Connections 1708 join the embedded modules 1702a, 1702b to a printed circuit board 1710, which may also include any standard components 1714, such as integrated circuits, resistors, capacitors, or inductors. Thus, FIG. 17 illustrates that described implementations may easily be scaled and otherwise used in combination with one another efficiently to leverage provided benefits.

FIG. 18 illustrates an example embodiment with multiple cavities. FIG. 18 includes a semiconductor die 1802 with a gate pad 1804 connected through a gate via 1806 to a gate contact 1808, a source pad 1810 connected through source vias 1812 to a source contact 1814, and a drain pad 1816 connected to a drain contact 1822 through drain vias 1820.

In FIG. 18, the semiconductor die 1802 is disposed between a first substrate 1830 having a first cavity 1827 and a second substrate 1836 having a second cavity 1829. Together, the cavities 1827, 1829 form a cavity 1834, within which the semiconductor die 1802 is disposed. For example, the cavity 1834 may be an air cavity, or, in other implementations, may be filled with a dielectric material or other insulating material.

As with earlier embodiments, the substrates 1830, 1836 may be formed using any suitable material, including any semiconductor material, such as silicon or GaN. Consequently, it is straightforward to form the cavities 1827, 1829 and the various vias 1806, 1812, and 1820, and to bond the substrates 1830, 1836 to one another. In FIG. 18, the cavity 1827 is smaller than (not as deep as) the cavity 1829. In other implementations, however, the cavity 1827 may be larger/deeper than the cavity 1829, or the cavities 1827, 1829 may be substantially the same size.

In the example of FIG. 18, as may be observed, gate contact 1808 and source contact 1814 are on one surface, while drain contact 1822 is on an opposed surface. Consequently, various corresponding types of electrical connections may be made.

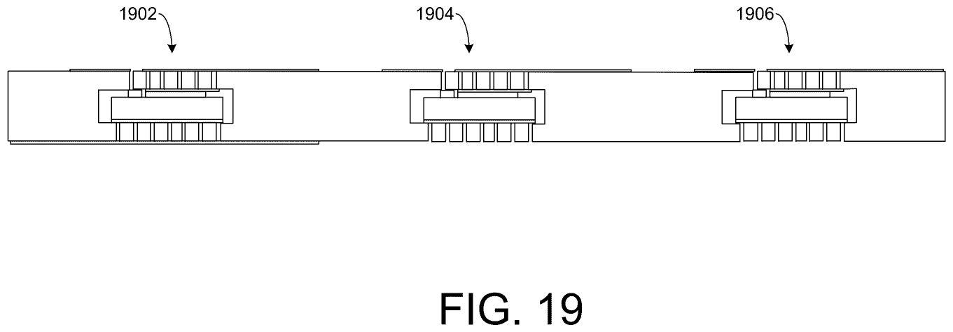

For example, as shown in FIG. 19, multiple modules 1902, 1904, 1906 may be joined and deployed together. For example, the modules 1902, 1904, 1906 may be joined and deployed with a common drain contact.

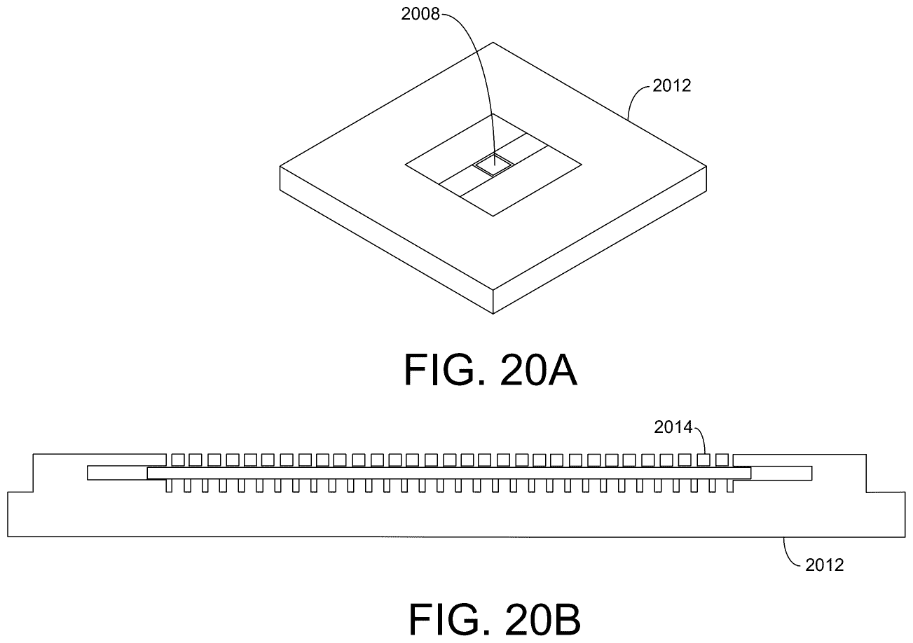

FIG. 20A is an isometric view of an example embodiment with a cooling block. FIG. 20B. is a cross-sectional view of the example embodiment of FIG. 20A. In FIGS. 20A and 20B, a multitude of thermally conducting vias 2014 thermally connect a cooling block to the embedded die 2008. The cooling block 2012 may effectively spread the generated heat for disposition on a further heatsink attached to the cooling block 2012. Heat is conducted both in the x/y plane for spreading and in the z-direction for disposition at the cooling block 2012 and/or other heatsink/heat exchanger.

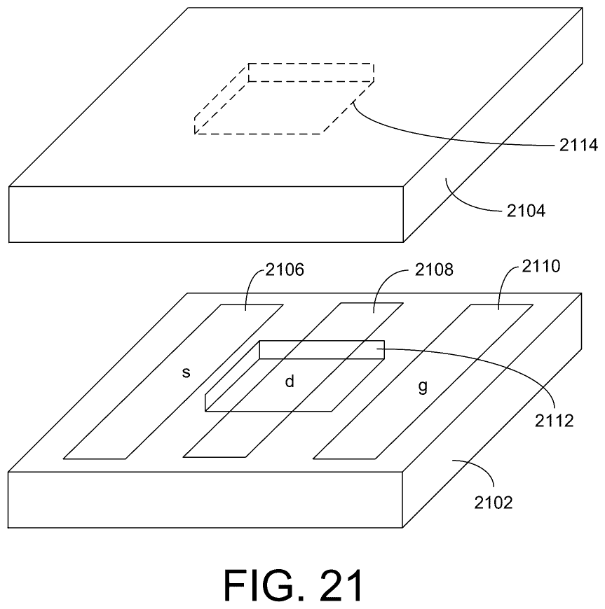

FIG. 21 is a 3D exploded view indicating a cavity 2114 at the bottom of a lid wafer 2104, and a cavity 2112 at the top of a base wafer 2102. Electrical connection terminals for source 2106, drain 2108 and gate 2110 are redistributed to the bottom of the base wafer 2102. FIG. 21 thus provides an example assembled package for the embodiments of FIGS. 18-20B.

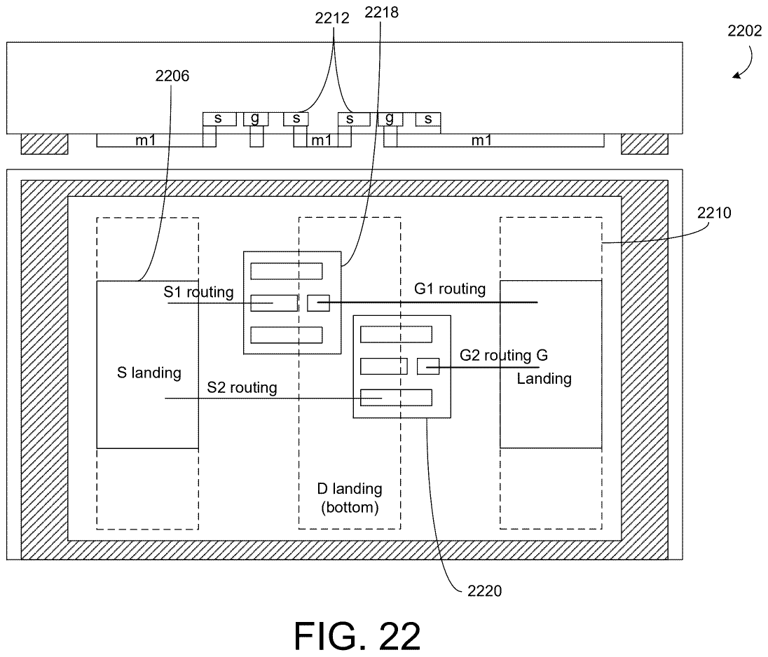

FIG. 22 illustrates an example of single-metal layer routing for multiple dies, where die 2218 has a source pad 2212 routed via S1 routing to a source landing 2206, which may provide an electrical contact to the module 2202. Die 2220 likewise has a source pad 2212 routed via S2 routing to S landing 2206. Similarly, 2218 has gate routed via G1 routing to G landing 2210, whereas die 2220 has its gate routed to same G landing 2210 via G2 routing. Finally dies 2218 and 2220 have their common drains routed at the bottom of the package, as indicated by dashed lines in FIG. 22.

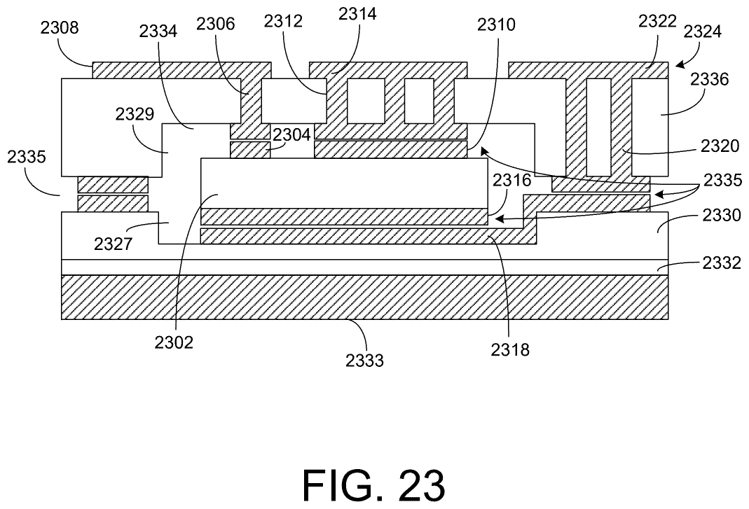

FIG. 23 is a cross-sectional view of an example dual-cavity embodiment. FIG. 23 illustrates a semiconductor die 2302 with a gate pad 2304 connected through a gate via 2306 to a gate contact 2308, a source pad 2310 connected through source vias 2312 to a source contact 2314, and a drain pad 2316 connected to a metal layer 2318 and thereby to a drain contact 2322 through drain vias 2320. Accordingly, the module of FIG. 23 may be connected to other elements using any suitable technique, including those mentioned above, as well as Cu pillars, bondwires, or various others.

In FIG. 23, the semiconductor die 2302 is disposed between a first substrate 2330 having a first cavity 2327 and a second substrate 2336 having a second cavity 2329. Together, the cavities 2327, 2329 form a cavity 2334, within which the semiconductor die 2302 is disposed. For example, as in FIG. 18, the cavity 2334 may be an air cavity, or, in other implementations, may be filled with a dielectric material or other insulating material.

Further in FIG. 23, a RDL 2324 is formed on a surface of the second substrate 2336. Accordingly, and in contrast with the example of FIG. 18, a dielectric or other electrically isolating layer 2332 may be formed on the first substrate 2330, and a metal heatsink 2333 may be connected thereto.

In the example of FIG. 23, gate via 2306 and source vias 2312 are formed through a relatively thinner portion of the second substrate 2336 between the cavity 2334 and the gate contact 2308/source contact 2314. Meanwhile, the drain vias 2320 are formed through a thicker portion of the second substrate 2336 that is adjacent to the cavity 2334.

Metal attachment points 2335 are established to join the semiconductor die 2302 to the layer 2318 and thereby to the first substrate 2330, and to connect the second substrate 2336 to the first substrate 2330 and to the semiconductor die 2302. In FIG. 23, the metal attachment points 2335 are metal-to-metal connections, but other connections may be used, as well. Metal attachment points 2335 may be referred to as die attachment points when connecting to leads of the semiconductor die 2302, or as substrate attachment points when attaching the first substrate 2330 and/or the second substrate 2336. In FIG. 23, as illustrated, the cavity 2327 is shallower than the cavity 2329, or, put another way, the cavity 2327 has a first depth that is less than a second depth of the cavity 2329. For example, the shallower cavity 2327 and the overall structure of the first substrate 2330 may be effective in facilitating heat transfer to the heat sink 2333.

As may be observed in FIG. 23, the semiconductor die 2302 extends out of the cavity 2327 and into the cavity 2329. Consequently, given the relative depths of the cavities 2327, 2329, metal attachment points 2335 occur at three different levels or planes within the example module of FIG. 23, i.e., at a first level between the drain pad 2316 and the metal layer 2318, at a second level between the two substrates 2330, 2336, and at a third level between the gate/source pads 2304/2310 and the gate source contacts 2308/2314. Put another way, die attach of the substrates 2330, 2336 occurs between die attach of the substrates 2330, 2336 to gate/source/drain pads 2304, 2310, 2316.

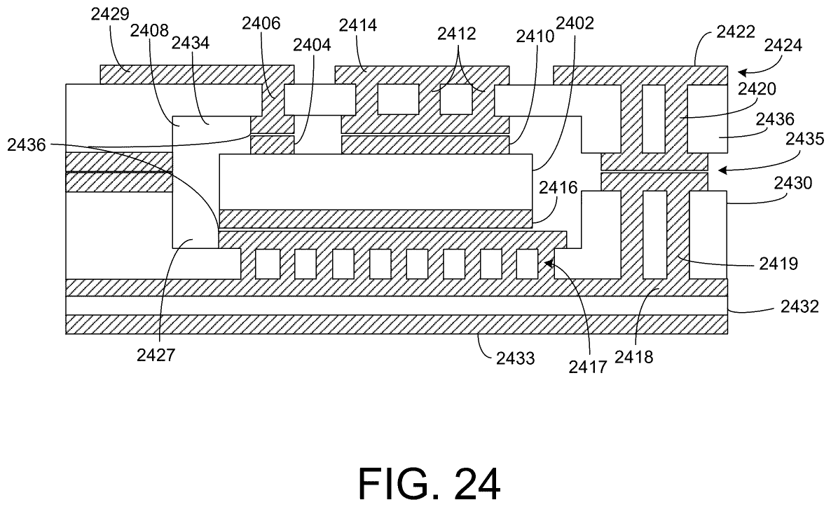

FIG. 24 is a cross-sectional view of an alternate example dual-cavity embodiment. FIG. 24 illustrates a semiconductor die 2402 with a gate pad 2404 connected through a gate via 2406 to a gate contact 2408, a source pad 2410 connected through source vias 2412 to a source contact 2414, and a drain pad 2416 connected to a metal layer 2418 and thereby to a drain contact 2422 through drain vias 2420. Accordingly, the module of FIG. 24, like that of FIG. 23, may be connected to other elements using any suitable technique, including those mentioned above, as well as Cu pillars, bondwires, or various others.

In FIG. 24, the semiconductor die 2402 is disposed between a first substrate 2430 having a first cavity 2427 and a second substrate 2436 having a second cavity 2429. Together, the cavities 2427, 2429 form a cavity 2434, e.g., a composite cavity or a combined cavity, within which the semiconductor die 2402 is disposed.

Further in FIG. 24, a RDL 2424 is formed on a surface of the second substrate 2436. A dielectric or other electrically isolating layer 2432 may be formed on the first substrate 2430, and a metal heatsink 2433 may be connected thereto.

In the example of FIG. 24, as in FIG. 23, gate via 2406 and source vias 2412 are formed through a relatively thinner portion of the second substrate 2436 between the cavity 2434 and the gate contact 2408/source contact 2414. The drain vias 2420 are formed through a thicker portion of the second substrate 2436 that is adjacent to the cavity 2434.

In contrast to FIG. 23, the cavity 2427 of the first substrate 2430 is larger/deeper than the cavity 2429 of the second substrate 2436. Drain redistribution occurs partially through additional drain vias 2417 and drain vias 2419 through the first substrate 2430, as shown.

Metal attachment points 2435 are established to join the semiconductor die 2402 to the layer 2418 and thereby to the first substrate 2430, and to connect the second substrate 2436 to the first substrate 2430 and to the semiconductor die 2402. In FIG. 24, although the cavity 2327 is deeper than the cavity 2329, heat transfer is facilitated through backside metal 2418 as part of the drain redistribution. For example, the backside metal 2418 may be close to the heat sink 2333, separated only by the electrically-isolating layer 2432.

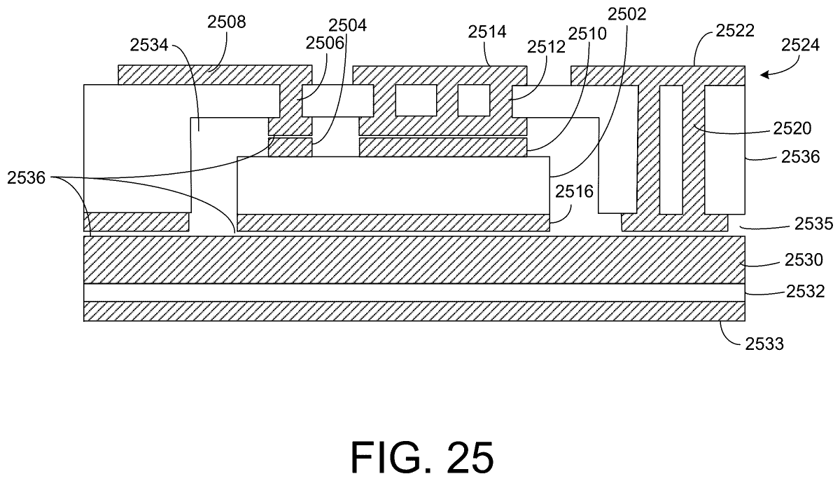

FIG. 25 is a cross-sectional view of an example single-cavity embodiment on metal. FIG. 25 illustrates a semiconductor die 2502 with a gate pad 2504 connected through a gate via 2506 to a gate contact 2508, a source pad 2510 connected through source vias 2512 to a source contact 2514, and a drain pad 2516 connected to a leadframe 2530 (or other metal element) and thereby to a drain contact 2522 through drain vias 2520. The semiconductor die 2502 is disposed between the leadframe 2430 and a substrate 2536 having a cavity 2534.

Further in FIG. 25, a RDL 2524 is formed on a surface of the substrate 2536. A dielectric or other electrically isolating layer 2532 may be formed on the leadframe 2530, and a metal heatsink 2533 may be connected thereto.

In the example of FIG. 25, as in FIGS. 23 and 24, gate via 2506 and source vias 2512 are formed through a relatively thinner portion of the substrate 2536 between the cavity 2534 and the gate contact 2508/source contact 2514. The drain vias 2520 are formed through a thicker portion of the substrate 2536 that is adjacent to the cavity 2534.

In contrast to FIGS. 23 and 24, the cavity 2534 is the only included cavity. That is, the leadframe 2530 has a flat surface and does not have a cavity. Drain redistribution occurs partially through the leadframe 2530, as shown.

Metal attachment points 2535 are established to join the semiconductor die 2502 to the leadframe 2530, and to connect the substrate 2536 to the leadframe 2530 and to the semiconductor die 2502. In FIG. 25, heat transfer is facilitated through the metal leadframe 2530 and the heatsink 2533.

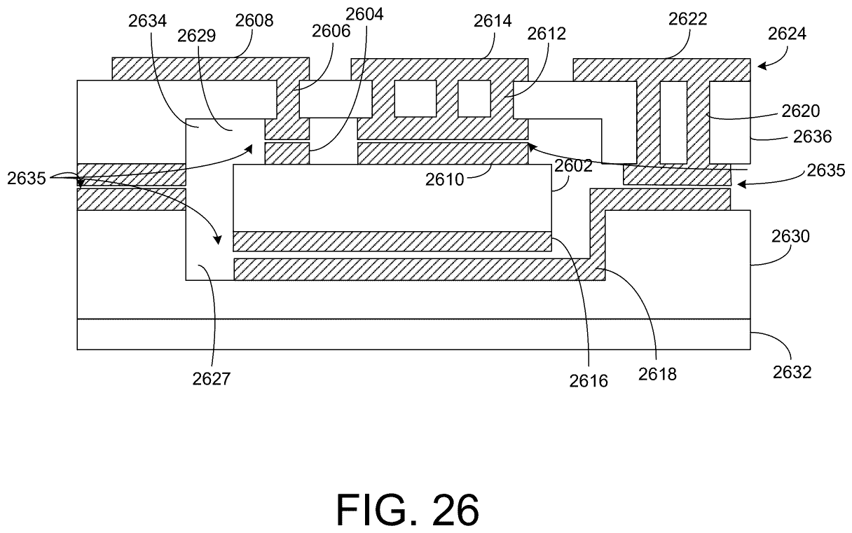

FIG. 26 is a cross-sectional view of an example dual-cavity embodiment with silicon bonded to diamond. FIG. 26 illustrates a semiconductor die 2602 with a gate pad 2604 connected through a gate via 2606 to a gate contact 2608, a source pad 2610 connected through source vias 2612 to a source contact 2614, and a drain pad 2616 connected to a metal layer 2618 and thereby to a drain contact 2622 through drain vias 2620.

In FIG. 26, the semiconductor die 2602 is disposed between a first substrate 2630 having a first cavity 2627 and a second substrate 2636 having a second cavity 2629. Together, the cavities 2627, 2629 form a cavity 2634, within which the semiconductor die 2602 is disposed.

Metal attachment points 2635 are established to join the semiconductor die 2602 to the layer 2618 and thereby to the first substrate 2630, and to connect the second substrate 2636 to the first substrate 2630 and to the semiconductor die 2602.

Further in FIG. 26, a RDL 2624 is formed on a surface of the second substrate 2636. A layer 2632 may be selected to be a material that is electrically isolating and that has good thermal characteristics. For example, the layer 2632 may be diamond directly bonded to the first substrate 2630.

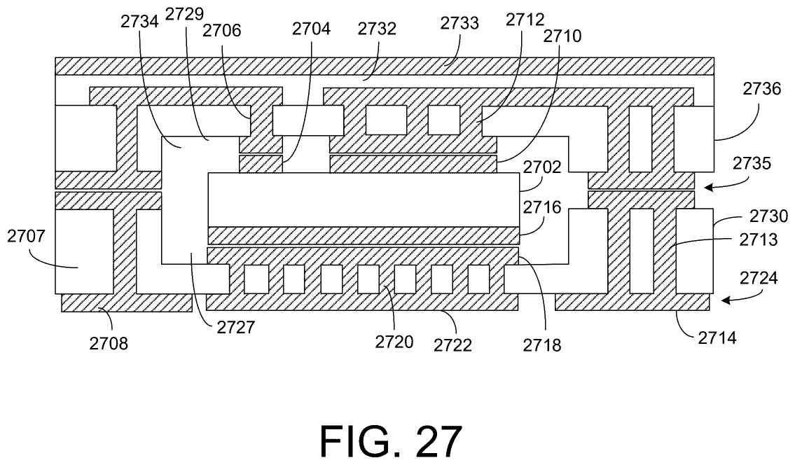

FIG. 27 is a cross-sectional view of an example dual-cavity embodiment with a drain-side redistribution layer. FIG. 27 illustrates a semiconductor die 2702 with a gate pad 2704 connected through a gate via 2706 in a second substrate 2736, die-attach 2735, and a gate via 2707 in a first substrate 2730 to a gate contact 2708. The semiconductor die 2702 further has a source pad 2710 connected through source vias 2712 in the second substrate 2736, die-attach 2735, and a source via 2713 in the first substrate 2730 to a source contact 2714. A drain pad 2716 is connected to a metal layer 2718 and thereby to a drain contact 2722 through drain vias 2720.

In FIG. 27, the semiconductor die 2702 is disposed between the first substrate 2730 having a first cavity 2727 and a second substrate 2736 having a second cavity 2729. Together, the cavities 2727, 2729 are aligned with one another to form a cavity 2734, within which the semiconductor die 2702 is disposed.

In FIG. 27, a RDL 2724 is thus formed on a surface of the first substrate 2730, i.e., on a bottom of the module of FIG. 27 as illustrated, as compared to the various RDLs 2324, 2424, 2524, 2624 of preceding FIGS. 23, 24, 25, 26, which were formed on the tops of those modules, as illustrated. A dielectric or other electrically isolating layer 2732 may thus be formed on the second substrate 2736, and a metal heatsink 2733 may be connected thereto, i.e., on a top of the module of FIG. 27, as illustrated.

Metal attachment points 2735 are established to join the semiconductor die 2702 to the layer 2718 and thereby to the first substrate 2730, and to connect the second substrate 2736 to the first substrate 2730 and to the semiconductor die 2702.

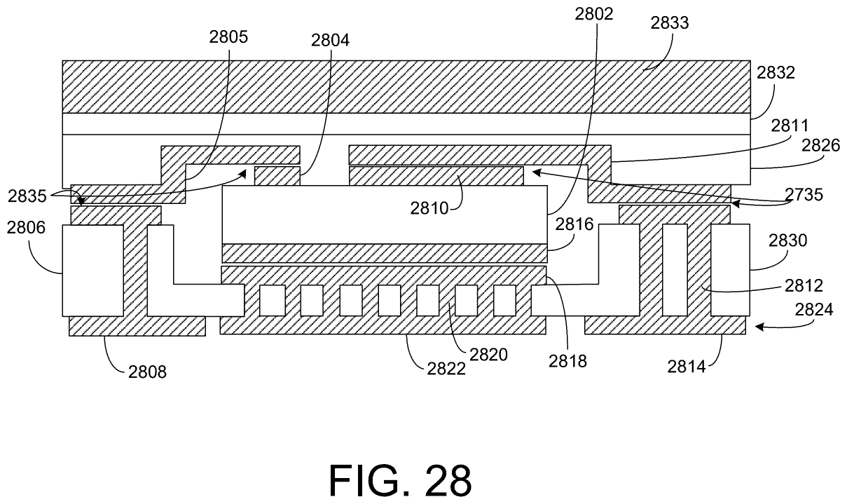

FIG. 28 is a cross-sectional view of an alternate example dual-cavity embodiment with a drain-side redistribution layer. FIG. 28 illustrates a semiconductor die 2802 with a gate pad 2804 connected to a metal layer 2805, die-attach 2835, and a gate via 2806 in a first substrate 2830, and thereby to a gate contact 2808. The semiconductor die 2802 further has a source pad 2810 connected to a metal layer 2811, die-attach 2835, and through source vias 2812 in the first substrate 2830, and thereby to a source contact 2814. A drain pad 2816 is connected to a metal layer 2818 and thereby to a drain contact 2822 through drain vias 2820.

In FIG. 28, the semiconductor die 2802 is disposed between the first substrate 2830 having a first cavity 2827 and a second substrate 2836 having a second cavity 2829. Together, the cavities 2827, 2829 form a cavity 2834, within which the semiconductor die 2802 is disposed. In FIG. 28, and in the various dual cavity structures described herein, the cavities are not necessarily drawn to scale. For example, a deeper cavity may be ten times larger than a shallow cavity in a dual cavity structure (e.g., 150 microns compared to 15 microns or less). More generally, any suitable size/depth and ratio may be selected.

In FIG. 28, a RDL 2824 is thus formed on a surface of the first substrate 2830, i.e., on a bottom of the module of FIG. 28 as illustrated, and similar to the example of FIG. 27. However, as shown and described, the RDL 2824 of FIG. 28 is formed without requiring vias in the second substrate 2836.

A dielectric or other electrically isolating layer 2832 may be formed on the second substrate 2836. As in FIG. 27, a metal heatsink 2833 may be connected thereto, i.e., on a top of the module of FIG. 28, as illustrated.

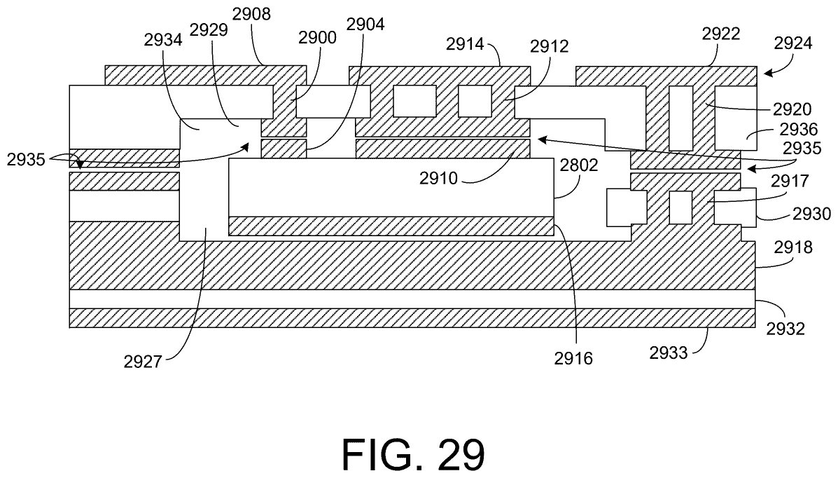

FIG. 29 is a cross-sectional view of an example dual-cavity embodiment with one cavity formed using a metal substrate and a substrate frame. FIG. 29 illustrates a semiconductor die 2902 with a gate pad 2904 connected through a gate via 2906 to a gate contact 2908, a source pad 2910 connected through source vias 2912 to a source contact 2914, and a drain pad 2916 connected to a leadframe 2918 and thereby to a drain contact 2622 through drain vias 2917 in a first substrate 2930 and drain vias 2620 in a second substrate 2936.

In FIG. 29, the semiconductor die 2902 is disposed between a combination of the leadframe 2918 and the first substrate 2630 defining a first cavity 2927 and a second substrate 2936 having a second cavity 2929. Together, the cavities 2927, 2929 form a cavity 2934, within which the semiconductor die 2902 is disposed.

In more detail, the first substrate 2930 may be formed as a frame (e.g., similar to a picture frame) defining a perimeter around the semiconductor die 2902. The leadframe 2918, as illustrated, may have a flat surface with portions that underly and support the first substrate 2930.

Metal attachment points 2935 are established to join the semiconductor die 2902 to the leadframe 2918, and to connect the second substrate 2936 to the first substrate 2930, the semiconductor die 2902, and the leadframe 2918.

Thus, in FIG. 29, a RDL 2924 is formed on a surface of the second substrate 2936. A layer 2932 may be selected to be a material that is electrically isolating (e.g., Silicon Nitride, such as Si₃N₄), and a heatsink 2933 may be attached thereto.

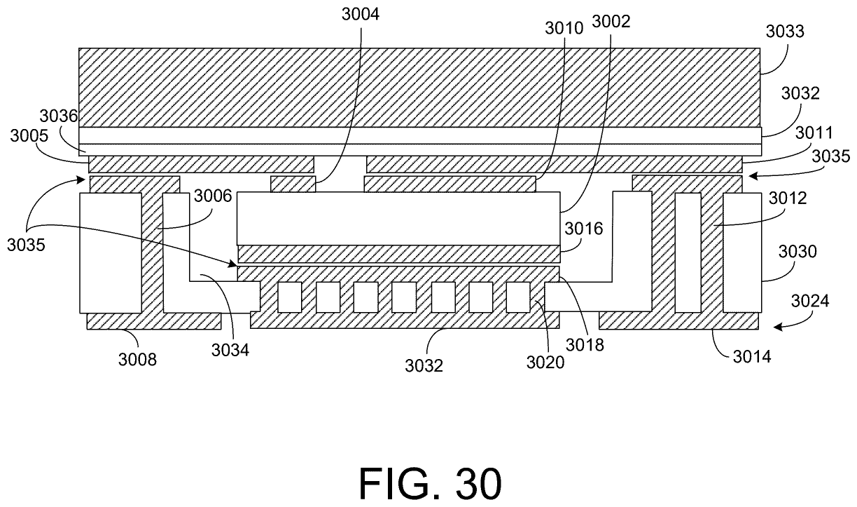

FIG. 30 is a cross-sectional view of an example dual-substrate, single-cavity embodiment. FIG. 30 illustrates a semiconductor die 3002 with a gate pad 3004 connected to a metal layer 3005, die-attach 3035, and a gate via 3006 in a first substrate 3030, and thereby to a gate contact 3008. The semiconductor die 3002 further has a source pad 3010 connected to a metal layer 3011, die-attach 3035, and through source vias 3012 in the first substrate 3030, and thereby to a source contact 3014. A drain pad 3016 is connected to a metal layer 3018 and thereby to a drain contact 3022 through drain vias 3020.

In FIG. 30, the semiconductor die 3002 is disposed between the first substrate 3030 having a cavity 3034 and the second substrate 3036, where the second substrate 3036 has no cavity and provides a flat surface for connection to the gate contact 3005 and the source contact 3011. The second substrate 3036 may be suitably thinned to ensure good thermal qualities with respect to transferring heat through electrically isolating layer 3032 and to a heatsink 3033.

In FIG. 30, a RDL 3024 is formed on a surface of the first substrate 30, i.e., on a bottom of the module of FIG. 30 as illustrated, and similar to the example of FIGS. 27 and 28. As shown and described, and similar to the example of FIG. 28, the RDL 30 of FIG. 30 is formed without requiring vias in the second substrate 2836. In FIG. 30, metal attachment points are at two levels or planes, i.e., between the drain pad 3016 and the metal layer 3018, and between the first substrate 3030 and the second substrate 3036, which includes the gate/source connections, as well, as shown and described.

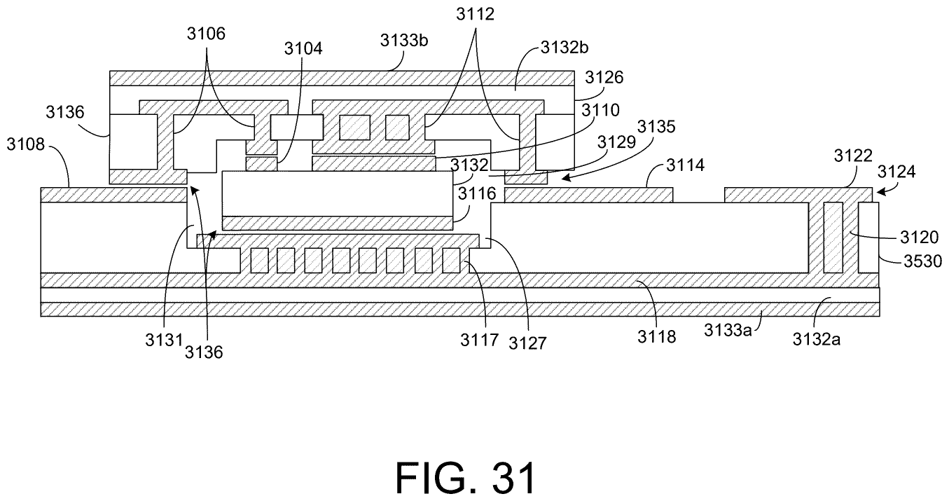

FIG. 31 is a cross-sectional view of an example dual-cavity embodiment with a redistribution layer formed between substrates. FIG. 31 illustrates a semiconductor die 3102 with a gate pad 3104 connected through a gate via 3106 in a second substrate 3136 to a die-attach 3135, and thus to a gate contact 3108. The semiconductor die 3102 further has a source pad 3110 connected through source vias 3112 in the second substrate 3136, through a die-attach 3135, and thus to a source contact 3114. A drain pad 3116 is connected through die-attach 3135 and through drain vias 3117 to a metal layer 3118 and thereby to a drain contact 3122 through drain vias 3120.

In FIG. 31, the semiconductor die 3102 is disposed between the first substrate 3130 having a first cavity 3127 and a second substrate 3136 having a second cavity 3129. Together, the cavities 3127, 3129 form a cavity 3134, within which the semiconductor die 3102 is disposed.

In FIG. 31, a RDL 3124 is thus formed on a surface of the first substrate 3130, i.e., between, or in the middle of, the first substrate 3130 and the second substrate 3136, as illustrated. A dielectric or other electrically isolating layer 3132a may thus be formed on the first substrate 3130, and a metal heatsink 3133a may be connected thereto, i.e., on a bottom of the module of FIG. 31, as illustrated. With the RDL 3124 in the middle of the module of FIG. 31, a dielectric or other electrically isolating layer 3132b may thus be formed on the second substrate 3136, and a metal heatsink 3133b may be connected thereto, i.e., on a top of the module of FIG. 31, as illustrated.

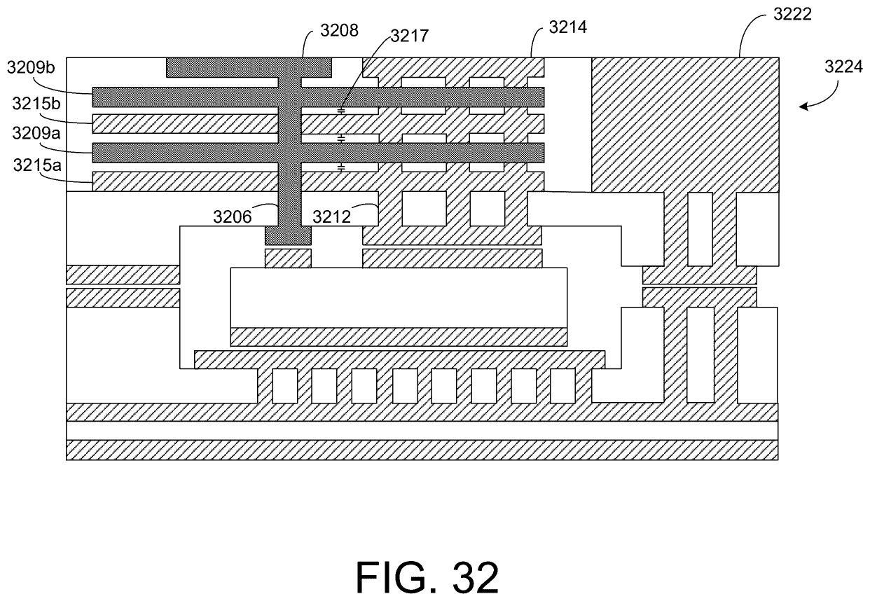

FIG. 32 is a cross-sectional view of an example dual-cavity embodiment with integrated passive devices. In FIG. 32 and similar figures described below, many of the various components and elements already described are neither enumerated or discussed in detail, for the sake of brevity. However, it will be understood that virtually any of the preceding embodiments (e.g., single cavity embodiments) may have elements substituted or combined in the context of the various embodiments described below.

For example, in FIG. 32, a gate contact 3208, source contact 3214, and drain contact 3222 forming a RDL 3224 that includes metal layers 3209a, 3209b connected to the gate contact 3208 by way of gate vias 3206, and metal layers 3215a, 3215b connected to the source contact 3214 by way of source vias 3212. As shown, the embodiment of FIG. 32 illustrates inclusion of integrated passive devices, such as capacitors 3217, e.g., MIM capacitors (MIMCAPs). Other types of passive devices, such as resistors or inductors, may also easily be integrated.

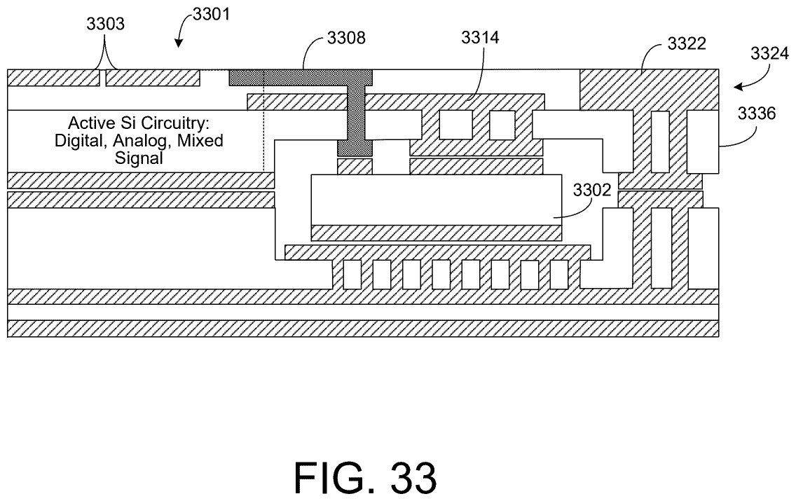

FIG. 33 is a cross-sectional view of an example dual-cavity embodiment with integrated active circuitry. That is, similar to the embodiment of FIG. 32, the embodiment of FIG. 33 illustrates the inclusion of active circuitry 3301. Active circuitry 3301 may be connected to other circuits (not shown) by terminals 3303, and may be connected to gate contact 3308 and source contact 3314, as shown. Accordingly, the active circuitry 3301 may be connected in the context of RDL 3324 that includes drain contact 3322.

Further, the active circuitry 3301 may easily be formed within the substrate 3336, e.g., using conventional or future silicon processing/fabrication techniques. Any suitable and available circuits may be included. To give a specific example, a gate-driver for a power discrete semiconductor die 3302 may be included.

FIG. 34 is a cross-sectional view of an example dual-cavity embodiment with integrated MEMs technology. Similar to FIG. 32, a gate contact 3408, source contact 3414, and drain contact 3422 form a RDL 3424 that includes metal layers 3409a, 3409b connected to the gate contact 3408 by way of gate vias 3406, and metal layers 3415a, 3415b connected to the source contact 3414 by way of source vias 3412. As shown, the embodiment of FIG. 34 illustrates inclusion of MEMS technology, including various types of MEMS devices.

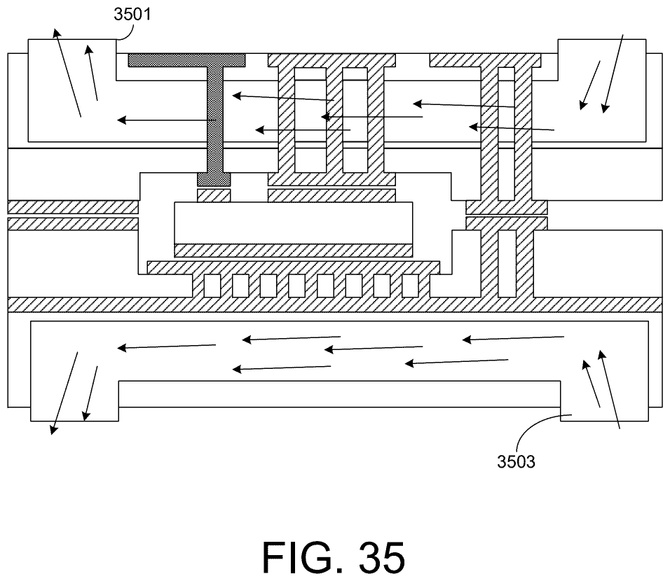

FIG. 35 is a cross-sectional view of an example dual-cavity embodiment with integrated MEMs pipes for liquid cooling. That is, FIG. 35 provides a more specific example of MEMs technology than shown in FIG. 34. Specifically, the embodiment of FIG. 35 includes incorporation of micro-fluidic heat pipes 3501, 3503 for dual-side, liquid cooling.

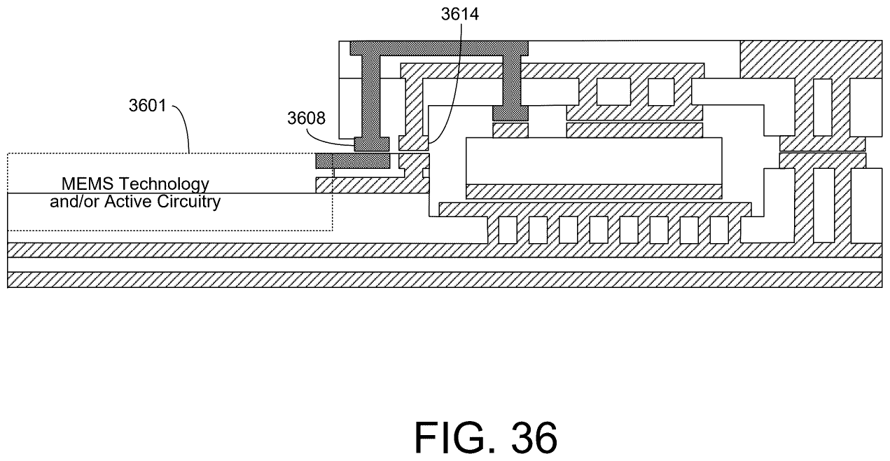

FIG. 36 is a cross-sectional view of an alternate example dual-cavity embodiment with integrated MEMs technology and/or active circuitry 3601. Specifically, as shown, FIG. 36 illustrates an embodiment similar to that of FIG. 31, but with gate contact 3608 and source contact 3614 connected to MEMs technology/active circuitry 3601. For example, as noted above and described in detail with respect to FIG. 13, the embodiment of FIG. 36 may be configured to provide a fast, reliable solid-state relay.

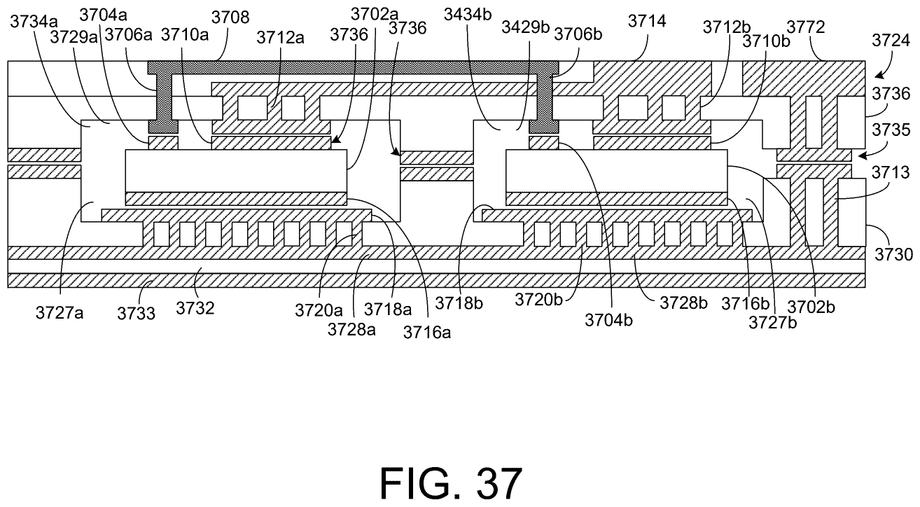

FIG. 37 is a cross-sectional view of an example dual-cavity, dual-die embodiment. FIG. 37 illustrates a semiconductor die 3702a with a gate pad 3704a connected through a gate via 3706a to a gate contact 3708, a source pad 3710a connected through source vias 3712a to a source contact 3714, and a drain pad 3716a connected to a metal layer 3718a and thereby to a drain contact 3722 through drain vias 3720a.

In FIG. 37, the semiconductor die 3702a is disposed between a first substrate 3730 having a cavity 3727a and a second substrate 3736 having a cavity 3729a. Together, the cavities 3727a, 3729a form a cavity 3734a, within which the semiconductor die 3702a is disposed.

Further in FIG. 37, a RDL 3724 is formed on a surface of the second substrate 3736. A dielectric or other electrically isolating layer 3732 may be formed on the first substrate 3730, and a metal heatsink 3733 may be connected thereto.

FIG. 37 further illustrates a semiconductor die 3702b with a gate pad 3704b connected through a gate via 3706b to the gate contact 3708, a source pad 3710b connected through source vias 3712b to the source contact 3714, and a drain pad 3716b connected to a metal layer 3718b and thereby to the drain contact 3722 through drain vias 3720b.

The semiconductor die 3702b is disposed between the first substrate 3730 having a cavity 3727b and the second substrate 3736 having a cavity 3729b. Together, the cavities 3727b, 3729b form a cavity 3734b, within which the semiconductor die 3702b is disposed.

Metal attachment points 3735 are established to join the semiconductor dies 3702a, 3702b to the layer 3718 and thereby to the first substrate 3730, and to connect the second substrate 3736 to the first substrate 3730 and to the semiconductor dies 3702a, 3702b.

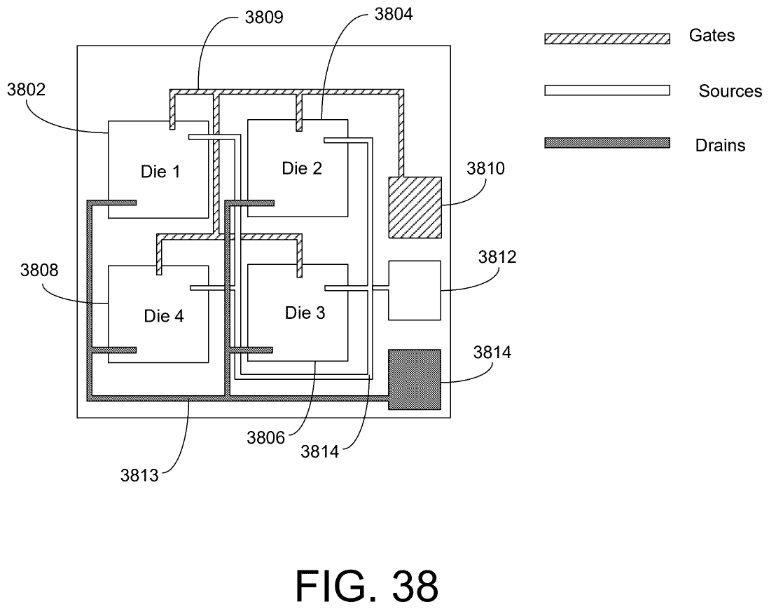

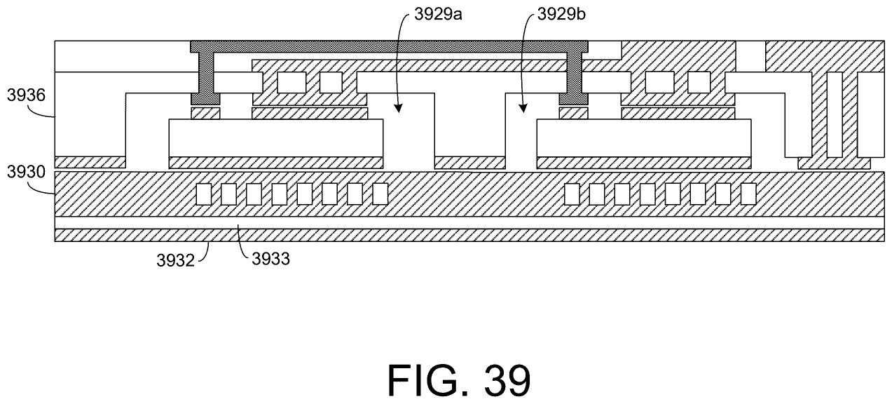

FIG. 38 is a top view of an example embodiment that may be constructed using various ones of the example embodiments of, e.g., FIG. 37 and/or FIGS. 39-50, and/or of, e.g., FIGS. 1-13 and/or FIGS. 23-26. FIG. 38 illustrates dies 3802, 3804, 3806, and 3808. As shown, gate connections 3809 connect all of the dies 3802, 3804, 3806, and 3808 to a common gate contact 3810. Similarly, source connections 3811 connect all of the dies 3802, 3804, 3806, and 3808 to a common source contact 3812. Finally, drain connections 3813 connect all of the dies 3802, 3804, 3806, and 3808 to a common drain contact 3814.

As may be appreciated from the above description, and as shown and described in various examples, below, the various connections 3809, 3811, 3813 may be made using substrate routing, e.g., using TSVs and RDLs. Moreover, the dies 3802, 3804, 3806, and 3808 may be included in a compact form, with the connections 3809, 3811, 3813 being formed without requiring wirebonds or other conventional connection techniques. Accordingly, the example of FIG. 38 may be provided as a four-die module that is small and reliable, with good thermal management, and that is straightforward to fabricate. It should be appreciated as well, that while a parallel connection of 4 dies are shown that together form a single functional switch, many different connections may be made that form desirable configurations. Such configurations may include, e.g., functional half-bridges comprising High-Side and Low-Side functional switches (each made up from one or more dies), full-bridges, T-types, 6-packs, or anti-series bi-directionally blocking. The preceding configurations are provided merely by way of example, and many other configurations may be realized, as well.

FIG. 39 is a cross-sectional view of an example dual-die embodiment having a substrate with a cavity on metal to provide a common drain connection. In FIG. 39, a leadframe 3930 is used as a first surface or substrate, and an optional electrical isolation layer 3932 electrically separates the leadframe 3930 from a remainder of the example of FIG. 39. Cavities 3929a and 3929b are formed in a substrate 3936. Thus, in FIG. 39, the leadframe 3930 provides a common drain connection, and the various advantages of embodiments with cavities as described herein may be obtained by forming the cavities 3929a, 3929b in the single substrate 3936 (e.g., a Si substrate), without having to form corresponding cavities in another substrate.

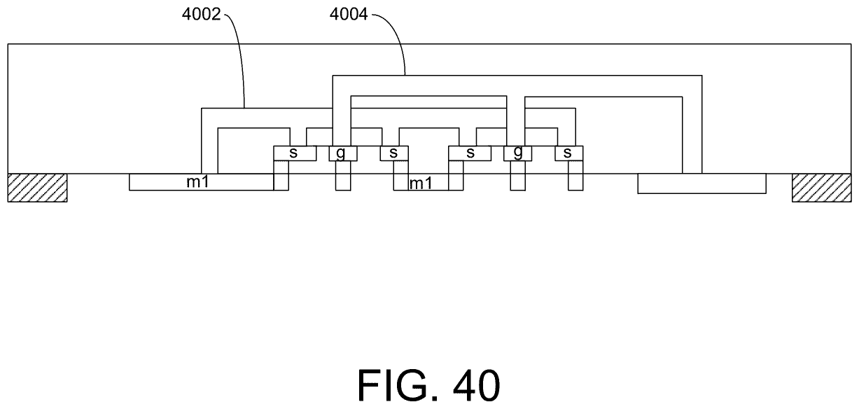

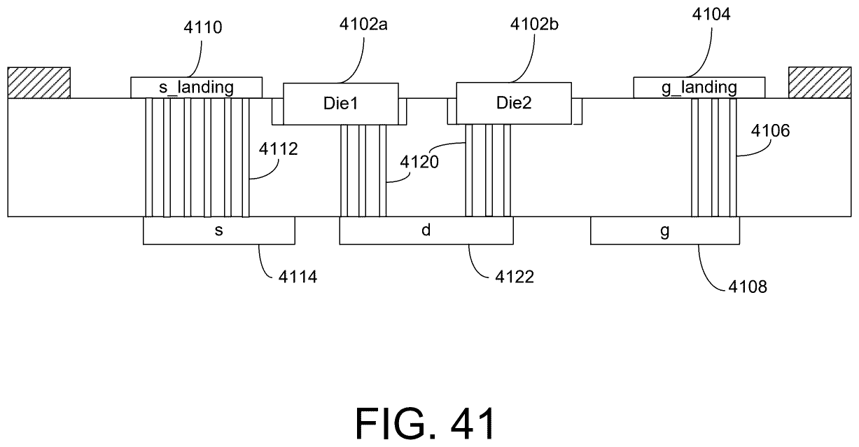

FIG. 40 illustrates example gate/source routing, while FIG. 41 illustrates example gate/source/drain routing. For example, FIG. 40 is similar to the example of FIG. 22, but includes additional routing/wiring 4002, 4004 FIG. 41 may be used with the embodiments of FIG. 22 or 40, and illustrates example routing for a die 4102a and a die 4102b. For example, a source landing 4110 is connected to a source pad 4114 by vias 4112. A drain pad 4122 is connected to the die 4102a and the die 4102b by way of vias 4120. A gate landing 4104 is connected to a gate pad 4108 by vias 4106.

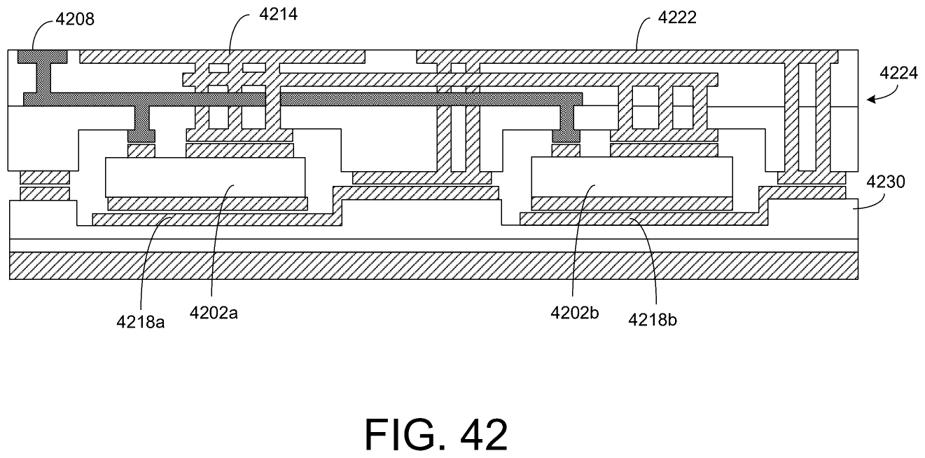

FIG. 42 is a cross-sectional view of an example dual-cavity, dual-die embodiment with a single redistribution layer. In FIG. 42, both of semiconductor dies 4202a, 4202b have a common gate connection 4208. The semiconductor dies 4202a, 4202b have a common source connection 4214. By way of metal layers 4218a, 4218b, the semiconductor dies 4202a, 4202b have a common drain connection 4222.

In the example of FIG. 42, the RDL 4224 includes three metal layers, as shown. Meanwhile, a single metal layer 4218a, 4218b, as already referenced, is redistributed to an upper or top surface in FIG. 42 to be included in the RDL 4224. In other examples, a single drain connection for the two dies 4202a, 4202b may be formed at a bottom of the example module of FIG. 42, or drains of the two dies 4202a, 4202b may be individually routed to a top of the module.

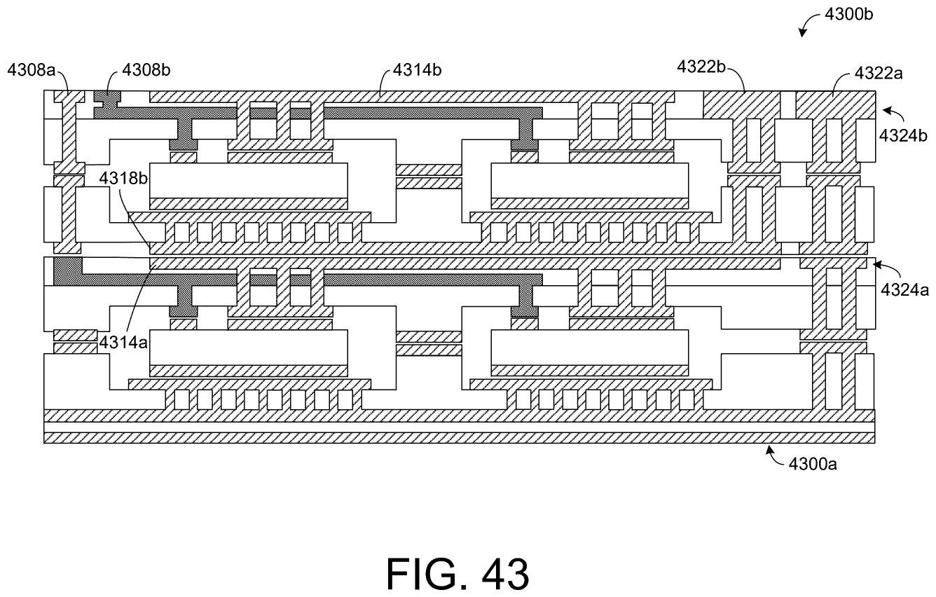

FIG. 43 is a cross-sectional view of an example stacked module with multiple dual-cavity, dual-die modules. In the example of FIG. 43, each of a module 4300a and a module 4300b are similar to the module of FIG. 42. A gate connection 4308a included in a RDL 4324b of the module 4300b provides a connection to gates of the module 4300a, via a RDL 4324a of the module 4300a. A gate connection 4308b and source connection 4314b of the module 4300b are also included within the RDL 4324b.

In the example of FIG. 43, a redistributed switchnode 4322b is included within the RDL 4324b, which is connected to a drain connection 4318b of the module 4300b, as well as to a source connection 4314a of the module 4300a. A drain connection 4322a within the RDL 4324b provides connection to drains of the module 4300a.

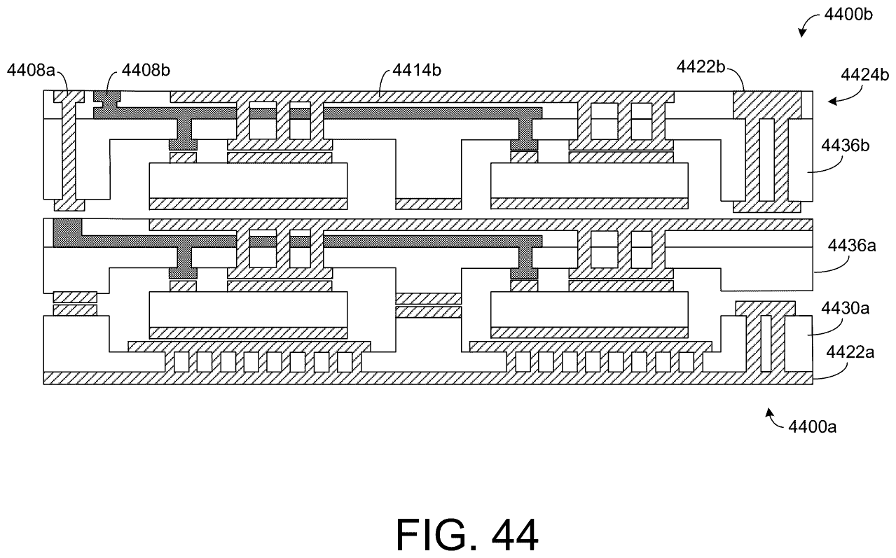

FIG. 44 is a cross-sectional view of an example stacked module in a half-bridge configuration. FIG. 44 is similar to FIG. 43, including a module 4400a and a module 4400b, with separate, respective gate connections 4408a, 4408b, a source connection 4414b, and a redistributed switch node 4422b.

However, in FIG. 43, the modules 4300a, 4300b each include dual substrates and dual cavities. In contrast, the module 4400a is a dual substrate, dual cavity module that includes first substrate 4430a and second substrate 4436a, but the module 4400b includes a second substrate 4436b, while using the module 4400a itself as a lower substrate. In further contrast with FIG. 43, in FIG. 44, a drain connection 4422a of the module 4400b is not routed to a RDL 4424 of the module 4400b. Instead, the drain connection 4422a is provided as an input VDD, while the redistributed switch node 4422b is used as an output, and the source connection 4414b is used as a ground connection. Thus, FIG. 44 may be observed to provide a half bridge configuration with the positive connection VDD on one surface, a negative/ground connection on the opposed surface, and the switch node 4422b in between.

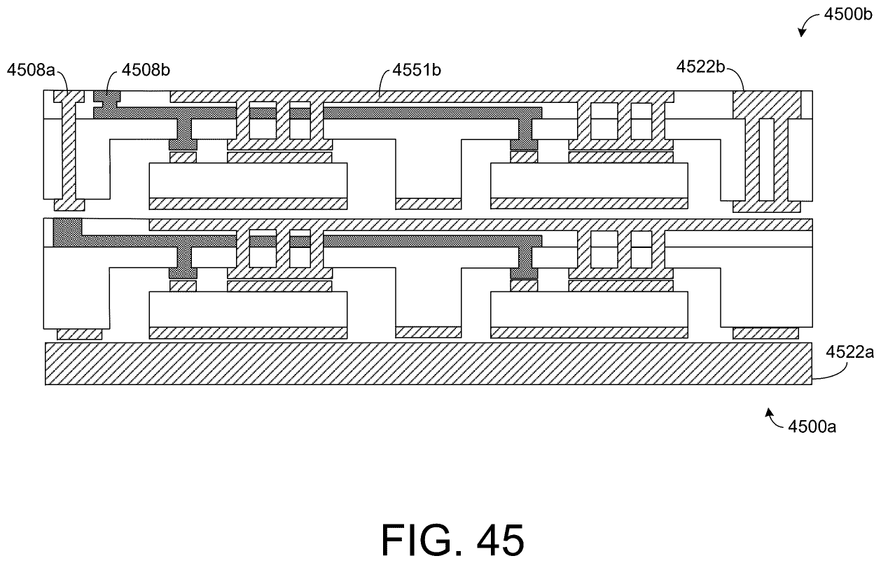

FIG. 45 is a cross-sectional view of an alternate example stacked module in a half-bridge configuration. FIG. 45 is similar to FIG. 44, including a module 4500a and a module 4500b, with separate, respective gate connections 4508a, 4508b, a source connection 4514b (GND), and a redistributed switch node 4522b (OUT). In FIG. 45, however, a substrate 4430a of FIG. 44 is replaced with a leadframe (e.g., a copper plate) to provide a drain connection 4522a (VDD/IN).

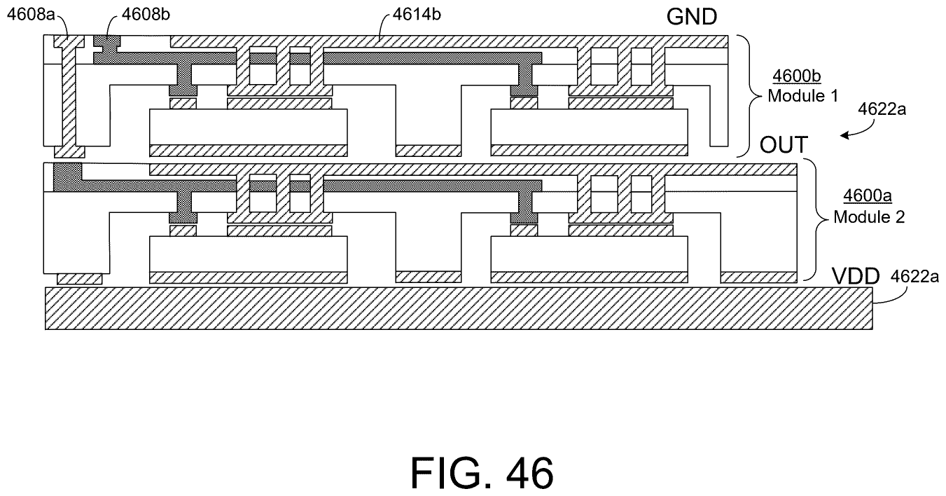

FIG. 46 is a cross-sectional view of a second alternate example stacked module in a half-bridge configuration. FIG. 46 is similar to FIG. 45, including a module 4600a and a module 4600b, with separate, respective gate connections 4608a, 4608b, a source connection 4614b (GND), and a redistributed switch node 4622b (OUT). As in FIG. 45, a substrate 4430a of FIG. 44 is replaced with a leadframe (e.g., a copper plate) to provide a drain connection 4622a (VDD/IN).

In FIG. 46, however, a module 4600a and a module 4600b are provided in a terraced configuration with respect to the leadframe/drain connection 4622a. That is, as shown, the module 4600a is shorter/smaller than the leadframe 4622a, while the module 4600b is shorter/smaller than the module 4600a.

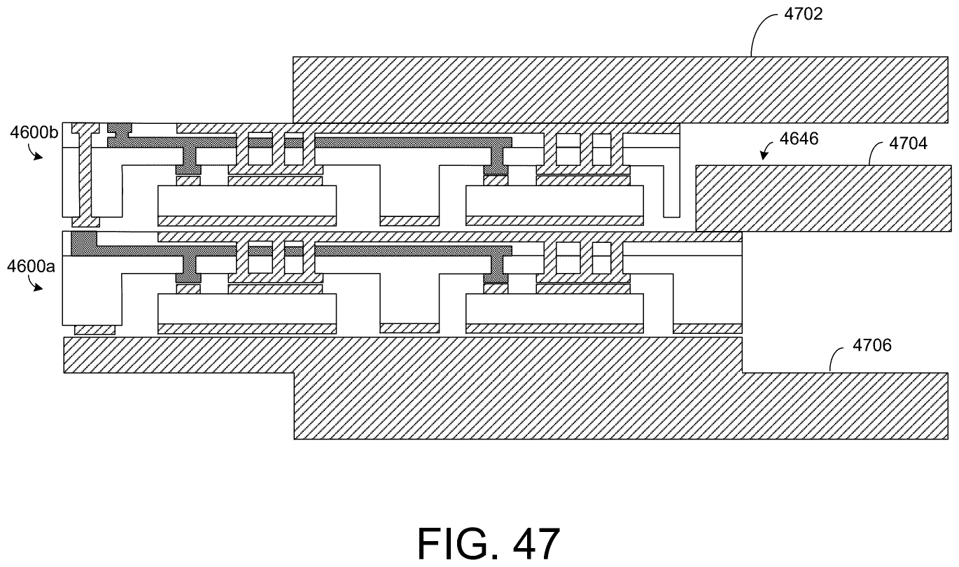

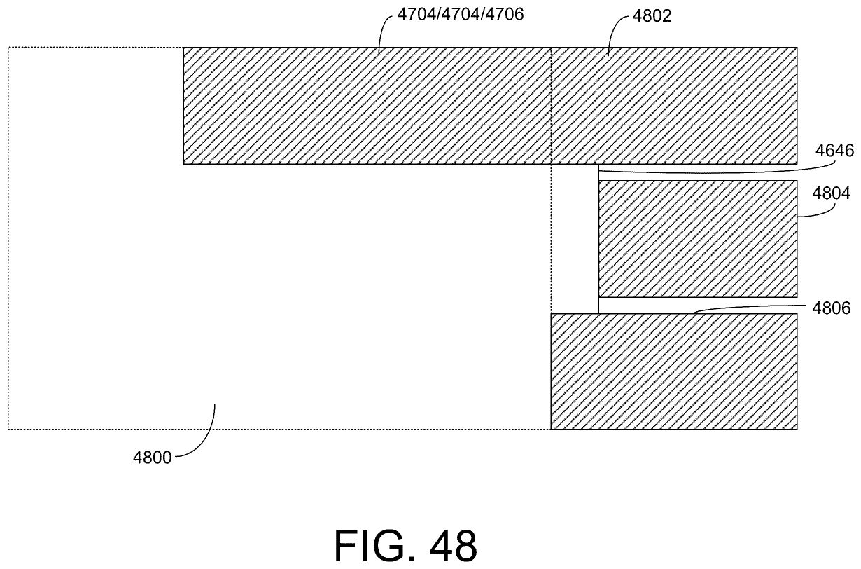

Consequently, while many of the described example embodiments include dual side electrical connectivity, as does the example of FIG. 46, the example of FIG. 46 further provides a connection 4646. As shown in FIG. 47, as well as in the top view of FIG. 48, the embodiment of FIG. 46 enables straightforward connection of power busbars 4702, 4704, and 4706, including a connection of the power busbar 4704 to the connection 4646.

FIG. 48 illustrates a top-side view of the example embodiment of FIG. 47, wherein the switch-node (OUT) busbar is affixed to the terraced connection, and the VDD and GND busbars are affixed to the top and bottom surfaces. In such a configuration, with respect to FIG. 47, tab/busbar 4804 corresponds to busbar 4706 in FIG. 47, whereas busbar 4806 corresponds to 4704 and 4802 corresponds to 4702.

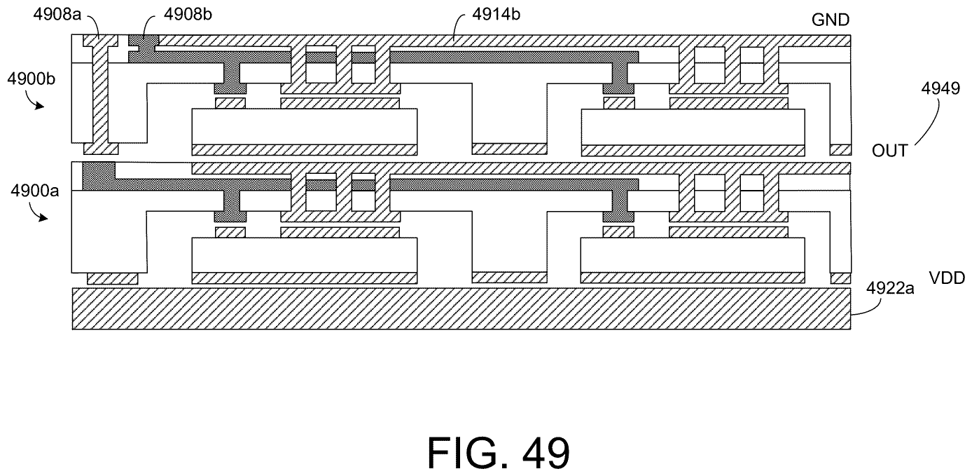

FIG. 49 is a cross-sectional view of an additional example stacked module in a half-bridge configuration. FIG. 49 is similar to FIG. 45, but with the three-level or top/middle/bottom GND/OUT/VDD connections of FIGS. 46-48. Specifically, as shown, FIG. 49 includes a module 4900a and a module 4900b, with separate, respective gate connections 4908a, 4908b, and a source connection 4914b (GND). A leadframe 4922a (e.g., a copper plate) provides a drain connection (VDD/IN). A redistributed switch node 4949 (OUT) is provided as the third power terminal.

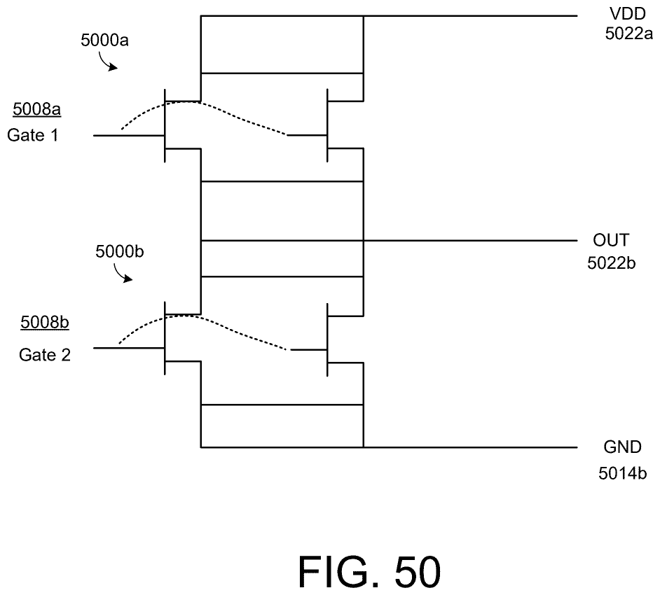

FIG. 50 is a circuit diagram for a stacked module in a half-bridge configuration, wherein a High-Side functional switch 5000a comprises two power semiconductors (transistors) connected in parallel with input 5008a, and the Low-Side functional switch 5000b comprises two transistors in parallel with input 5008b. The drain of the HS functional switch is the VDD (or positive DC) electrical terminal 5022a, and the source of LS is GND (or negative DC) electrical terminal 5014b. The HS source and LS drain common connection is the switch-node 5022b, which functions as an output. For example, in a traction inverter application, VDD is the positive battery terminal, GND is the negative battery terminal, and OUT is the phase-node connected to one of the motor phases. A typical EV motor has 3 phases, each of which would be driven by a half-bridge in a similar configuration as shown in FIG. 50, with the HS and LS functional switches comprising one or multiple (arbitrarily many) parallel semiconductors (transistors).

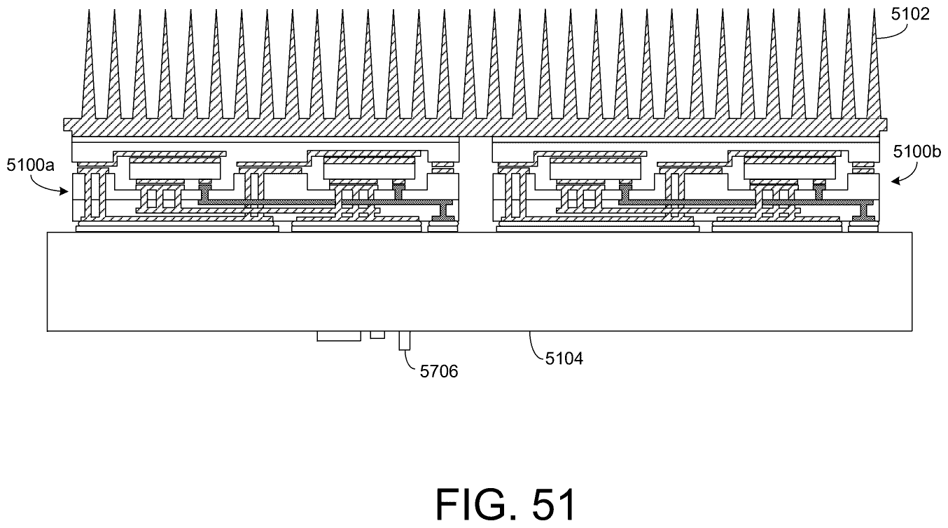

FIG. 51 is a cross-sectional view of a dual-cavity embodiment packaged with a printed circuit board 5104 and a heatsink 5102. FIG. 51 illustrates that multiple modules 5100a, 5100b, each including multiple dies, may share the common heatsink 5102. Further, the modules 5100a, 5100b may be connected to a common PCB 5104, using, e.g., any standard assembly technique, such as soldering. Further PCB components 5106 may also easily be included. In one example, 3 such half-bridge modules are combined—for example on a single cooling structure and/or control PCB—to form a 3-phase traction inverter power stage.

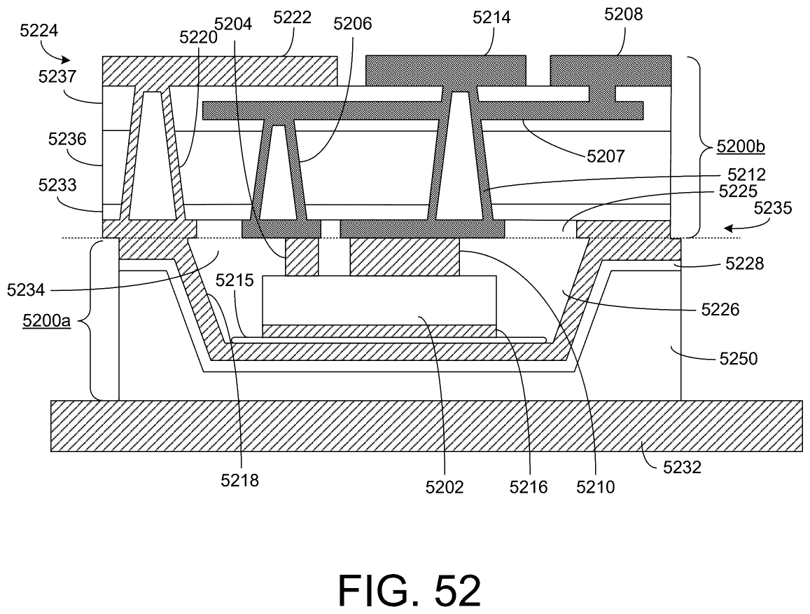

FIG. 52 is a cross-sectional view of a single-cavity embodiment with alternate gate routing and a bonded interface. FIG. 52 illustrates a semiconductor die 5202 with a sinter or solder or similar connection 5215 to a metal layer 5218. The semiconductor die 5202 has a gate pad 5204 connected through a gate via 5206 to a gate contact 5208, a source pad 5210 connected through source vias 5212 to a source contact 5214, and a drain pad 5216 connected to a metal layer 5218 and thereby to a drain contact 5222 through drain vias 5220.

In FIG. 52, the semiconductor die 5202 is disposed between a first substrate 5230, having a cavity 5234, and a second substrate 5236. Similar to the example embodiment of FIG. 3, the semiconductor die 5202 is encased within a dielectric 5226, which is disposed within the cavity 5234. Dielectric layers 5233 and 5237 are disposed on each surface of the second substrate 5236.

The gate connection 5208, source connection 5214, and drain connection 5222 are formed on the dielectric layer 5237, defining a RDL 5224. A dielectric or other electrically isolating layer 5228 may be formed between the first substrate 5230 and the metal layer 5218, and a leadframe 5232 may be mechanically connected to the substrate 5230 on a side opposed to the semiconductor die 5202, but not electrically connected to the semiconductor die 5202.

FIG. 52 illustrates an example in which a bottom assembly 5200a includes the semiconductor die 5202 within the cavity 5234, with associated elements as described above. Meanwhile, a top wafer portion 5200b includes the various vias and other points of connection, as also described above. The bottom assembly 5200a and the top wafer portion 5200b may be joined and bonded at a bonded interface 5235.

Metal attachment points 5235 are established to connect the second substrate 2436 to the first substrate 2430 and to the semiconductor die 2402. Thus, in some examples, the embodiment of FIG. 52 may be constructed using wafer-to-wafer bonding techniques, such as one or more of the techniques described above.

Also in FIG. 52, the gate connection 5208 is routed from the gate via 5206 across the source via 5212, using a routing layer 5207, so that the gate connection 5208 is on a different side of the source connection 5214, as compared to the gate pad 5204 relative to the source pad 5210. It is to be understood that the RDLs using one or more metal layers may be used to re-order (redistribute) the order and physical location of the top connections such as illustrated herein.

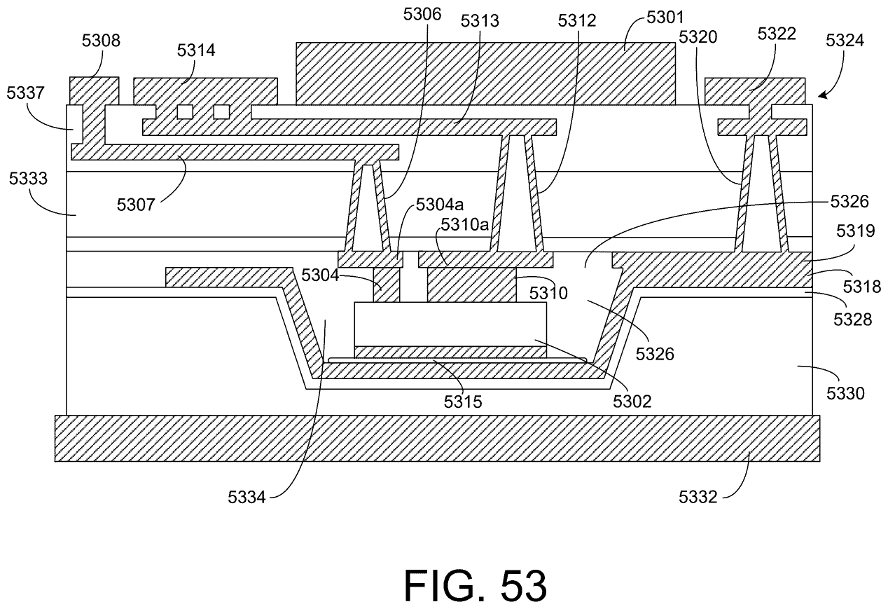

FIG. 53 is a cross-sectional view of a single-cavity embodiment with alternate gate and source routing to accommodate a heatsink 5301. FIG. 53 illustrates a semiconductor die 5302 with a sinter or solder or similar connection 5315 to a metal layer 5318. The semiconductor die 5302 has a gate pad 5304 connected through a gate via 5306 to a gate contact 5308, a source pad 5310 connected through source vias 5312 to a source contact 5314, and a drain pad 5316 connected to a metal layer 5318 and thereby to a drain contact 5322 through drain vias 5320.

The semiconductor die 5302 is disposed between a first substrate 5330, having a cavity 5334, and a second substrate 5336. The semiconductor die 5302 is encased within a dielectric 5326, which is disposed within the cavity 5334. Dielectric layers 5333 and 5337 are disposed on each surface of the second substrate 5336.

The gate connection 5308, source connection 5314, and drain connection 5322 are formed on the dielectric layer 5337, defining a RDL 5324. A dielectric or other electrically isolating layer 5328 may be formed between the first substrate 5330 and the metal layer 5318, and a leadframe 5332 may be mechanically connected to the substrate 5330 on a side opposed to the semiconductor die 5302, but not electrically connected to the semiconductor die 5302.

Also in FIG. 53, the gate connection 5308 is routed from the gate via 5306 away from the source via 5312, using a routing layer 5307, while the source connection 5314 is routed away from the source via 5312, using a routing layer 5313. Accordingly, space is created on a surface of the dielectric layer 5337 for a heatsink 5301. Advantageously, in FIG. 53, the heatsink 5301 may thus be positioned directly over, or otherwise proximate to, the semiconductor die 5302.

The example embodiment of FIG. 53 may be constructed using wafer fabrication techniques, without requiring wafer-to-wafer bonding. In the example of FIG. 53, a metal layer 5319 is added on a portion of the metal layer 5318 and coplanar with the a landing pad 5304a of the gate pad 5304 and a landing pad 5310a of the source pad 5310, in order to maintain planarity for further construction of the dielectric layer 5333 and remaining layers of the example of FIG. 53. Understanding that a heatsink may be attached to the thermal face (5332) and the electrical face (5301), the example embodiment of FIG. 53 achieves double-sided cooling. Similarly, double-sided cooling may be achieved similarly for any of the embodiments disclosed herein, as well as any embodiments not disclosed herein, by extension.

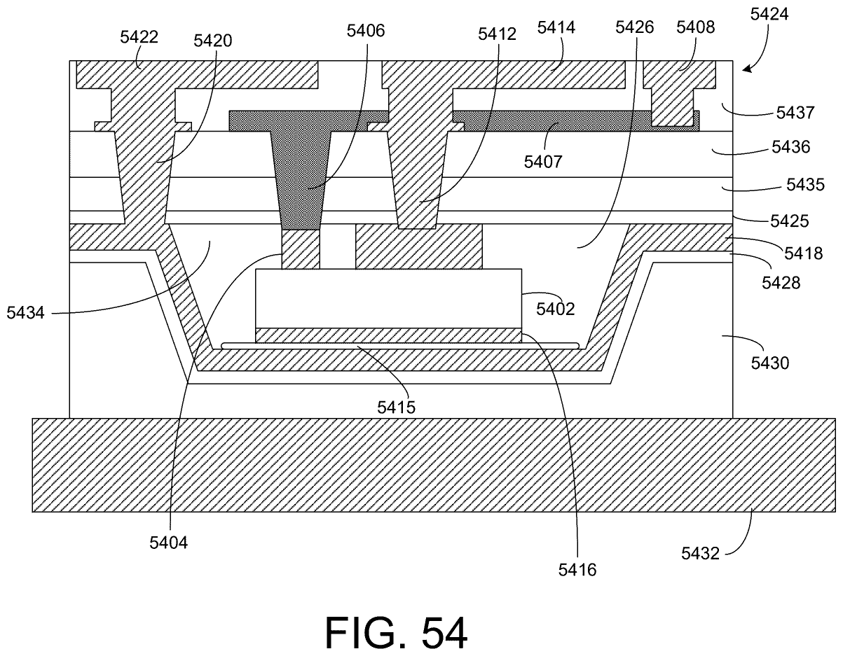

FIG. 54 is a cross-sectional view of a single-cavity embodiment with alternate gate routing. FIG. 54 illustrates a semiconductor die 5402 with a solder connection 5415 to a metal layer 5418. The semiconductor die 5402 has a gate pad 5404 connected through a gate via 5406 to a gate contact 5408, a source pad 5410 connected through source vias 5412 to a source contact 5414, and a drain pad 5416 connected to a metal layer 5418 and thereby to a drain contact 5422 through drain vias 5420.

In FIG. 54, the semiconductor die 5402 is disposed between a first substrate 5430, having a cavity 5434, and a second substrate 5436. The semiconductor die 5402 is encased within a dielectric 5426, which is disposed within the cavity 5434.

Dielectric layers 5433 and 5437 are disposed on each surface of the second substrate 5436, with the dielectric layer 5433 being disposed on an insulating layer 5425. For example, the dielectric layers 5433, 5437 may be provided using the same or similar material as the encapsulating dielectric layer 5426.

The gate connection 5408, source connection 5414, and drain connection 5422 are formed on the dielectric layer 5437, defining a RDL 5424. A dielectric or other electrically isolating layer 5428 may be formed between the first substrate 5430 and the metal layer 5418, and a leadframe 5432 may be mechanically connected to the substrate 5430 on a side opposed to the semiconductor die 5402, but not electrically connected to the semiconductor die 5402.

Also in FIG. 54, the gate connection 5408 is routed from the gate via 5406 across the source via 5412, using a routing layer 5407, so that the gate connection 5408 is on a different side of the source connection 5414, as compared to the gate pad 5404 relative to the source pad 5410.

FIG. 54 thus illustrates an example that is structurally similar to the example of FIG. 52, but constructed using the techniques of FIG. 53. That is, the embodiment of FIG. 54 may be constructed using silicon fabrication techniques, without requiring wafer-to-wafer bonding.

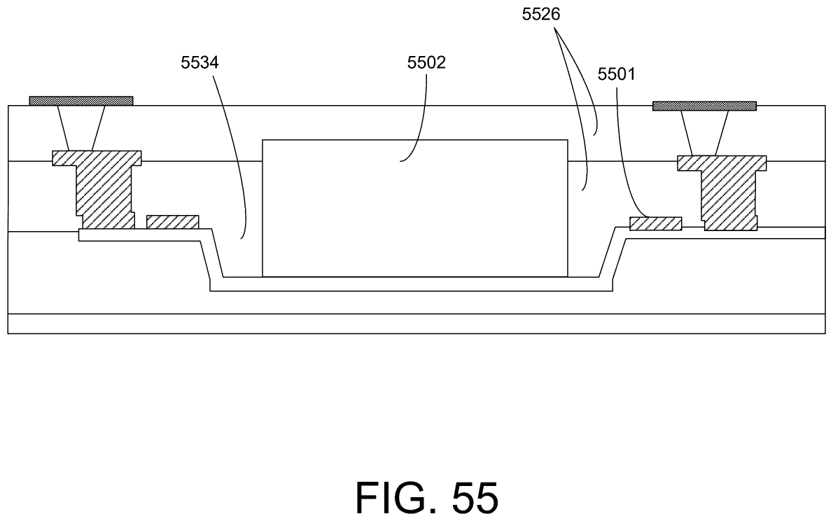

FIG. 55 is a cross-sectional view of a single-cavity embodiment with an embedded magnetic element. As described, e.g., with respect to FIG. 12, various embodiments may include a magnetic element, shown as magnetic element 5502 in FIG. 55, in the place of (or in addition to) the types of semiconductor dies described herein. For example, the magnetic element 5502 may include a ferric, ferrous material, or iron powder.

Further in FIG. 55, a winding 5501 represents a metallic element that is embedded in a spiral pattern around the magnetic element 5502. Remaining elements of FIG. 55 should be understood to represent non-limiting examples of embodiments described herein, so that any suitable or desired one(s) of the described embodiments should be understood to be usable in conjunction with the magnetic element 5502 and the spiral windings 5501.

Thus, FIG. 55 illustrates, for example, that a cylindrical ferrous or ferric puck may be used as a magnetic core and may be positioned within a cavity 5534 of a module, fully encapsulated by an insulating dielectric layer(s) 5526 to ensure electrical isolation while allowing thermal conduction.

The spiral winding 5501 may be formed from patterned metal layers and coil around the magnetic element 5502 in multiple turns. Not shown in FIG. 55, terminals of the spiral windings 5501 may be connected, e.g., to die contacts or external package leads, to provide electrical access.

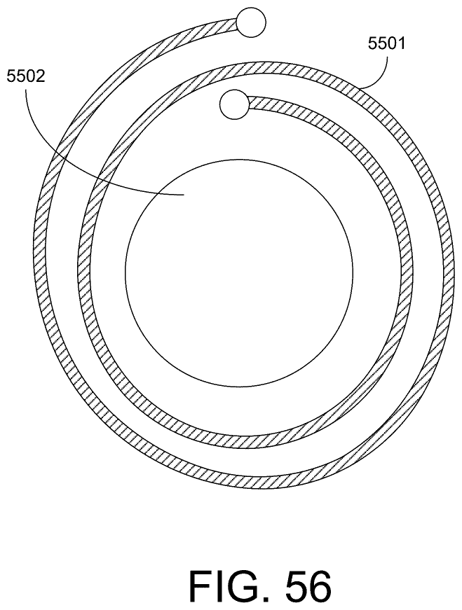

FIG. 56 is a top view of the example of FIG. 55. FIG. 56 illustrates the winding 5501 encircling the magnetic element 5502. More specifically, the magnetic element 5502 is illustrated as a circular puck, surrounded by the windings 5501 as a series of concentric spiral traces forming inductive windings that encircle the magnetic element 5502 for magnetic coupling. The spirals 5501, e.g., copper or aluminum, are illustrated as fanning out from an inner starting point near an edge of the magnetic element 5502 to an outer termination. Not shown in FIG. 56, but as appreciated from FIG. 55, insulating dielectric may be used to separate winding levels and prevent shorting.

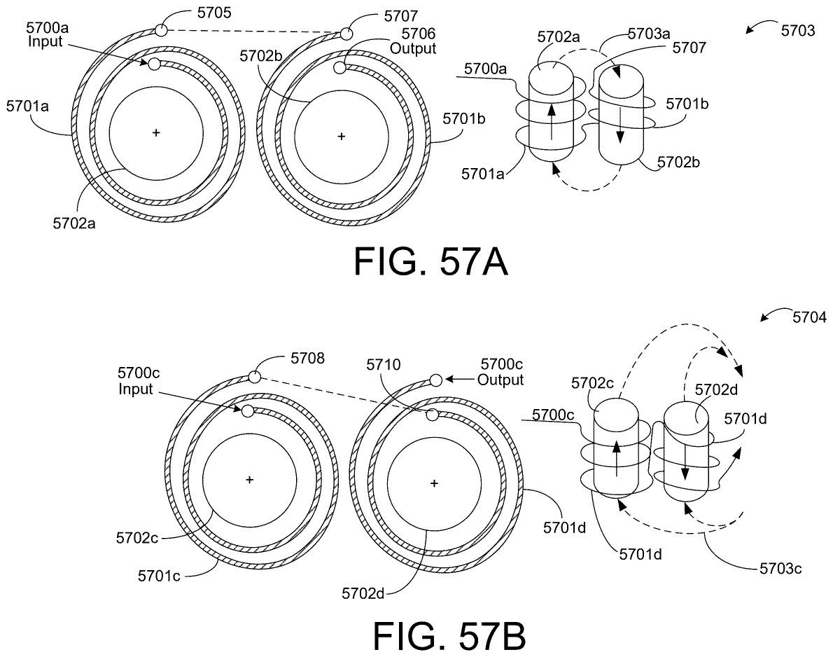

FIG. 57A illustrates a first example embodiment of the examples of FIG. 55 and FIG. 56. In FIG. 57A, windings 5701a surround magnetic element 5702a, while windings 5702b surround magnetic element 5702b. An input 5700a is illustrated at an innermost terminal of the windings 5701a, while an output of the windings 5701a at an outermost terminal 5705 is connected to an input at an outermost terminal 5707 of the windings 5702b. An output 5700b is illustrated at an innermost terminal of the windings 5702b.

In FIG. 57, for example, the magnetic elements 5702a, 5702b may be placed side-by-side within respective cavities, with windings 5701a, 5701b coiled in opposite directions to produce opposing magnetic fields. As shown in an isolated isometric view 5703, flux lines 5703a enter the magnetic element 5702a perpendicularly from the bottom (south pole) and exit the magnetic element 5702b similarly, resulting in cancellation between the magnetic elements 5702a, 5702b, e.g., for applications such as differential inductors or noise suppression. The spirals 5701a, 5701b enable routing currents in counter-rotating paths, resulting in flux arrows 5703a curving outward from the magnetic element 5702a and inward toward the magnetic element 5702b, minimizing crosstalk while maintaining isolation via dielectric encapsulation.

FIG. 57B illustrates a second example embodiment of the examples of FIG. 55 and FIG. 56. In FIG. 57B, windings 5701c surround magnetic element 5702c, while windings 5702d surround magnetic element 5702d. An input 5700c is illustrated at an innermost terminal of the windings 5701c, while an output of the windings 5701c at an outermost terminal 5708 is connected to an input at an innermost terminal 5710 of the windings 5702d. An output 5700d is illustrated at an outermost terminal of the windings 5702d.

As shown in an isolated isometric view 5704, flux lines 5703c enter the magnetic elements 5702c, 5702d perpendicularly from the bottom (south pole) and exit the magnetic elements 5702c, 5702d similarly, resulting in additive fields that amplify mutual inductance for coupled applications such as, e.g., common-mode chokes.

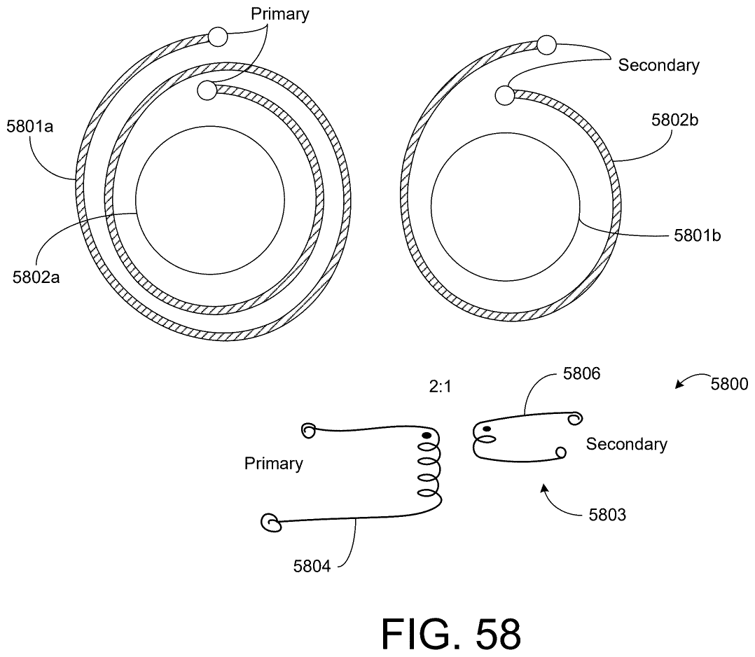

FIG. 58 illustrates a third example embodiment of the examples of FIG. 55 and FIG. 56. FIG. 58 illustrates an embedded transformer application in which a magnetic element 5802a is encircled by spiral windings 5801a to provide a primary winding and a magnetic element 5802b is encircled by spiral windings 5801b to provide a secondary winding.

As represented in the corresponding, illustrated circuit diagram 5800, a transformer may thus be provided with primary winding 5804 having a 2:1 ratio with a secondary winding 5806 to achieve, e.g., a desired step-down voltage ratio. Not shown explicitly in FIG. 58, it will be appreciated from the present description that vias may be used at inner and outer terminals of the windings 5801a, 5801b to establish electrical connections. In one example application, the secondary output may be connected to a load resistor through a rectification diode for DC conversion, to thereby provide desired voltage stepping within a power module for applications such as, e.g., isolated power delivery in traction inverters. The puck-shape described and illustrated above may be cylindrical in nature as illustrated, or may be implemented using a number of other forms. Such forms may include, e.g., candy-bar shaped, donut-shaped, U-shaped, E-shaped or many other forms. Likewise it should be appreciated that multiple layers of windings can be realized (e.g., spirals in multiple metal layers in embodiments such as that of FIG. 3 or others, e.g., using vias to interconnect layers/windings as appropriate. Although windings are shown here to be closed in a spiral manner around the z-axis, it should be appreciated that it is also possible to realize windings in x and/or y axis using multiple metal layers and using vias to connect the metal layers in z, as may be understood from the example of FIG. 12. Further, inductors, coupled inductors, transformers, matrix transformers and other magnetic structures are realizable using the general techniques described here.

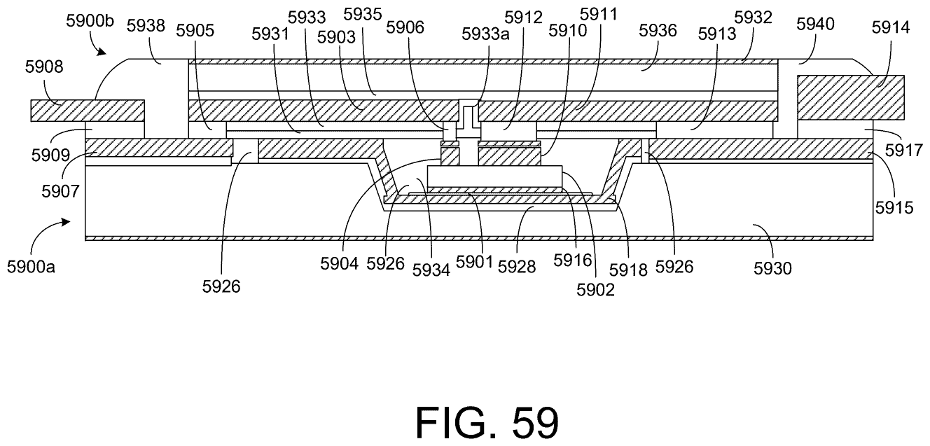

FIG. 59 is a cross-sectional view of an alternate single-cavity embodiment. FIG. 59 illustrates a semiconductor die 5902 with a solder connection 5901 to a metal layer 5918. The semiconductor die 5902 has a gate pad 5904 with solder connection 5906 to metal layer 5903, having solder connection 5905 to metal layer 5907 that has a solder connection 5909 to a gate contact 5908. A source pad 5910 has a solder connection 5912 to a metal layer 5911, which has a solder connection 5913 to a metal layer 5915 that is connected through a solder connection 5917b to a source contact 5914. A drain pad 5916 us connected to a metal layer 5918 with the solder connection 5901, and thereby to a drain contact that is not shown in the cross section of FIG. 59.

The semiconductor die 5902 is disposed between a first substrate 5930, having a cavity 5934, and a second substrate 5936. The semiconductor die 5902 is encased within a dielectric 5926, which is disposed within the cavity 5934. Dielectric layers 5931 and 5933 provide isolation for the various metal layers 5918, 5903, and 5911, while a dielectric layer 5935 electrically isolates the second substrate 5936.

Further in FIG. 59, a back metal 5937 may be attached to the first substrate 5930, and/or a back metal 5932 may be attached to the second substrate 5936. An encapsulant 5938 may be used to isolate the gate contact 5908 from the second substrate 5936, while an encapsulant 5940 may be used to isolate the source contact 5914 from the second substrate 5936.

Thus, FIG. 59 illustrates a lower or bottom assembly 5900a covered by an upper or top assembly 5900b. Example techniques for forming the example of FIG. 59 are described in detail, below, and other examples may be constructed, as well.

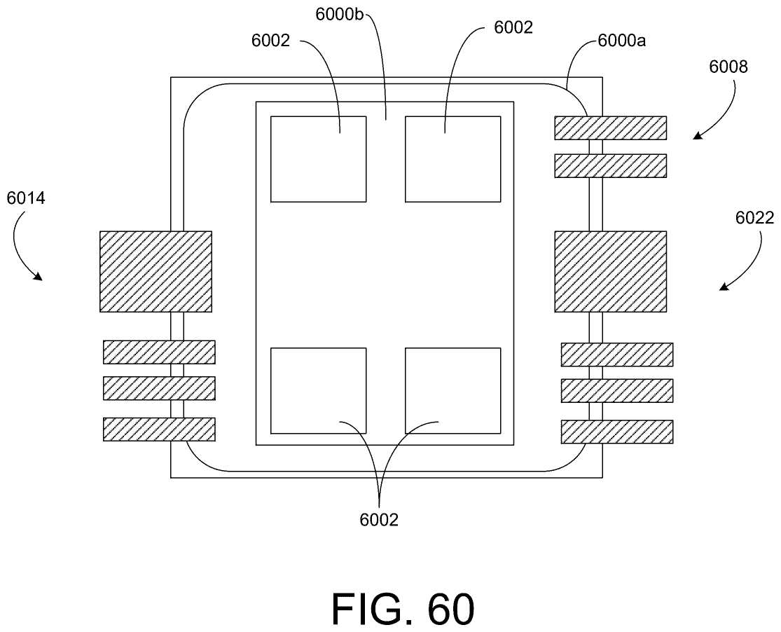

FIG. 60 is an example top view of the embodiment of FIG. 59. In FIG. 60, a lower assembly 6000a corresponding to the lower assembly 5900a of FIG. 59 is illustrated as including four dies 6002, which may represent SiC or GaN power dies. An assembly 6000b corresponding to the upper assembly 5900b of FIG. 59 is illustrated transparently as covering the dies 6002, in accordance with the embodiment of FIG. 59.

Source leads 6014 and drain leads 6022 enable parallel current sharing/current distribution for high power applications, e.g., in a half-bridge configuration. Gate connection 6008 are also illustrated. Of course, many other layouts are possible.

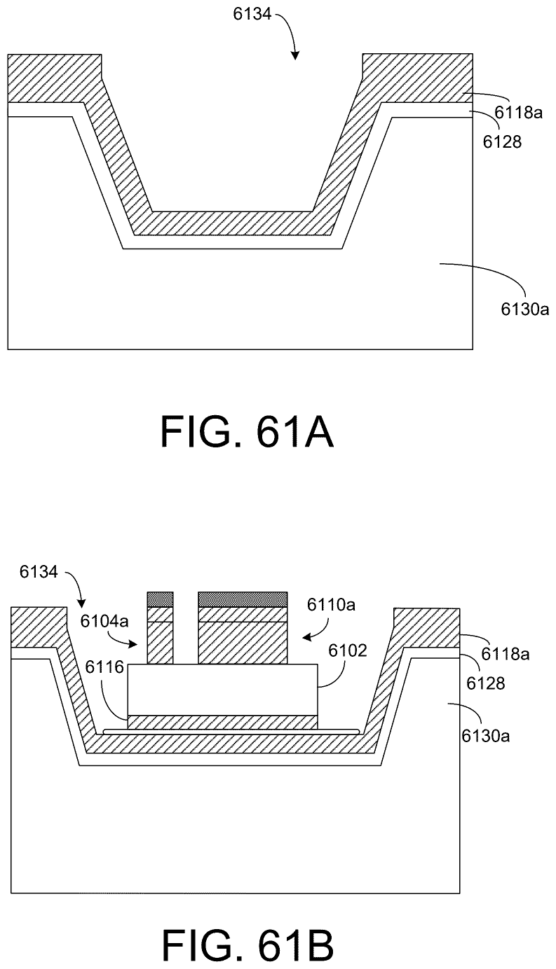

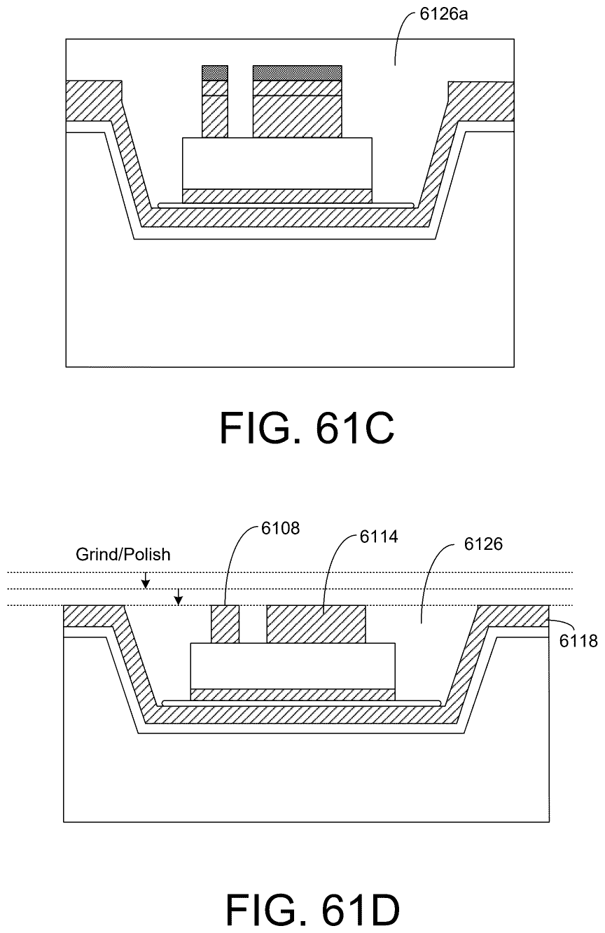

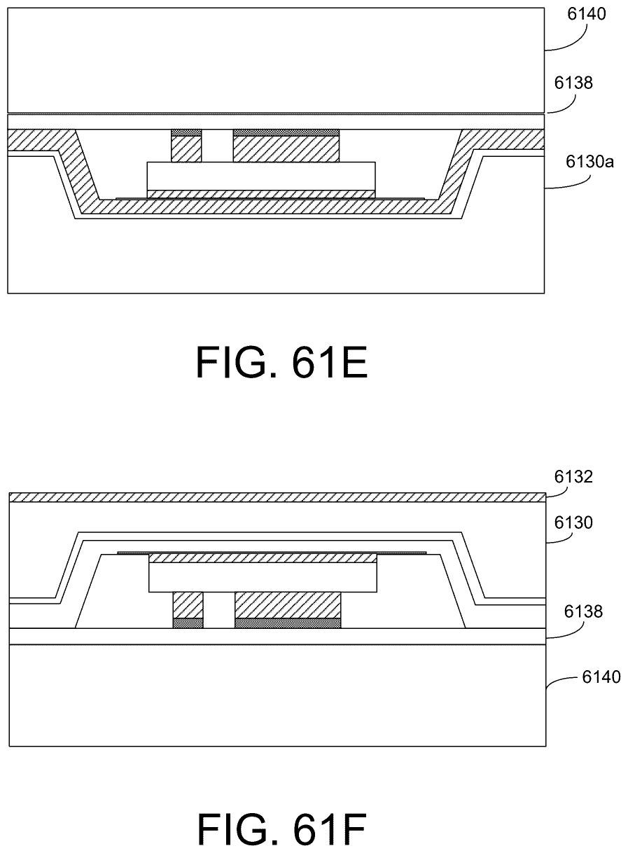

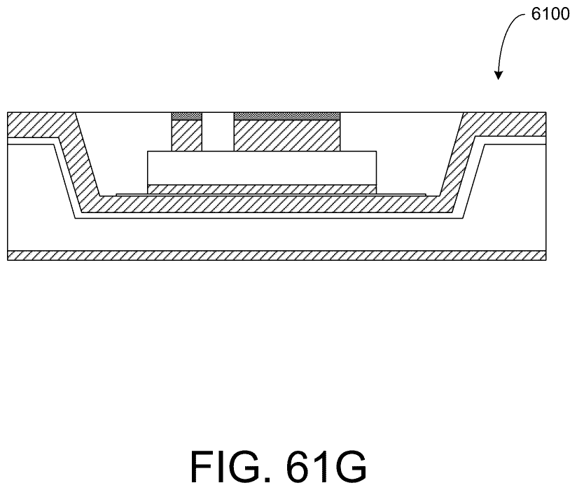

FIGS. 61A-61G illustrate example processes for forming a lower assembly of FIG. 59. In FIG. 61A, a cavity 6134 is etched in a substrate 6130a. A dielectric layer 6128 is deposited, and then a conducting layer 6118a is deposited. In FIG. 61B, a semiconductor die 6102 is soldered to the conducting layer 6118, including a gate pad 6104a and a source pad 6110a.

In FIG. 61C, an electrically isolating/dielectric material 6126a, e.g., not including a mold compound, is deposited. In FIG. 61D, grinding and polishing is performed to provide a planar surface with the dielectric material 6126, conducting layer 6118, gate pad 6108, source pad 6114, and conducting layer 6118.

In FIG. 61E, glass 6140 (or tape, or other suitable material) may be bonded to the assembly using bonding layer 6138. In this way, thinning of the substrate 6130a to obtain the thinned substrate 6130 may proceed. The wafer back side may be chemically etched to relieve grinding stress and to prepare the surface for back metal deposition. Then, a backside metal 6132 may be added. Accordingly, as show in FIG. 61G, the glass 6140 may be removed to obtain bottom assembly 6100.

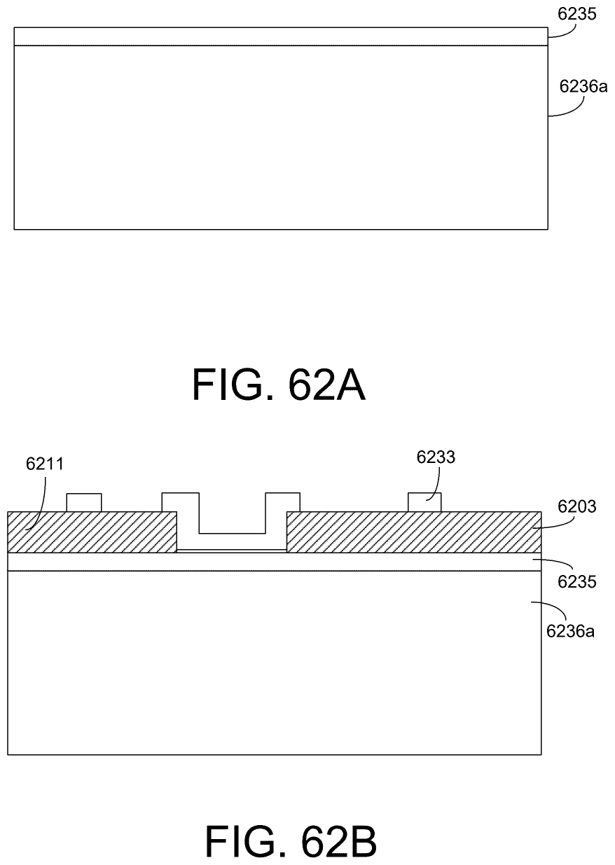

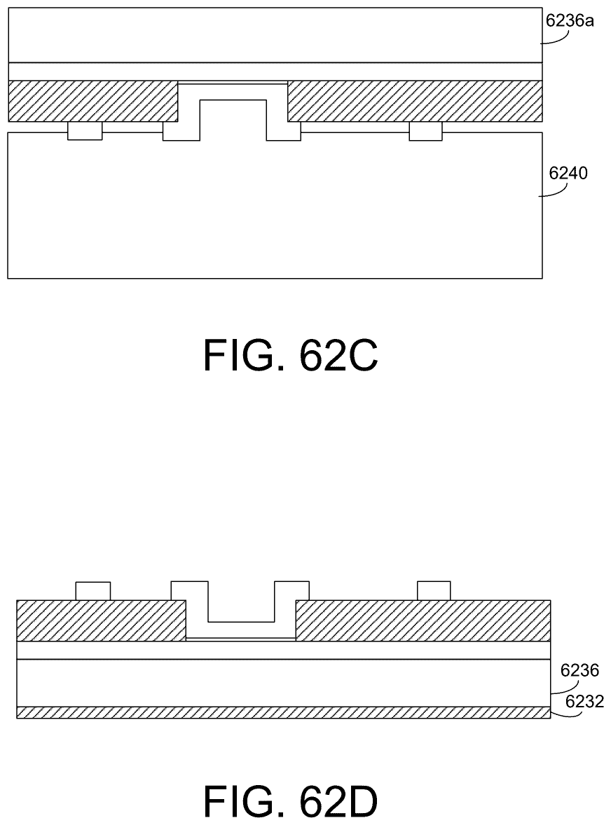

FIGS. 62A-62D illustrate example processes for forming an upper assembly of FIG. 59. In FIG. 62A, a substrate 6236a has a dielectric layer 6235 formed thereon. In FIG. 62B, a patterned metal layer including metal layers 6211, 6233 is added, which (as may be appreciated from FIG. 59) may be used for source/gate connections to the lower assembly 6100 of FIG. 61G. Then, electrically isolating layer 6233 may be added, as shown.

In FIG. 62C, tape or glass 6240 is added to enable flipping and thinning of the substrate 6236a. As shown in FIG. 62D, following such thinning to obtain the thinned substrate 6236, a back metal layer 6232 may be added. Not illustrated separately, mounting tape and associated framing may proceed, followed by debonding and dicing for mounting on (e.g., soldering to) the lower assembly of FIG. 59 or FIG. 61G, using suitable encapsulant/underfill.

Thus, FIGS. 59, 60, 61A-61G, and 62A-62D generally illustrate that any desired die or other element may be bonded within a cavity of a first (bottom) wafer, and that the wafer may be thinned, and a back metal applied if desired. A second (top) wafer built with a single-level RDL (or more) may be thinned and may also be provided with a back metal, if desired. The second wafer may then be diced and the resulting diced pieces may be die bonded to the first wafer. Lead frame attachment and final encapsulation may then be completed to obtain, e.g., the example package of FIG. 60.

Many variations in resulting modules are possible. For example, the second wafer, and thus the diced pieces, may have active devices mounted therein or thereon. Similarly, temperature sensors (e.g., Negative Temperature Coefficient (NTC) sensors, or similar) and/or passive elements can be mounted on either or both of the first or second substrate.

Many processing variations are possible, as well. For example, one or both wafers may be thinned, and one or both sides of the module(s) may have back metal(s). Selection of thinning/back metal use may be made, e.g., to facilitate mechanical stress/bending control, and for reliability at high temperatures and in thermal cycling.

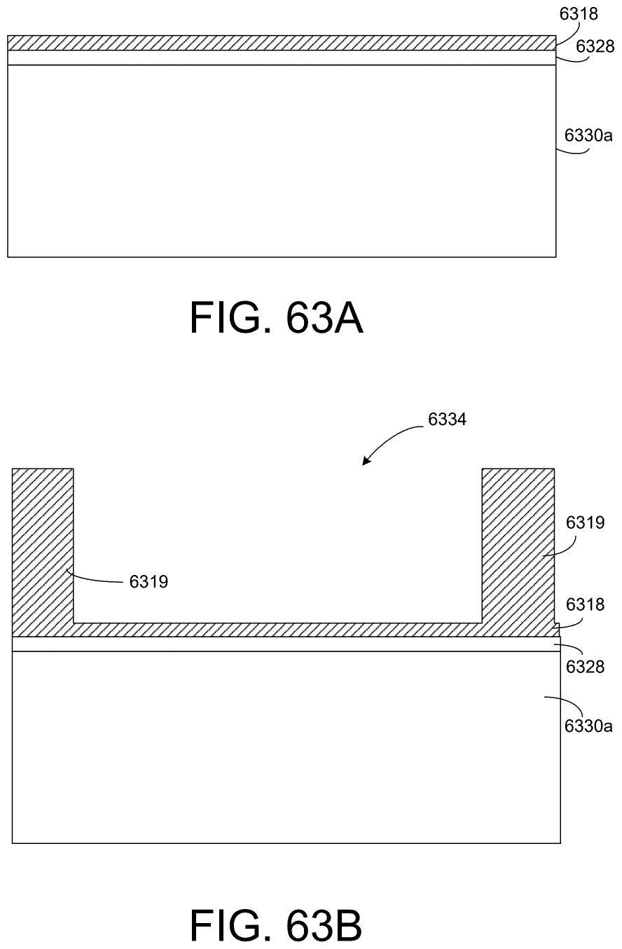

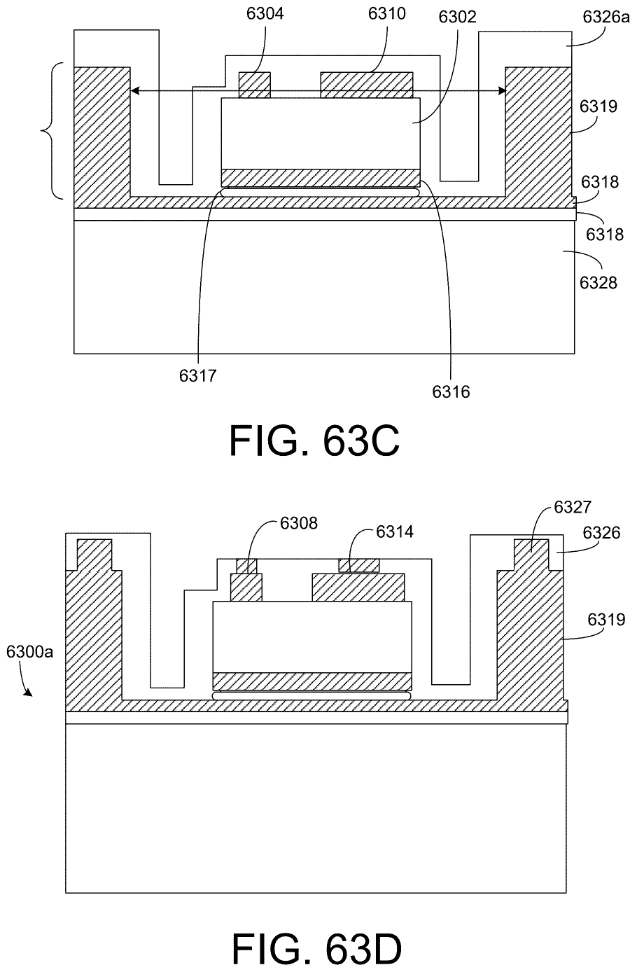

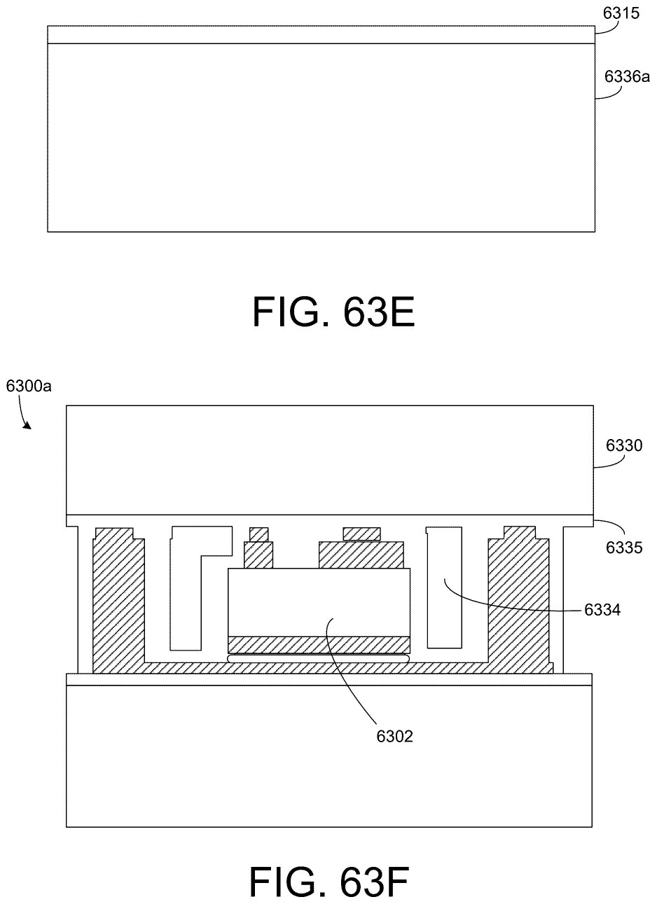

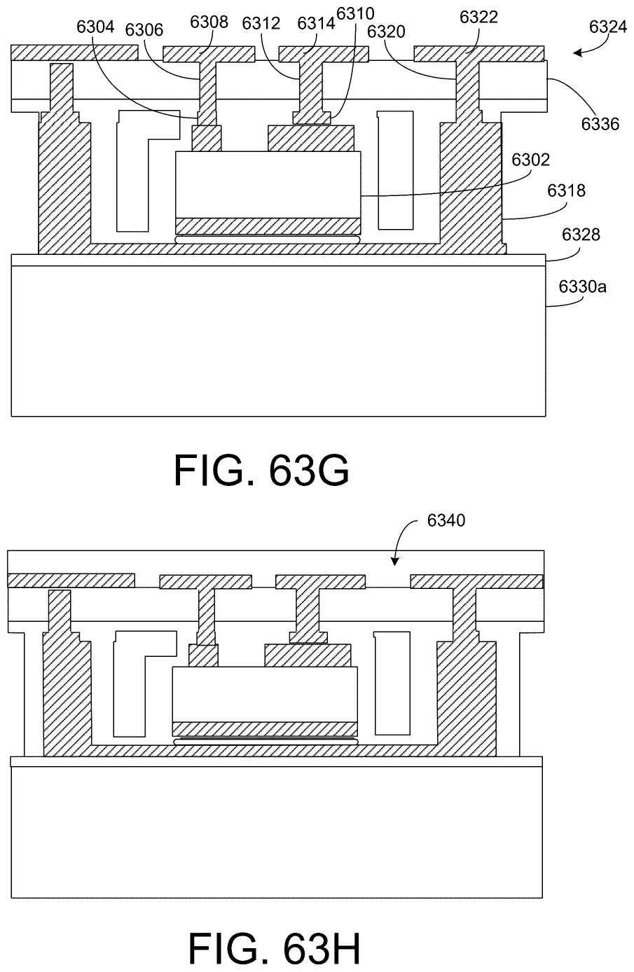

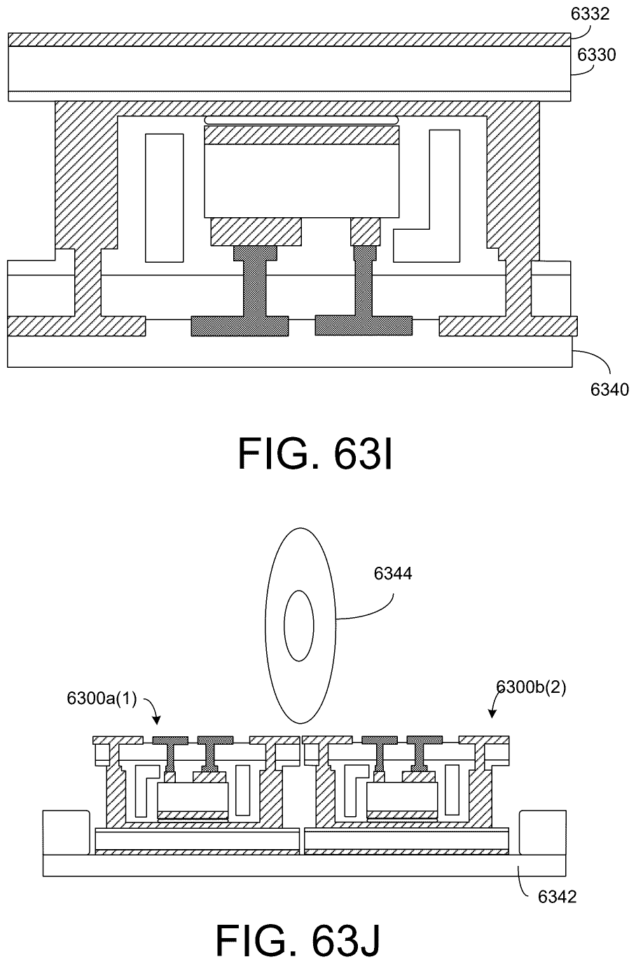

FIG. 63A-63J illustrate example processes for forming an alternate embodiment with metal pillars. In FIG. 63A, a first or bottom/lower substrate 6330a (wafer) is cleaned and a dielectric layer 6328 is formed thereon. A metal layer 6318 is then deposited on the dielectric layer 6328. In FIG. 63B, metal pillars 6319 are formed, e.g., plated, onto the metal layer 6318. As described and illustrated below, the metal pillars 6319, in conjunction with the metal layer 6318, effectively provide a cavity 6334. Therefore, for example, a height of the metal pillars 6334 may be selected to be a height of a semiconductor die or other element to be included within the cavity 6334.

In FIG. 63C, a semiconductor die 6302 having a gate pad 6304, source pad 6310, and drain pad 6316, is connected to the metal layer 6318 with a solder connection 6307 (or sinter connection). Then, an electrically-isolating material 6326a, e.g., silicon oxide or oxide/nitride, is provided. In FIG. 63C, etching is performed, thereby forming electrically-isolating layer 6326 and an end 6327 of the metal pillars 6319, while exposing gate pad 6304 and source pad 6310. Accordingly, a bottom portion or assembly 6300a is formed.

In FIG. 63E, a second or top/upper wafer 6336a is cleaned, and a dielectric layer 6335 is formed thereon. As shown in FIG. 63F, the second wafer 6336 may then be flipped and mounted onto the bottom assembly 6300a, e.g., in a wafer-to-wafer bonding process. As illustrated, a portion of the cavity 6334 may be left open or air-filled. The pillars 6319 may be formed without wrapping around the semiconductor die 6302, in case future underfill processes are used following later dicing, and the metal pillars 6319 are formed recessed from an outer edge of the module so as not to extend into dicing channels.

In FIG. 63G, the second wafer 6336a is thinned to provide thinned second substrate 6336. Then, a gate via 6306 is formed to establish a gate contact 6308, a source via 6312 is formed to establish a source contact 6314,, and a drain via 6320 is formed to establish a drain contact 6322. Accordingly, a RDL 6324 is established.

In FIG. 63H, tape 6340 (or glass adhesive bond) is attached, which, as shown in FIG. 63I, enables backside thinning of the first substrate 6330a to obtain thinned first substrate 6330. A metal layer 6332 may then be formed, e.g., by sputtering or plating, where the metal layer 6332 may be patterned or uniform (e.g., depending on a dicing method to be used). Finally, in FIG. 63J, a saw 6344 or other dicing method may be used in conjunction with mounting tape 6342 to singulate a module 6300(1) and a module 6300(2).

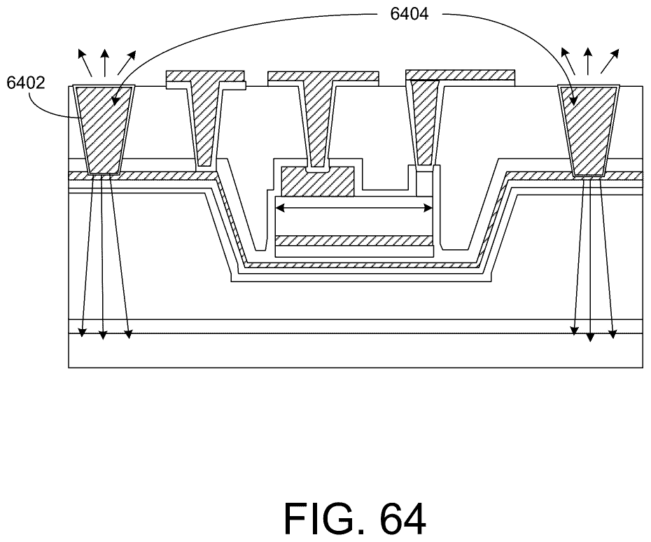

FIG. 64 is a cross-sectional view of an example embodiment with heat sinks 6404 formed in vias 6402. As shown in FIG. 64, additional heat sinks 6404 may be formed as dummy metal posts in vias 6402. The vias 6402 may be formed during formation of other vias of the module of FIG. 64, e.g., simply by including a mask modification for the mask already being used to form existing vias. Accordingly, the heat sinks 6404 may be formed in any desired location.

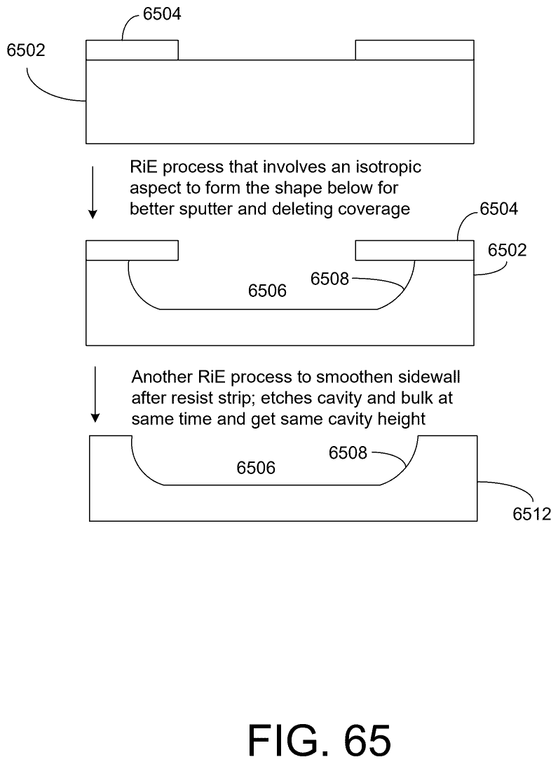

FIG. 65 illustrates an example process flow for forming cavities that may be used with various embodiments. In FIG. 65, in process 6500a, a wafer 6502 is provided with resist 6504, which is applied, exposed, and developed to define an opening 6505.

Then, in process 6500b, a combination of anisotropic and isotropic reactive ion etching (RIE) process may be performed that etches a cavity 6506 that has sloped sidewalls 6508. The shape of the cavity can be controlled by changing process parameters (e.g., gas flows, pressures, power, bias voltage, or others). Finally, in process 6500c, following removal of the resist 6504, a second RIE process is performed to smooth the sloped sidewalls 6508 following resist removal.

Accordingly, the sidewalls 6508 have a smooth and gradual sloping that is suitable for dielectric and metal coverage, and may be used in any of the embodiments described herein.

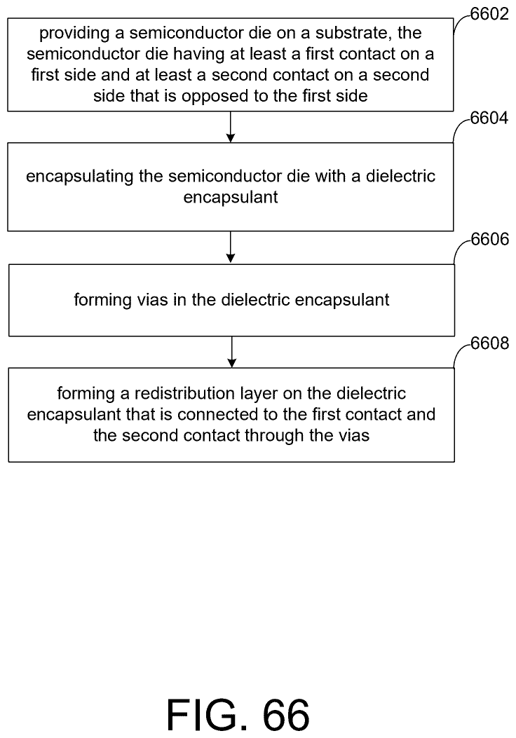

FIG. 66 is a first flowchart illustrating example embodiments. FIG. 66 illustrates example embodiments that include providing a semiconductor die on a substrate, the semiconductor die having at least a first contact on a first side and at least a second contact on a second side that is opposed to the first side (6602), and encapsulating the semiconductor die with a dielectric encapsulant (6604). The example embodiments of FIG. 66 further include forming vias in the dielectric encapsulant (6606) and forming a redistribution layer on the dielectric encapsulant that is connected to the first contact and the second contact through the vias (6608).

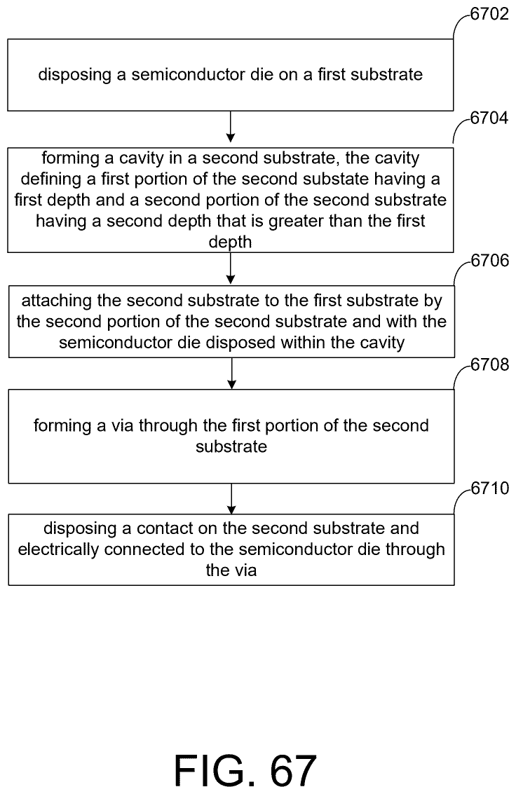

FIG. 67 is a second flowchart illustrating example embodiments. FIG. 67 illustrates example embodiments that include disposing a semiconductor die on a first substrate (6702) and forming a cavity in a second substrate, the cavity defining a first portion of the second substrate having a first depth and a second portion of the second substrate having a second depth that is greater than the first depth (6704). The example embodiments of FIG. 67 further include attaching the second substrate to the first substrate by the second portion of the second substrate and with the semiconductor die disposed within the cavity (6706), forming a via through the first portion of the second substrate (6708), and disposing a contact on the second substrate and electrically connected to the semiconductor die through the via (6710).

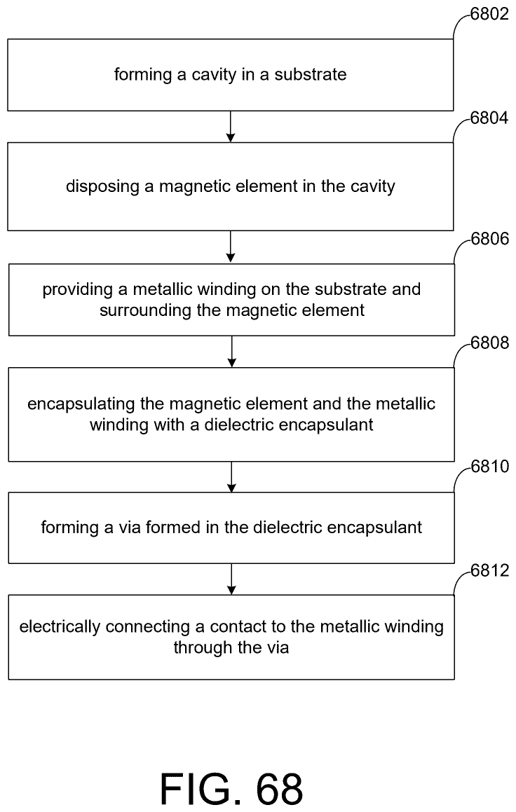

FIG. 68 is a third flowchart illustrating example embodiments. FIG. 68 illustrates example embodiments that include forming a cavity in a substrate (6802), disposing a magnetic element in the cavity (6804), and providing a metallic winding on the substrate and surrounding the magnetic element (6806). The example embodiments of FIG. 68 further include encapsulating the magnetic element and the metallic winding with a dielectric encapsulant (6808), forming a via formed in the dielectric encapsulant (6810), and electrically connecting a contact to the metallic winding through the via (6812).

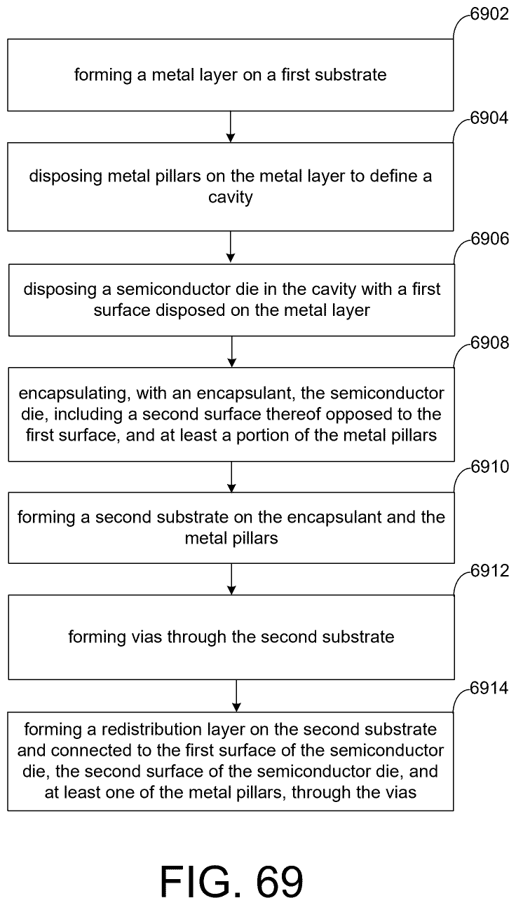

FIG. 69 is a fourth flowchart illustrating example embodiments. FIG. 69 illustrates example embodiments that include forming a metal layer on a first substrate (6902), disposing metal pillars on the metal layer to define a cavity (6904), and disposing a semiconductor die in the cavity with a first surface disposed on the metal layer (6906). The example embodiments of FIG. 69 further include encapsulating, with an encapsulant, the semiconductor die, including a second surface thereof opposed to the first surface, and at least a portion of the metal pillars (6908) and forming a second substrate on the encapsulant and the metal pillars (6910). The example embodiments of FIG. 69 further include forming vias through the second substrate (6912), and forming a redistribution layer on the second substrate and connected to the first surface of the semiconductor die, the second surface of the semiconductor die, and at least one of the metal pillars, through the vias (6914).

Thus, as described herein, example embodiments may include a device embedded in a substrate, to provide heat spreading, coefficient of thermal expansion compatibility, lower package thermal/electrical resistance, and other electrical or thermal characteristics. The device may include a semiconductor die, packaged electronic device, or multi-chip module, and the substrate may include a semiconductor substrate. The device and substrate may include silicon, silicon carbide, GaN, GaaS, other wide band gap materials, hybrid materials, or any other electronics/semiconductor material. The substrate may include one or more through-vias for electrical connections to one or more electrical interconnects on the device.

The device may include a MOSFET, IGBT, or other power, sensor, processor, or other integrated circuits. The device may include one or more electrical interconnects on a top and/or a bottom major surface such as a gate, source, drain, other signals, or dummy circuit. The substrate include one or more blocks integrated to form a larger substrate block with a cavity, a lid, a top, and a bottom surface. The substrate include one or more redistribution layers on the top and/or the bottom surface, with the RDL including one or more exposed external electrical interconnect surfaces.

A non-conducting material may be used to secure the device(s) within a cavity. The device may be attached to the substrate, RDL, or through-via with an electrically conducting material. The lid wafer/substrate/assembly and/or RDL may include conducting and non-conducting layers. The substrate and/or device may include one or more patterned layers to form electrical circuits, blind and/or through vias, and/or the substrate and/or device may include one or more electrical interconnects comprising one or more wire bonds, clips, diffusion bonds, pillar, or combinations thereof. The non-conducting metal layers may include, e.g., gold, silver, aluminum, titanium, nickel, TiW, copper, nickel vanadium, or any combinations or alloys thereof.

Various example embodiments may include an array comprising one or more of the apparatus implementations, as described above. Various example embodiments may include a method for making the apparatus or array thereof, and/or a method for assembling the apparatus or array thereof. Various example embodiments may include a power system including one or more of the apparatus or array thereof, a traction motor system including one or more of the apparatus or array thereof, and/or a multi-phase motor system including one or more of the apparatus or array thereof.

Example embodiments include an embodiment with a single piece of silicon (e.g., with a cavity) on top of a metal plate. Such embodiments may include a single device or multiple devices in parallel (e.g., with direct-connected drain(s)).

Embodiments may include one cavity per device or one cavity for multiple dies. There may be a different number of cavities (with different sizes) in a lower/bottom assembly than vs. in an upper/top assembly. One or more cavities in a lower/bottom assembly substrate may be different in depth than in the upper/top assembly. Different cavities in a single substrate may be different depths (e.g., to accommodate dies of different thicknesses), including a cavity that extends entirely through a depth of a substrate(s). There may be a cavity or cavities in only one of the lower/upper assemblies.

As described above, electrical isolation and thermal conduction may be provided on one side of example modules, while all electrical conduction/connection is provided on the opposed side of the module, e.g., using a RDL and vias (e.g., TSVs). For example, an upper/top surface may provide electrical connectivity while a lower/bottom surface provide thermal conductivity, or vice versa. In other examples, a top or bottom may be electrically conducting on part of the surface area, while another portion is electrically isolated (but thermally conductive), thus allowing for partial dual-sided cooling.

Example embodiments redistribute signals along a top surface of a lower/bottom substrate with the upper/top substrate recessed to provide electrical connectivity, while enabling electrically isolated double-sided cooling. Alternatively, redistribution may occur along a bottom of the upper/top substrate.

Spacing of power discretes in the substrates may be designed in such a way that heat generation, spreading, and/or signature are optimized.

Embedded active circuitry may be in either or both top/bottom substrate(s). One of the top/bottom substrates may be recessed to provide an exposed middle surface for connectivity. Active circuitry may be included in a second embedded die that is interconnected with a first embedded die through redistribution layer(s).

Example embodiments provide an ability to interface one or both substrates with different materials, e.g., for thermal conductivity with electrical isolation. For example, direct bonding of silicon to diamond may be provided.

In some examples, chemical vapor deposition (CVD) diamond may be used. In some examples, insulators used may be both electrically insulating and highly thermally conductive. For example, such insulators may include Si3N4 or CVD diamond.

In some examples, one or more colling elements may be used, which may include a Thermoelectric cooler (TEC), a heat sink, or a LTCC (Low Temperature Co-fired Ceramic) cavity (a hollow space created within a multilayered LTCC substrate; used to manufacture high-performance passive components like filters and antennas). In this context, LTCC technology refers to a way to manufacturer multilayer circuits from ceramic substrates. An example LTCC device may include multiple dielectric layers, screen-printed or photo-imaged low-loss conductors, embedded baluns, resistors and/or capacitors, and via holes for interconnecting the multiple layers. Other examples include a thin film substrate with microfluidic channels, flexible thermo-electric generator (TEG) cooling, one or more microfluidic channels (on any desired/available side of a device), liquid cooling, a heat exchanger (e.g., an evaporative heat exchanger), and/or air/refrigerant flow.

Various techniques may be used for connected two or more of the above cooling elements, or portions thereof. For example, techniques and/or connective components may include a heat clamp, thermal vias and/or through silicon vias (TSVs), thermal glue, thermal great, a heat pipe, sintering or soldering.

Example embodiments may include electrically conducting redistributed terminals that are soldered onto a PCB using standard PCB fabrication/assembly techniques and technologies such as soldering (e.g., reflow and/or wave). In other embodiments, such terminals may be soldered, welded, bolted or otherwise connected (mechanically and electrically, e.g., using ACA bonding) to any electrically conducting conduit such as PCBs, bus-bars or similar.

Example embodiments may include embedded MEMS technology in one or both of the top/bottom substrate(s), and/or in a separate embedded die. For example, MEMS technology may be integrated with a power discrete die (e.g., SiC or GaN power FET), or could further be integrated with embedded active circuitry in either/both substrate(s). For example, MEMS technology and active circuitry may be embedded in one substrate, or there may be one substrate for MEMS, and one for analog/digital/mixed IC.

In example embodiments, a semiconductor switching device may be embedded/integrated with a MEMS relay/contactor (or multiple series-connected relays) in a parallel fashion, such that said semiconductor can make and break connection (with no arcing), whereas the MEMS relay/contactor can achieve very low (mechanical contact) resistance in the ON-state. In one example embodiment, the MEMS relay/contactor is in series with a semiconductor and provides galvanic isolation in the OFF state. In one example embodiment, the semiconductor has a MEMS relay/contactor in parallel and another in series to achieve all functionality of a high-voltage DC capable solid-state, high-speed relay/contactor. In one example embodiment, MEMS technology may include micro-fluidics allowing for liquid cooling of the module without the need for an external liquid-cooled heat-sink

Example embodiments include embedded Integrated Passive Devices (IPDs) such as, e.g., MIMCAPs using multiple metal routing layers/RDL or other standard Si-processes. Other types of integrated capacitors (such as MOSCAPS) may be included, as well as inductors and resistors. Such elements may be in a lower/bottom and/or upper/top substrate, or in a second embedded die.

Geometry/Impedance controlled redistribution routing (manual or automatic) may be provided. For example, a 50-Ohms or similar routing/termination impedance target may be matched. Accordingly, a specific propagation delay target may be achieved, or a redistribution inductance/impedance of two routes/connections, such as paralleled power semiconductors, may be matched. For example, automated routing of the RDL that accomplishes specified goals of impedance may be provided. In example embodiments, Machine Learning (ML) and/or other implementations of Artificial Intelligence (AI), such as generative AI, may be used to optimize for specific goals (e.g. size, cost, or number of metal layers) and/or achieve automation.

There may be two or more dies embedded in single substrate sandwich. There may be two or more power discrete dies that are connected in parallel via substrate redistribution routing. There may be multiple devices or sets of parallel devices in half-bridge configuration(s). There may be multiple devices or sets of parallelized devices/half-bridges forming a 6-pack or higher half-bridge count(s) for multi-phase systems (e.g., 3-phase or 6-phase traction inverters). There may be different dies, serving different purposes and made from different materials (such as a Si IC die embedded together with a SiC and/or GaN transistor). Such dies may be of different thicknesses.

There may be one die per cavity or multiple dies in a single cavity. There may be multiple dies per cavity in one of the substrates, with a single die per cavity in the other substrate. There may be two or more modules combined in an array (horizontally), or two or more modules stacked vertically to form multi-layer systems. There may betwo or more dies vertically stacked modules using, e.g., four, three, or two pieces of silicon substrates. There may be “terraced” implementations, with one level a POS terminal (VDD) of a half-bridge, a next level is OUTPUT (switching node), and a top level is a NEG terminal (GND, Rtn). In other example, terminals may be in a different order.

Electrically routing may be provided in a middle layer or either/both of the top/bottom surfaces of a module, with thermal interface (and electrical isolation) partially or fully on one surface or both surfaces of the module. There may be ‘N’ layers vertically stacked. Example modules may be electrically configured in a half-bridge configuration with positive terminal on one surface, output in the middle, and negative terminal on the other surface.

In example embodiments, a finished module may itself be considered a base device and may be embedded into or nested within a larger module.

As referenced above, various embodiments (single-die, multi-die, multi-stack) can be combined. Combining multiple dies, chips, modules and systems together (horizontally and/or vertically) allows for formation of fully integrated miniaturized systems. For example, such system(s) may include multiple power-discrete dies (e.g., WBG devices such as SiC or GaN power transistors), MEMS relays, nano-tubes (micro-fluidics), temperature sensors, Drivers for the power-discretes as well as other analog, digital and mixed signal ICs, and/or passives (IPDs) for filtering functions, decoupling, local energy storage and current limiting.

In more specific examples, a fully integrated miniaturized traction motor driver for integration into a motor may be provided, including a powerstage with drivers, current sensing, feedback (shaft/rotor position), PWM generation, motor drive/control, filtering, decoupling and local energy storage, and protection, where such protection may include temperature derating, Over-Current Protection, Short-circuit protection, or a power rail e-fuse (e.g., an extremely fast circuit breaker for high-voltage DC with galvanic isolation).

Small size may be achieved through higher switching frequency (e.g., above 20 kHz) and multiple (lower current) modules working in tandem, including, e.g., combined with advanced inverter topologies such as multi-level (e.g. Hybrid Switched Cap [HSC], Flying Cap Multi-Level [FCML] or similar).

Example embodiments may have a final overall finished thickness that is less than, e.g., 875 um, which allows for processing on standard wafer-handling equipment.

Described techniques may be used to replace wirebonds and other conventional interconnect techniques in any context, and are well-suited to power applications, due to, e.g., improvements to electrical and thermal performance as described herein. Described techniques can be performed using standard semiconductor processing, such as lithography patterning, and can also utilize solder or polymer jetting, or screening through a metal mask.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, a DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, a spacer material can be an epoxy, a silicone adhesive, a conductive material, a non-conductive material, an organic material, a semiconductor material, a metal alloy, a metal foam, a phase change material, etc.

In the present description, semiconductor die(s) that may be used may be any of a wide variety including, by non-limiting example, power semiconductor die, diodes, metal oxide field effect transistors (MOSFETs), insulated gate bipolar junction transistors (IGBTs), hybrid devices, rectifiers, random access memory, high-electron-mobility transistors, image sensors, wide bandgap (WBG) semiconductor devices, hybrid devices, or any other semiconductor die/device type. Any of a wide variety of semiconductor substrate types may be employed for the semiconductor die packaged using the semiconductor package designs disclosed in this document including, by non-limiting example, silicon, silicon carbide, gallium arsenide, gallium nitride, silicon on insulator, ruby, sapphire, or any other semiconductor material type. A wide variety of semiconductor package configurations may be formed using the principles disclosed herein.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

Various example embodiments are provided in the following enumerated list.
1. A semiconductor package, comprising:
   a substrate;
   a semiconductor die disposed on the substrate and having at least a first contact on a first side and at least a second contact on a second side that is opposed to the first side;
   a dielectric encapsulant encapsulating the semiconductor die and having vias formed therein; and
   a redistribution layer formed on the dielectric encapsulant and connected to the first contact and the second contact through the vias.
2. The semiconductor package of example 1, further comprising a conductive layer electrically connected to the second contact and disposed between the second contact and the substrate, wherein the conductive layer is electrically connected to the redistribution layer through at least one of the vias.
3. The semiconductor package of example 1, wherein the substrate is electrically isolated from the semiconductor die by the dielectric encapsulant.
4. The semiconductor package of example 1, wherein the semiconductor die is disposed on a first surface of the substrate, and further comprising a heatsink disposed on a second surface of the substrate that is opposed to the first surface of the substrate.
5. The semiconductor package of example 1, wherein the second contact of the semiconductor die is electrically connected to the substrate.
6. The semiconductor package of example 1, further comprising:
   an insulating layer formed on the dielectric encapsulant and on the redistribution layer, the insulating layer having second vias formed therein; and
   a second redistribution layer formed on the insulating layer and connected to the redistribution layer through the second vias.
7. The semiconductor package of example 1, further comprising a cavity formed in the substrate, wherein the semiconductor die is disposed within the cavity.
8. The semiconductor package of example 1, further comprising:
   a second substrate formed of semiconductor material and disposed on the dielectric encapsulant, the second substrate having second vias formed therein, wherein the redistribution layer is formed on the second substrate and connected to the first contact and the second contact through the vias and the second vias.
9. The semiconductor package of example 1, further comprising:
   a second semiconductor die disposed on the redistribution layer;
   a second dielectric encapsulant formed on the redistribution layer and encapsulating the second semiconductor die, the second dielectric encapsulant having second vias formed therein; and
   a second redistribution layer formed on the second dielectric encapsulant and connected to the semiconductor die through the vias and the second vias, and connected to the second semiconductor die through the second vias.
10. The semiconductor package of example 1, further comprising:
   a second substrate formed of semiconductor material;
   a second semiconductor die disposed on a first side of the second substrate facing the semiconductor die;
   a second dielectric encapsulant at least partially encapsulating the second semiconductor die;
   second vias formed through the second dielectric encapsulant, with the semiconductor die and the second semiconductor die connecting through the second vias;
   third vias formed through the second dielectric encapsulant and through the second substrate;
   fourth vias formed through the second substrate; and
   a second redistribution layer formed at least partially on a second side of the second substrate, opposed to the first side of the second substrate, and connected to the redistribution layer and the second semiconductor die through the second vias, the third vias, and the fourth vias.
11. The semiconductor package of example 1, further comprising:
   second vias formed through the substrate; and
   a conductive layer formed on the substrate, and connected to the semiconductor die through the second vias.
12. The semiconductor package of example 1, wherein individual contacts of the redistribution layer are positioned in a quad flat no-lead footprint.
13. The semiconductor package of example 1, wherein individual contacts of the redistribution layer are electrically connected to corresponding contacts of a printed circuit board.
14. The semiconductor package of example 1, further comprising:
   a second substrate having a cavity formed therein, wherein the substrate is positioned within the cavity.
15. The semiconductor package of example 1, wherein individual contacts of the redistribution layer are positioned in a quad flat no-lead footprint, and further comprising a magnetic structure disposed on a surface of the substrate opposed to the redistribution layer.
16. A method of making a semiconductor package, comprising:
   providing a semiconductor die on a substrate, the semiconductor die having at least a first contact on a first side and at least a second contact on a second side that is opposed to the first side;
   encapsulating the semiconductor die with a dielectric encapsulant;
   forming vias in the dielectric encapsulant; and
   forming a redistribution layer on the dielectric encapsulant that is connected to the first contact and the second contact through the vias.
17. The method of example 16, comprising: providing a conductive layer electrically connected to the second contact and disposed between the second contact and the substrate, wherein the conductive layer is electrically connected to the redistribution layer through at least one of the vias.
18. The method of example 16, wherein the substrate is electrically isolated from the semiconductor die by the dielectric encapsulant.
19. The method of example 16, further comprising:
   disposing the semiconductor die on a first surface of the substrate; and
   disposing a heatsink on a second surface of the substrate that is opposed to the first surface of the substrate.
20. The method of example 16, further comprising:
   forming an insulating layer on the dielectric encapsulant and on the redistribution layer;
   forming second vias in the insulating layer; and
   forming a second redistribution layer on the insulating layer and connected to the redistribution layer through the second vias.
21. The method of example 16, further comprising:
   forming a cavity in the substrate; and
   disposing the semiconductor die within the cavity.
22. The method of example 16, further comprising:
   disposing a second substrate formed of semiconductor material on the dielectric encapsulant;
   forming second vias in the second substrate; and
   forming the redistribution layer on the second substrate and connected to the first contact and the second contact through the vias and the second vias.
23. The method of example 16, further comprising:
   disposing a second semiconductor die on the redistribution layer;
   forming a second dielectric encapsulant on the redistribution layer and encapsulating the second semiconductor die;
   forming second vias in the second dielectric encapsulant; and
   forming a second redistribution layer on the second dielectric encapsulant and connected to the semiconductor die through the vias and the second vias, and connected to the second semiconductor die through the second vias.
24. The method of example 16, further comprising:
   disposing a second semiconductor die on a first side of a second substrate formed of semiconductor material that is facing the semiconductor die;
   at least partially encapsulating the second semiconductor die with a second dielectric encapsulant;
   forming second vias through the second dielectric encapsulant, with the semiconductor die and the second semiconductor die connecting through the second vias;
   forming third vias through the second dielectric encapsulant and through the second substrate;
   forming fourth vias through the second substrate; and
   forming a second redistribution layer at least partially on a second side of the second substrate, opposed to the first side of the second substrate, and connected to the redistribution layer and the second semiconductor die through the second vias, the third vias, and the fourth vias.
25. The method of example 16, further comprising:
   forming second vias through the substrate; and
   forming a conductive layer on the substrate and connected to the semiconductor die through the second vias.
26. The method of example 16, further comprising:
   forming a cavity in a second substrate; and
   disposing the substrate within the cavity.
27. A semiconductor package comprising:
   a first substrate;
   a semiconductor die disposed on the first substrate;
   a second substrate having a cavity formed therein, the cavity defining a first portion of the second substrate having a first depth and a second portion of the second substrate having a second depth that is greater than the first depth, and the second substrate being attached to the first substrate by the second portion of the second substrate and with the semiconductor die disposed within the cavity;
   a via formed through the first portion of the second substrate; and
   a contact disposed on the second substrate and electrically connected to the semiconductor die through the via.
28. The semiconductor package of example 27, wherein the via is a second via, the contact is a second contact, and further comprising:
   a first via formed through the first substrate; and
   a first contact disposed on the first substrate and electrically connected to the semiconductor die through the first via.
29. The semiconductor package of example 27, further comprising:
   a second via formed through the second portion of the second substrate;
   a metal layer formed between the semiconductor die and the first substrate and extending between the first substrate and the second portion of the second substrate; and
   a redistribution layer formed on the second substrate that includes the contact and a second contact electrically connected to the metal layer through the second via.
30. The semiconductor package of example 27, wherein the cavity is a second cavity, and further comprising:
   a first cavity formed in the first substrate and aligned with the second cavity to form a combined cavity, wherein the semiconductor die is disposed within the combined cavity.
31. The semiconductor package of example 30, wherein the cavity has a first depth that is different from a second depth of the second cavity.
32. The semiconductor package of example 27, further comprising a redistribution layer on the second substrate and a heatsink on the first substrate.
33. The semiconductor package of example 27, further comprising:
   a first metal attachment point between the first substrate and the second substrate;
   a second metal attachment point between the semiconductor die and the second substrate; and
   a third metal attachment point between the semiconductor die and the first substrate.
34. The semiconductor package of example 27, wherein the first substrate comprises a metal substrate.
35. The semiconductor package of example 34, further comprising:
   a second via formed through the second portion of the second substrate;
   a third substrate disposed around a perimeter of the first substrate and having a third via formed therethrough; and
   a redistribution layer formed on the second substrate and connected to the first substrate and thereby to the semiconductor die through the second via and the third via.
36. The semiconductor package of example 27, wherein the first substrate comprises a direct bonded metal substrate.
37. The semiconductor package of example 27, further comprising:
   a dielectric layer formed on the second substrate; and
   a heatsink formed on the dielectric layer.
38. The semiconductor package of example 27, further comprising:
   a first metal layer extending through the first substrate and parallel to a surface of the semiconductor die, and electrically connected to the semiconductor die;
   a second metal layer that includes the contact and that extends through the second substrate and parallel to the surface of the semiconductor die;
   a second via formed through the second portion of the second substrate;
   a third via formed through the first substrate; and
   a redistribution layer formed on the first substrate between the first substrate and the second substrate, electrically connected to the first metal layer by way of the third via and to the second metal layer by way of the second via.
39. The semiconductor package of example 27, wherein the second substrate includes a semiconductor substrate, and further comprising an electronic element formed in the second substrate and connected to the semiconductor die by way of the contact.
40. The semiconductor package of example 27, wherein at least one of the first substrate and the second substrate includes a semiconductor substrate, and further comprising micro-electronic mechanical systems element formed in at least one of the first substrate and the second substrate and connected to the semiconductor die by way of the contact.
41. The semiconductor package of example 40, wherein the semiconductor die and the micro-electronic mechanical systems element are combined to provide a relay.
42. The semiconductor package of example 27, wherein at least one of the first substrate and the second substrate includes a semiconductor substrate, and further comprising micro-electronic mechanical systems micro-fluidic heat pipe formed in at least one of the first substrate and the second substrate.
43. A method of making a semiconductor package, comprising:
   disposing a semiconductor die on a first substrate;
   forming a cavity in a second substrate, the cavity defining a first portion of the second substrate having a first depth and a second portion of the second substrate having a second depth that is greater than the first depth;
   attaching the second substrate to the first substrate by the second portion of the second substrate and with the semiconductor die disposed within the cavity;
   forming a via through the first portion of the second substrate; and
   disposing a contact on the second substrate and electrically connected to the semiconductor die through the via.
44. The method of example 43, wherein the via is a second via, the contact is a second contact, and further comprising:
   forming a first via through the first substrate; and
   disposing a first contact on the first substrate and electrically connected to the semiconductor die through the first via.
45. The method of example 43, further comprising:
   forming a second via through the second portion of the second substrate;
   forming a metal layer between the semiconductor die and the first substrate and extending between the first substrate and the second portion of the second substrate; and
   forming a redistribution layer on the second substrate that includes the contact and a second contact electrically connected to the metal layer through the second via.
46. The method of example 43, wherein the cavity is a second cavity, and further comprising:
   forming a first cavity in the first substrate and aligned with the second cavity to form a combined cavity, wherein the semiconductor die is disposed within the combined cavity.
47. The method of example 46, wherein the first cavity has a first depth that is different from a second depth of the second cavity.
48. The method of example 43, further comprising;
   forming a redistribution layer on the second substrate; and
   providing a heatsink on the first substrate.
49. The method of example 43, further comprising:
   providing a first metal attachment point between the first substrate and the second substrate;
   providing a second metal attachment point between the semiconductor die and the second substrate; and
   providing a third metal attachment point between the semiconductor die and the first substrate.
50. The method of example 43, wherein the first substrate comprises a metal substrate.
51. The method of example 43, further comprising:
   forming a second via through the second portion of the second substrate;
   disposing a third substrate around a perimeter of the first substrate;
   forming a third via through the third substrate; and
   forming a redistribution layer on the second substrate and connected to the first substrate and thereby to the semiconductor die through the second via and the third via.
52. The method of example 43, further comprising:
   providing a first metal layer extending through the first substrate and parallel to a surface of the semiconductor die, and electrically connected to the semiconductor die;
   providing a second metal layer that includes the contact and that extends through the second substrate and parallel to the surface of the semiconductor die;
   forming a second via through the second portion of the second substrate;
   forming a third via formed through the first substrate; and
   forming a redistribution layer on the first substrate between the first substrate and the second substrate, electrically connected to the first metal layer by way of the third via and to the second metal layer by way of the second via.
53. The method of example 43, wherein the second substrate includes a semiconductor substrate, and further comprising:
   providing an electronic element formed in the second substrate and connected to the semiconductor die by way of the contact.
54. The method of example 43, wherein at least one of the first substrate and the second substrate includes a semiconductor substrate, and further comprising:
   providing a micro-electronic mechanical systems (MEMS) element in at least one of the first substrate and the second substrate.
55. A semiconductor package, comprising:
   a substrate having a cavity formed therein;
   a magnetic element disposed in the cavity;
   a metallic winding disposed on the substrate and surrounding the magnetic element;
   a dielectric encapsulant encapsulating the magnetic element and the metallic winding; and
   a contact electrically connected to the metallic winding through a via formed in the dielectric encapsulant.
56. The semiconductor package of example 55, wherein the magnetic element includes a cylindrical ferrous puck.
57. The semiconductor package of example 55, wherein the metallic winding comprises patterned metal layers that coil around the magnetic element in at least two turns.
58. The semiconductor package of example 55, wherein the metallic winding has an inner terminal proximate an edge of the magnetic element and spiral to an outer terminal distal from the magnetic element.
59. The semiconductor package of example 58, wherein the substrate includes a second cavity adjacent to the cavity, and further comprising:
   a second magnetic element disposed in the second cavity;
   a second metallic winding disposed on the substrate and surrounding the second magnetic element; and
   at least a second contact electrically connected to the second metallic winding through a second via formed in the dielectric encapsulant.
60. The semiconductor package of example 59, wherein the second metallic winding has a second inner terminal and a second outer terminal, and further wherein the outer terminal is electrically connected to the second inner terminal.
61. The semiconductor package of example 59, wherein the second metallic winding has a second inner terminal and a second outer terminal, and further wherein the inner terminal and the second inner terminal have a first common contact, and the outer terminal and the second outer terminal have a second common contact.
62. The semiconductor package of example 59, wherein the metallic winding has a first number of turns around the magnetic element and the second metallic winding has a second number of turns around the second magnetic element that is less than the first number of turns.
63. A method of making a semiconductor package, comprising:
   forming a cavity in a substrate;
   disposing a magnetic element in the cavity;
   providing a metallic winding on the substrate and surrounding the magnetic element;
   encapsulating the magnetic element and the metallic winding with a dielectric encapsulant;
   forming a via formed in the dielectric encapsulant; and
   electrically connecting a contact to the metallic winding through the via.
64. The method of making a semiconductor package of example 63, wherein the magnetic element includes a cylindrical ferrous puck.
65. The method of making a semiconductor package of example 63, further comprising:
   providing the metallic winding including patterned metal layers that coil around the magnetic element in at least two turns.
66. The method of making a semiconductor package of example 63, wherein the metallic winding has an inner terminal proximate an edge of the magnetic element and spiral to an outer terminal distal from the magnetic element.
67. The method of making a semiconductor package of example 66, wherein the substrate includes a second cavity adjacent to the cavity, and further comprising:
   disposing a second magnetic element in the second cavity;
   providing a second metallic winding on the substrate and surrounding the second magnetic element;
   forming a second via through the dielectric encapsulant; and
   electrically connecting a second contact to the second metallic winding through the second via.
68 The method of making a semiconductor package of example 67, wherein the second metallic winding has a second inner terminal and a second outer terminal, and further comprising:
   electrically connecting the outer terminal to the second inner terminal.
69. The method of making a semiconductor package of example 67, wherein the second metallic winding has a second inner terminal and a second outer terminal, and further comprising:
   providing the inner terminal and the second inner terminal with a first common contact; and
   providing the outer terminal and the second outer terminal with a second common contact.
70. The method of making a semiconductor package of example 67, further comprising:
   providing the metallic winding with a first number of turns around the magnetic element; and
   providing the second metallic winding with a second number of turns around the second magnetic element that is less than the first number of turns.
71. A semiconductor package comprising:
   a first substrate;
   a metal layer disposed on the first substrate;
   metal pillars disposed on the metal layer and defining a cavity;
   a semiconductor die disposed in the cavity with a first surface disposed on the metal layer;
   an encapsulant encapsulating the semiconductor die, including a second surface thereof opposed to the first surface, and at least a portion of the metallic pillars;
   a second substrate formed on the encapsulant and the metal pillars; and
   a redistribution layer formed on the second substrate and connected to the first surface of the semiconductor die, the second surface of the semiconductor die, and at least one of the metal pillars, through vias formed through the second substrate.
72. A method of making a semiconductor package, comprising:
   forming a metal layer on a first substrate;
   disposing metal pillars on the metal layer to define a cavity;
   disposing a semiconductor die in the cavity with a first surface disposed on the metal layer;
   encapsulating, with an encapsulant, the semiconductor die, including a second surface thereof opposed to the first surface, and at least a portion of the metal pillars;
   forming a second substrate on the encapsulant and the metal pillars;
   forming vias through the second substrate; and
   forming a redistribution layer on the second substrate and connected to the first surface of the semiconductor die, the second surface of the semiconductor die, and at least one of the metal pillars, through the vias.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor package, comprising:
a substrate;
a semiconductor die disposed on the substrate and having at least a first contact on a first side and at least a second contact on a second side that is opposed to the first side;
a dielectric encapsulant encapsulating the semiconductor die and having vias formed therein; and
a redistribution layer formed on the dielectric encapsulant and connected to the first contact and the second contact through the vias.

2. The semiconductor package of claim 1, further comprising a conductive layer electrically connected to the second contact and disposed between the second contact and the substrate, wherein the conductive layer is electrically connected to the redistribution layer through at least one of the vias.

3. The semiconductor package of claim 1, further comprising a cavity formed in the substrate, wherein the semiconductor die is disposed within the cavity.

4. The semiconductor package of claim 1, further comprising:
a second substrate formed of semiconductor material and disposed on the dielectric encapsulant, the second substrate having second vias formed therein, wherein the redistribution layer is formed on the second substrate and connected to the first contact and the second contact through the vias and the second vias.

5. The semiconductor package of claim 1, further comprising:
a second semiconductor die disposed on the redistribution layer;
a second dielectric encapsulant formed on the redistribution layer and encapsulating the second semiconductor die, the second dielectric encapsulant having second vias formed therein; and
a second redistribution layer formed on the second dielectric encapsulant and connected to the semiconductor die through the vias and the second vias, and connected to the second semiconductor die through the second vias.

6. The semiconductor package of claim 1, further comprising:
a second substrate formed of semiconductor material;
a second semiconductor die disposed on a first side of the second substrate facing the semiconductor die;
a second dielectric encapsulant at least partially encapsulating the second semiconductor die;
second vias formed through the second dielectric encapsulant, with the semiconductor die and the second semiconductor die connecting through the second vias;
third vias formed through the second dielectric encapsulant and through the second substrate;
fourth vias formed through the second substrate; and
a second redistribution layer formed at least partially on a second side of the second substrate, opposed to the first side of the second substrate, and connected to the redistribution layer and the second semiconductor die through the second vias, the third vias, and the fourth vias.

7. The semiconductor package of claim 1, further comprising:
a second substrate having a cavity formed therein, wherein the substrate is positioned within the cavity.

8. A semiconductor package comprising:
a first substrate;
a semiconductor die disposed on the first substrate;
a second substrate having a cavity formed therein, the cavity defining a first portion of the second substrate having a first depth and a second portion of the second substrate having a second depth that is greater than the first depth, and the second substrate being attached to the first substrate by the second portion of the second substrate and with the semiconductor die disposed within the cavity;
a via formed through the first portion of the second substrate; and
a contact disposed on the second substrate and electrically connected to the semiconductor die through the via.

9. The semiconductor package of claim 8, wherein the via is a second via, the contact is a second contact, and further comprising:
a first via formed through the first substrate; and
a first contact disposed on the first substrate and electrically connected to the semiconductor die through the first via.

10. The semiconductor package of claim 8, further comprising:
a second via formed through the second portion of the second substrate;
a metal layer formed between the semiconductor die and the first substrate and extending between the first substrate and the second portion of the second substrate; and
a redistribution layer formed on the second substrate that includes the contact and a second contact electrically connected to the metal layer through the second via.

11. The semiconductor package of claim 8, wherein the cavity is a second cavity, and further comprising:
a first cavity formed in the first substrate and aligned with the second cavity to form a combined cavity, wherein the semiconductor die is disposed within the combined cavity.

12. The semiconductor package of claim 8, further comprising:
a first metal attachment point between the first substrate and the second substrate;
a second metal attachment point between the semiconductor die and the second substrate; and
a third metal attachment point between the semiconductor die and the first substrate.

13. The semiconductor package of claim 8, further comprising:
a first metal layer extending through the first substrate and parallel to a surface of the semiconductor die, and electrically connected to the semiconductor die;
a second metal layer that includes the contact and that extends through the second substrate and parallel to the surface of the semiconductor die;
a second via formed through the second portion of the second substrate;
a third via formed through the first substrate; and
a redistribution layer formed on the first substrate between the first substrate and the second substrate, electrically connected to the first metal layer by way of the third via and to the second metal layer by way of the second via.

14. The semiconductor package of claim 8, wherein the second substrate includes a semiconductor substrate, and further comprising an electronic element formed in the second substrate and connected to the semiconductor die by way of the contact.

15. The semiconductor package of claim 8, wherein at least one of the first substrate and the second substrate includes a semiconductor substrate, and further comprising micro-electronic mechanical systems element formed in at least one of the first substrate and the second substrate and connected to the semiconductor die by way of the contact.

16. The semiconductor package of claim 15, wherein the semiconductor die and the micro-electronic mechanical systems element are combined to provide a relay.

17. A semiconductor package, comprising:
a substrate having a cavity formed therein;
a magnetic element disposed in the cavity;
a metallic winding disposed on the substrate and surrounding the magnetic element;
a dielectric encapsulant encapsulating the magnetic element and the metallic winding; and
a contact electrically connected to the metallic winding through a via formed in the dielectric encapsulant.

18. The semiconductor package of claim 17, wherein the magnetic element includes a cylindrical ferrous puck.

19. The semiconductor package of claim 17, wherein the metallic winding comprises patterned metal layers that coil around the magnetic element in at least two turns.

20. The semiconductor package of claim 17, wherein the metallic winding has an inner terminal proximate an edge of the magnetic element and spiral to an outer terminal distal from the magnetic element.

21. The semiconductor package of claim 20, wherein the substrate includes a second cavity adjacent to the cavity, and further comprising:
a second magnetic element disposed in the second cavity;
a second metallic winding disposed on the substrate and surrounding the second magnetic element; and
at least a second contact electrically connected to the second metallic winding through a second via formed in the dielectric encapsulant.
